(19) United States
(12) Patent Application Publication
(10) Pub. No.: US 2023/0421156 A1
(43) Pub. Date: Dec. 28, 2023

(54) GLITCH ABSORBING BUFFER FOR DIGITAL CIRCUITS

(71) Applicant: QUALCOMM Incorporated, San Diego, CA (US)

(72) Inventors: Basma HAJRI, Cork (IE); Harshat PANT, San Diego, CA (US); Chirag AGRAWAL, Poway, CA (US); Shih-Hsin Jason HU, San Diego, CA (US)

(21) Appl. No.: 17/849,469

(22) Filed: Jun. 24, 2022

(51) Int. Cl. H03K 19/0948; H03K 5/01; H03K 19/20

(52) U.S. Cl. CPC H03K 19/0948; H03K 5/01; H03K 19/20; H03K 2005/00013

(57) ABSTRACT

An aspect relates to a glitch absorbing buffer (GABUF) including: a delay element configured to delay an input signal by a delay to generate a delayed input signal; and a logic circuit, responsive to the input signal, the delayed input signal, and an output signal, configured to propagate a pulse in the input signal to the output signal if a width of the pulse is greater than the delay, and suppress the propagating of the pulse to the output signal if the width of the pulse is less than the delay.

### FIELD

Aspects of the present disclosure relate generally to digital circuits, and in particular, to a glitch absorbing buffer (GABUF) for combinational logic digital circuits.

### BACKGROUND

Many integrated circuits (ICs) include sequential digital circuits to perform various operations. In sequential digital circuits, a set of flip-flops send data, under sequential control of a clock, to combinational logic circuits that perform various combinational logic operations. In theory, the data provided to the combinational logic circuits should arrive at the same time. However, due to imbalances in metal traces between the flip-flops and the combinational logic circuits, the arrival of the data may not be at the same time. As a result of such imbalances, the combinational logic circuit produce glitches, which have the adverse effects of unnecessarily consuming power and creating noise.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes a glitch absorbing buffer (GABUF), including: a delay element configured to delay an input signal by a delay to generate a delayed input signal; and a logic circuit, responsive to the input signal, the delayed input signal, and an output signal, configured to propagate a pulse in the input signal to the output signal if a width of the pulse is greater than the delay, and suppress the propagating of the pulse to the output signal if the width of the pulse is less than the delay.

Another aspect of the disclosure relates to an apparatus. The apparatus includes a glitch absorbing buffer (GABUF), including: a first delay element configured to delay an input signal by a first delay to generate a first delayed input signal; a second delay element configured to delay the first delayed input signal by a second delay to generate a second delayed input signal, wherein a sum of the first delay and the second delay is equal to a delay; and a logic circuit, responsive to the input signal, the first delayed input signal, the second delayed input signal, and an output signal, configured to propagate a pulse in the input signal to the output signal if a width of the pulse of a pulse burst is greater than the delay, and suppress the propagating of the pulse to the output signal if the width of the pulse of the pulse burst is less than the delay and a period of the pulse burst is greater than the width of the pulse plus the first delay.

Another aspect of the disclosure relates to a wireless communication device. The wireless communication device includes at least one antenna; a transceiver coupled to at least one antenna; one or more signal processing cores coupled to the transceiver, wherein the one or more signal processing cores comprises a set of glitch absorbing buffers (GABUFs), wherein each of the GABUFs includes: a delay element configured to delay an input signal by a delay to generate a delayed input signal; and a logic circuit, responsive to the input signal, the delayed input signal, and an output signal, configured to propagate a pulse in the input signal to the output signal if a width of the pulse is greater than the delay, and suppress the propagating of the pulse to the output signal if the width of the pulse is less than the delay.

Another aspect of the disclosure relates to a wireless communication device. The wireless communication device includes at least one antenna; a transceiver coupled to at least one antenna; one or more signal processing cores coupled to the transceiver, wherein the one or more signal processing cores comprises a set of glitch absorbing buffers (GABUFs), wherein each of the GABUFs includes: a first delay element configured to delay an input signal by a first delay to generate a first delayed input signal; a second delay element configured to delay the first delayed input signal by a second delay to generate a second delayed input signal, wherein a sum of the first delay and the second delay is equal to a delay; and a logic circuit, responsive to the input signal, the first delayed input signal, the second delayed input signal, and an output signal, configured to propagate a pulse in the input signal to the output signal if a width of the pulse of a pulse burst is greater than the delay, and suppress the propagating of the pulse to the output signal if the width of the pulse of the pulse burst is less than the delay and a period of the pulse burst is greater than the width of the pulse plus the first delay.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a schematic diagram of an example combinational logic circuit in accordance with an aspect of the disclosure.

FIG. 1B illustrates a timing diagram of an example unintended positive glitch produced by the combinational logic circuit of FIG. 1A in accordance with another aspect of the disclosure.

FIG. 1C illustrates a schematic diagram of another example combinational logic circuit in accordance with an aspect of the disclosure.

FIG. 1D illustrates a timing diagram of an example unintended negative glitch produced by the combinational logic circuit of FIG. 1C in accordance with another aspect of the disclosure.

FIG. 2 illustrates a block diagram of an example digital circuit in accordance with another aspect of the disclosure.

FIG. 3A illustrates a schematic diagram of an example two-input glitch absorbing buffer (GABUF) in accordance with another aspect of the disclosure.

FIG. 3B illustrates a timing diagram of an example pulse propagation operation of the two-input glitch absorbing buffer (GABUF) of FIG. 3A in accordance with another aspect of the disclosure.

FIG. 3C illustrates a timing diagram of an example pulse absorption operation of the two-input glitch absorbing buffer (GABUF) of FIG. 3A in accordance with another aspect of the disclosure.

FIG. 4 illustrates a block diagram of another example digital circuit in accordance with another aspect of the disclosure.

FIG. 5A illustrates a schematic diagram of another example two-input glitch absorbing buffer (GABUF) in accordance with another aspect of the disclosure.

FIG. 5B illustrates a timing diagram of an example operation of two-input glitch absorbing buffers (GABUFs) described herein in accordance with another aspect of the disclosure.

FIG. 5C illustrates a timing diagram of another example operation of two-input glitch absorbing buffers (GABUFs) described herein in accordance with another aspect of the disclosure.

FIG. 6 illustrates a schematic diagram of another example two-input glitch absorbing buffer (GABUF) in accordance with another aspect of the disclosure.

FIG. 7A illustrates a schematic diagram of another example two-input glitch absorbing buffer (GABUF) in accordance with another aspect of the disclosure.

FIG. 7B illustrates a schematic diagram of an example two-input logic AND gate in accordance with another aspect of the disclosure.

FIG. 7C illustrates a schematic diagram of an example two-input logic NOR gate in accordance with another aspect of the disclosure.

FIG. 8A illustrates a schematic diagram of another example two-input glitch absorbing buffer (GABUF) in accordance with another aspect of the disclosure.

FIG. 8B illustrates a schematic diagram of an example three-input logic OR gate in accordance with another aspect of the disclosure.

FIG. 9A illustrates a timing diagram of an example operation of the two-input glitch absorbing buffer (GABUF) of FIG. 3A in response to a pulse burst in accordance with another aspect of the disclosure.

FIG. 9B illustrates a schematic diagram of an example three-input glitch absorbing buffer (GABUF) in accordance with another aspect of the disclosure.

FIG. 9C illustrates a timing diagram of an example operation of the three-input glitch absorbing buffer (GABUF) of FIG. 9B in accordance with another aspect of the disclosure.

FIG. 10A illustrates a schematic diagram of another example three-input glitch absorbing buffer (GABUF) in accordance with another aspect of the disclosure.

FIG. 10B illustrates a timing diagram of an example operation of three-input glitch absorbing buffers (GABUFs) described herein in accordance with another aspect of the disclosure.

FIG. 10C illustrates a timing diagram of another example operation of three-input glitch absorbing buffers (GABUF) described herein in accordance with another aspect of the disclosure.

FIG. 11 illustrates a schematic diagram of another example three-input glitch absorbing buffer (GABUF) in accordance with another aspect of the disclosure.

FIG. 12A illustrates a schematic diagram of another example three-input glitch absorbing buffer (GABUF) in accordance with another aspect of the disclosure.

FIG. 12B illustrates a schematic diagram of an example three-input logic AND gate in accordance with another aspect of the disclosure.

FIG. 12C illustrates a schematic diagram of an example three-input logic NOR gate in accordance with another aspect of the disclosure.

FIG. 13A illustrates a schematic diagram of another example three-input glitch absorbing buffer (GABUF) in accordance with another aspect of the disclosure.

FIG. 13B illustrates a schematic diagram of an example four-input logic OR gate in accordance with another aspect of the disclosure.

FIG. 14 illustrates a block diagram of an example wireless communication device in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

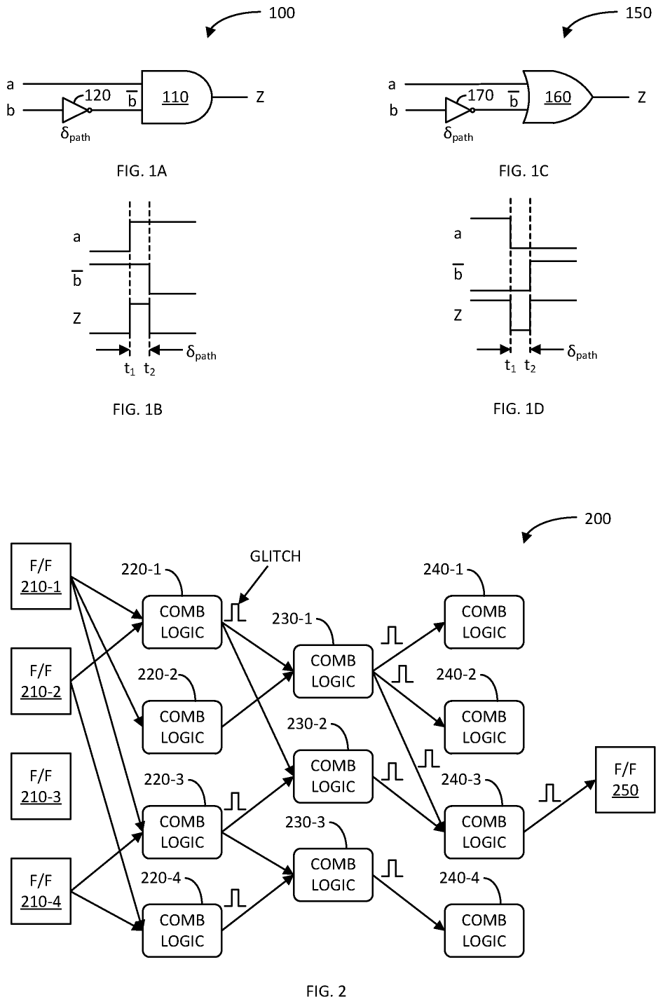

FIG. 1A illustrates a schematic diagram of an example combinational logic circuit 100 in accordance with an aspect of the disclosure. The combinational logic circuit 100 includes a two-input logic AND gate 110 and an inverter 120. A first logic signal “a” is applied to a first input of the AND gate 110, a second logic signal “b” is applied to a second input of the AND gate 110 via the inverter 120, and an output logic signal “Z” is generated by the AND gate 110 being the result of logically ANDing the first signal “a” with the inverted second signal “b̅.”

In this example, the combinational logic circuit 100 has unbalanced inputs. That is, the first input signal “a” propagates directly to the first input of the AND gate 110, whereas the second input signal “b” propagates to the second input of the AND gate 110 via the inverter 120. The inverter 120, not only logically inverts the second input signal “b”, but also delays the second input signal by an amount of δₚₐₜₕ. Accordingly, the inverted second input signal b arrives at the second input of the AND gate 110 at a delay interval of δₚₐₜₕ after the first input signal “a” arrives at the first input of the AND gate 110. As explained in more detail further herein, because the combinational logic circuit 100 reacts to the unbalanced inputs asynchronously, the combinational logic circuit 100 generates positive glitches or unintended positive pulses.

FIG. 1B illustrates a timing diagram of an example unintended positive pulse produced by the combinational logic circuit 100 in accordance with another aspect of the disclosure. The x- or horizontal axis of the timing diagram represents time, and the y- or vertical axis of the timing diagram represents, from top to bottom, the logic states of the first input signal “a”, the inverted and delayed second input signal b̅, and the output signal “Z.”

As the timing diagram illustrates, prior to time t₁, both first and second input signals “a” and “b” are at low logic states, the inverted second input signal b̅ is at a high logic state, and the output signal “Z” is at a low logic state. At time t₁, both the first and second input signals “a” and “b” transition to a high logic state. Because of the unbalanced inputs, the inverted second input signal b̅ remains at a high logic state until time t₂ (e.g., t₁+δₚₐₜₕ). Accordingly, during the time interval between t₁ and t₂, the AND gate 110 sees both input signals “a” and b̅ at high logic states; and thus, the AND gate 110 generates the output signal “Z” at a high logic state. When the inverted second input signal b̅ transitions to a low logic state at time t₂, the AND gate 110 generates the output signal “Z” at a low logic state.

As a result, the combinational logic circuit 100 generates an unintended positive pulse or glitch between times t₁ and t₂ due to the unbalanced inputs. Had the inputs been balanced, the transitions of the input signals “a” and b̅ would have arrived at the same time t₁, and the AND gate 110 would have maintained the output signal “Z” constant at a low logic state. Thus, due to the combinational logic circuit 100 reacting to the unbalanced inputs asynchronous, the combinational logic circuit 100 is prone to generating positive glitches.

FIG. 1C illustrates a schematic diagram of another example combinational logic circuit 150 in accordance with an aspect of the disclosure. The combinational logic circuit 150 includes a two-input logic OR gate 160 and an inverter 170. A first logic signal “a” is applied to a first input of the OR gate 160, a second logic signal “b” is applied to a second input of the OR gate 160 via the inverter 170, and an output logic signal “Z” is generated by the OR gate 160 being the result of logically ORing the first signal “a” with the inverted second signal “b̅.”

Similarly, in this example, the combinational logic circuit 150 has unbalanced inputs. That is, the first input signal “a” propagates directly to the first input of the OR gate 160, whereas the second input signal “b” propagates to the second input of the OR gate 160 via the inverter 170. The inverter 170, not only logically inverts the second input signal “b”, but also delays the second input signal by an amount of δₚₐₜₕ. Accordingly, the inverted second input signal b̅ arrives at the second input of the OR gate 160 at a delay interval of δₚₐₜₕ after the first input signal “a” arrives at the first input of the OR gate 160. Similarly, because the combinational logic circuit 150 reacts to the unbalanced inputs asynchronously, the combinational logic circuit 150 generates negative glitches or unintended negative pulses.

FIG. 1D illustrates a timing diagram of an example unintended negative glitch produced by the combinational logic circuit 150 in accordance with another aspect of the disclosure. Similarly, the x- or horizontal axis of the timing diagram represents time, and the y- or vertical axis of the timing diagram represents, from top to bottom, the logic states of the first input signal “a”, the inverted and delayed second input signal b̅, and the output signal “Z.”

As the timing diagram illustrates, prior to time t₁, the first and second input signals “a” and “b” are both at high logic states, the inverted second input signal b̅ is at a low logic state, and the output signal “Z” is at a high logic state. At time t₁, the first and second input signals “a” and “b” transition to low logic states. Because of the unbalanced inputs, the inverted second input signal b̅ remains at a low logic state until time t₂ (e.g., t₁+δₚₐₜₕ). Accordingly, during the time interval between t₁ and t₂, the OR gate 160 sees the input signals “a” and b̅ at low logic states, respectively; and thus, the OR gate 160 generates the output signal “Z” at a low logic state. When the inverted second input signal b̅ transitions to a high logic state at time t₂, the OR gate 160 generates the output signal “Z” at a high logic state.

As a result, the combinational logic circuit 150 generates an unintended negative pulse or glitch between times t₁ and t₂ due to the unbalanced inputs. Had the inputs been balanced, the transitions of the input signals “a” and b̅ would have arrived at the same time t₁, and the OR gate 160 would have maintained the output signal “Z” constant at a high logic state. Thus, due to the combinational logic circuit 150 reacting to the unbalanced inputs asynchronous, the combinational logic circuit 150 is prone to generating negative glitches.

FIG. 2 illustrates a schematic diagram of an example digital circuit 200 in accordance with another aspect of the disclosure. The digital circuit 200 includes a first hierarchical set of flip-flops (F/F) 210-1 to 210-4, a first hierarchical set of combinational logic circuits 220-1 to 220-4, a second hierarchical set of combinational logic circuits 230-1 to 230-3, a third hierarchical set of combinational logic circuits 240-1 to 240-4, and at least one second hierarchical set of flip-flop (F/F) 250 (although the digital circuit 200 may include more than one second hierarchical set of flip-flops (F/F)).

In this example, the first hierarchical F/F 210-1 includes an output coupled to inputs of first hierarchical combinational logic circuits 220-1 to 220-3, respectively. The first hierarchical F/F 210-2 includes an output coupled to inputs of the first hierarchical combinational logic circuits 220-1 and 220-4, respectively. The first hierarchical F/F 210-4 includes an output coupled to inputs of the first hierarchical combinational logic circuits 220-3 and 220-4, respectively. Although, in this example, the first hierarchical F/F 210-3 is not shown as having an output coupled to a combinational logic circuit, it shall be understood that it may have an output coupled to one or more combinational logic circuits.

Further, according to this example, the first hierarchical combinational logic circuit 220-1, in turn, includes an output coupled to inputs of the second hierarchical combinational logic circuits 230-1 to 230-2, respectively. The first hierarchical combinational logic circuit 220-2 includes an output coupled to the input of the second hierarchical combinational logic circuit 230-1. The first hierarchical combinational logic circuit 220-3 includes an output coupled to inputs of the second hierarchical combinational logic circuits 230-2 and 230-3, respectively. And, the first hierarchical combinational logic circuit 220-4 includes an output coupled to the input of the second hierarchical combinational logic circuit 230-3.

The second hierarchical combinational logic circuit 230-1, in turn, includes an output coupled to inputs of the third hierarchical combinational logic circuits 240-1 to 240-3, respectively. The second hierarchical combinational logic circuit 230-2 includes an output coupled to the input of the third hierarchical combinational logic circuit 240-3. The second hierarchical combinational logic circuit 230-3 includes an output coupled to an input of the third hierarchical combinational logic circuit 240-4.

The third hierarchical combinational logic circuit 240-3, in turn, includes an output coupled to an input of the second hierarchical F/F 250. Although, in this example, the third hierarchical combinational logic circuits 240-1, 240-2, and 240-4 are not shown as having outputs coupled to any combinational logic circuits, it shall be understood that each of them may have an output coupled to one or more second hierarchical F/Fs.

As further illustrated, in this example, the first hierarchical combinational logic circuits 220-1, 220-3, and 220-4 generate glitches (e.g., positive glitches) due to unbalanced inputs, respectively. These glitches propagate to the inputs of the second hierarchical combinational logic circuits 230-1 to 230-3. The second hierarchical combinational logic circuits 230-1 to 230-3, in turn, respond to these glitches by generating secondary-effect glitches. These secondary-effect glitches propagate to the inputs of the third hierarchical combinational logic circuits 240-1 to 240-4, which, respond by generating third-effect glitches; and so on, in a chain-reaction fashion. Glitches cause the digital circuit 200 to unnecessarily consume power (e.g., it is wasted power). Further, the glitches generate noise in the digital circuit 200, which may have adverse effects on the signals and circuit operation due to electromagnetic interference (EMI). Thus, reducing the number of glitches produced by digital circuits is of interest herein.

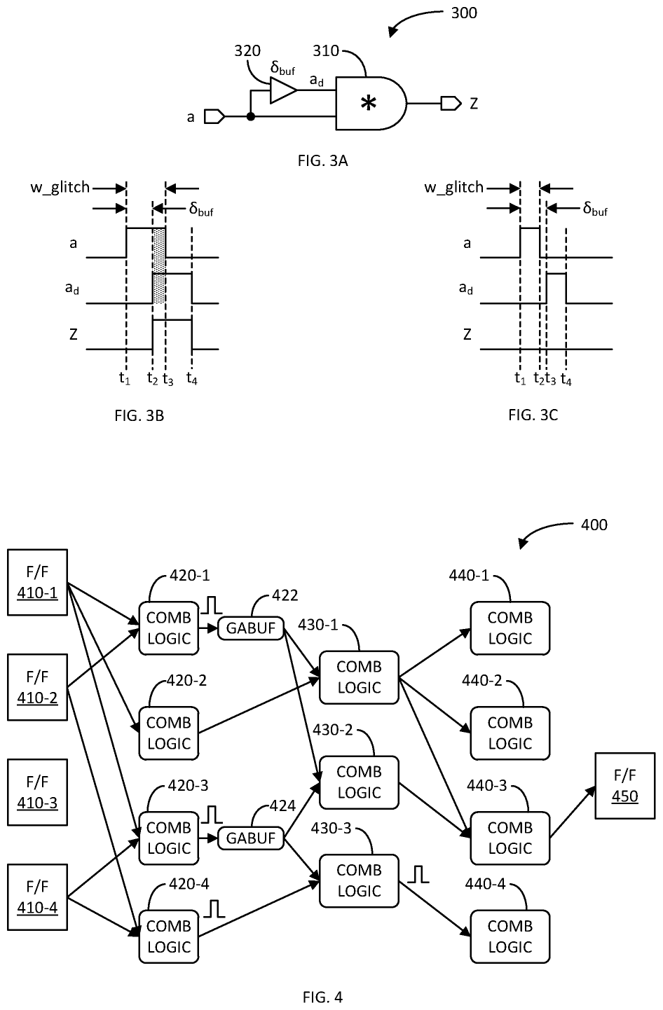

FIG. 3A illustrates a schematic diagram of an example two-input glitch absorbing buffer (GABUF) 300 in accordance with another aspect of the disclosure. The GABUF 300 is configured to propagate a pulse in an input signal “a” to an output signal “Z” if the width of the pulse is greater than a defined delay δ_{buf}, and suppress the propagation of a pulse in the input signal “a” to the output signal “Z” if the width of the pulse is less than the defined delay δ_{buf}. The defined delay δ_{buf} may be set to distinguish pulse width that represent actual data (e.g., the pulse width of actual data being greater than the defined delay δ_{buf}) from glitches (e.g., the pulse width of glitches being less than the defined delay δ_{buf}).

In particular, the GABUF 300 includes a logic circuit including a C-element 310, and a delay element, such as a buffer 320. The C-element 310 and buffer 320 include inputs configured to receive the input signal “a”. The C-element 310 includes a second input coupled to an output of the buffer 320. The buffer 320 may be configured to delay the input signal “a” by the defined delay δ_{buf} to generate a delayed input signal “a_{d}”. The C-element 310 is configured to generate the output signal “Z” as a logic zero (0) if both the inputs “a” and “a_{d}” are logic zeros (0s), as a logic one (1) if both the inputs “a” and “a_{d}” are logic ones (1s), and retain the previous logic state if the inputs “a” and “a_{d}” are at different logic states. The transfer function and truth table for the C-element 310 is provided below:

Zₙ=a*a_{d}+(a+a_{d})Zₙ₋₁ Eq. 1

C-element Truth Table

| a | a_{d} | Zₙ |
|---|---|---|
| 0 | 0 | 0 |
| 0 | 1 | Zₙ₋₁ |
| 1 | 0 | Zₙ₋₁ |
| 1 | 1 | 1 |

The pulse propagation and suppression operations of the GABUF 300 are discussed below with reference to timing diagrams depicted in FIGS. 3B-3C.

FIG. 3B illustrates a timing diagram of an example pulse propagation operation of the GABUF 300 in accordance with another aspect of the disclosure. The x- or horizontal-axis of the timing diagram represents time, and the y- or vertical-axis of the timing diagram represents, from top to bottom, the logic states of the input signal “a”, the delayed input signal “a_{d}”, and the output signal “Z”, respectively. According to the timing diagram, prior to time t₁, the input signal “a” and the delayed input signal “a_{d}” are both at logic zeros (0s). Thus, according to the transfer function (Eq. 1) or truth table of the C-element 310, the C-element 310 generates the output signal “Z” also at a logic zero (0).

At time t₁, the input signal “a” transitions to a logic one (1). Accordingly, as the input signal “a” (at logic one (1)) and the delayed input signal “a_{d}” (at logic zero (0)) are at different logic states at time t₁, the C-element 310 maintains the output signal “Z” at the previous state (at logic zero (0)). After a delay of δ_{buf} from the rising transition of the input signal “a” at time t₁ due to the buffer 320, the delayed input signal “a_{d}” transitions to a logic one (1) at time t₂. Accordingly, as both the input signal “a” and the delayed input signal “a_{d}” are at logic ones (1s) at time t₂, the C-element 310 transitions the output signal “Z” to a logic one (1).

At time t₃, the input signal “a” transitions back to a logic zero (0). Accordingly, as the input signal “a” (at logic zero (0)) and the delayed input signal “a_{d}” (at logic one (1)) are at different logic states at time t₃, the C-element 310 maintains the output signal “Z” at the previous state (at logic one (1)). After a delay (w_glitch−δ_{buf}) from the falling transition of the input signal “a” at time t₃ due to the buffer 320, the delayed input signal “a_{d}” transitions back to a logic zero (0) at time t₄. Accordingly, as both the input signal “a” and the delayed input signal “a_{d}” are at logic zeros (0s) at time t₄, the C-element 310 transitions the output signal “Z” to a logic zero (0).

Thus, in this example, the input signal “a” has a pulse having a width w_glitch (t₃−t₁) greater than the delay δ_{buf} (t₂−t₁) of the buffer 320. Since the pulse width w_glitch is greater than the buffer delay δ_{buf}, there is an interval (t₃−t₂) (depicted as a shaded region) where both the input signal “a” and the delayed input signal “a_{d}” are at logic ones (1s). Thus, at time t₂, the C-element 310 transitions the output signal “Z” to a logic one (1) forming the rising transition of the pulse in the output signal “Z”. At time t₃, the input signal “a” transitions to a logic zero (0), and at time t₄, the delayed input signal “a_{d}” transitions to a logic zero (0). Since both the input signal “a” and the delayed input signal “a_{d}” are at logic zeros (0s) at time t₄, the C-element 310 transitions the output signal “Z” to a logic zero (0) forming the falling transition of the pulse in the output signal “Z”. The width of the pulse of the output signal “Z” is the same as the width w_glitch of the pulse of the input signal “a”. Thus, because the pulse width w_glitch is greater than the buffer delay δ_{buf}, the GABUF 300 propagates the pulse to the output.

FIG. 3C illustrates a timing diagram of an example pulse absorption operation of the GABUF 300 in accordance with another aspect of the disclosure. Similarly, the x- or horizontal-axis of the timing diagram represents time, and the y- or vertical-axis of the timing diagram represents, from top to bottom, the logic states of the input signal “a”, the delayed input signal “a_{d}”, and the output signal “Z”, respectively. According to the timing diagram, prior to time t₁, the input signal “a” and the delayed input signal “a_{d}” are both at logic zeros (0s). Thus, according to the transfer function (Eq. 1) or truth table of the C-element 310, the C-element 310 generates the output signal “Z” also at a logic zero (0).

At time t₁, the input signal “a” transitions to a logic one (1). Accordingly, as the input signal “a” (at logic one (1)) and the delayed input signal “a_{d}” (at logic zero (0)) are at different logic states at time t₁, the C-element 310 maintains the output signal “Z” at the previous state (at logic zero (0)). In this example, the width w_glitch of the pulse of the input signal “a” is less than the buffer delay δ_{buf}. As such, at time t₂, the input signal “a” transitions to a logic one (1) before the delayed input signal “a_{d}” transitions to a logic one (1) at time t₃. As there is no overlap interval where both the input signal “a” and the delayed input signal “a_{d}” are logic ones (1s) at the same time, the C-element 310 maintains the output signal “Z” at the previous state (at logic zero (0)).

As discussed, at time t₃, the delayed input signal “a_{d}” transitions to a logic one (1), and at time t₄, the delayed input signal “a_{d}” transitions back to a logic zero (0). Accordingly, during time interval t₃−t₄, the input signal “a” (at logic zero (0)) and the delayed input signal “a_{d}” (at logic one (1)) are at different logic states; and thus, the C-element 310 maintains the output signal “Z” at the previous state (at logic zero (0)). Since after time t₄, both the input signal “a” and the delayed input signal “a_{d}” are at logic zeros (0s), the C-element 310 maintains the output signal “Z” at a logic zero (0).

Thus, in this example, the input signal “a” has a pulse with a width w_glitch (t₂−t₁) less than the delay δ_{buf} (t₃−t₁) of the buffer 320. Since the pulse width w_glitch is less than the buffer delay δ_{buf}, there is no overlap interval where both the input signal “a” and the delayed input signal “a_{d}” are at logic ones (1s). Thus, the C-element 310 maintains the output signal “Z” at a logic zero (0). Thus, because the pulse width w_glitch is less than the buffer delay δ_{buf}, the GABUF 300 suppresses the propagation of the pulse to the output.

FIG. 4 illustrates a schematic diagram of another example digital circuit 400 in accordance with another aspect of the disclosure. The digital circuit 400 is similar to digital circuit 200 previously discussed, and includes many of the same elements identified by the same reference numbers with the exception that the most significant digit is a “4” in digital circuit 400 as opposed to a “2” in digital circuit 200. Thus, the digital circuit 400 includes a set of first hierarchical level flip-flops (F/F) 410-1 to 410-4, a set of first hierarchical level combinational logic circuits 420-1 to 420-4, a set of second hierarchical level combinational logic circuits 430-1 to 430-3, a set of third hierarchical level combinational logic circuits 440-1 to 440-4, and at least one second hierarchical level flip-flop (F/F) 450.

The digital circuit 400 differs from digital circuit 200 in that a couple of glitch absorbing buffers (GABUF) 422 and 424 are added to the digital circuit 400 to reduce the propagation of glitches; and as a result, reduce wasted power consumption and noise associated with the secondary-effect glitches. For instance, in this example, the digital circuit 400 includes the GABUF 422 at the output of the first hierarchical level combinational logic circuit 420-1, and the GABUF 424 at the output of the first hierarchical level combinational logic circuit 420-3.

As illustrated, the GABUF 422 suppresses the glitch generated by the first hierarchical level combinational logic circuit 420-1 from propagating to the second hierarchical level combinational logic circuits 430-1 and 430-2. Similarly, the GABUF 424 suppresses the glitch generated by the first hierarchical level combinational logic circuit 420-3 from propagating to the second hierarchical level combinational logic circuits 430-2 and 430-3. As a GABUF has not been provided at the output of first hierarchical level combinational logic circuit 420-4, the glitch generated by the first hierarchical level combinational logic circuit 420-4 propagates to the second hierarchical level combinational logic circuit 430-3. As a result, the second hierarchical level combinational logic circuit 430-3 generates a secondary-effect glitch.

Comparing the digital circuit 400 to the digital circuit 200, the addition of GABUFs 422 and 424 reduces the number of secondary- and third-effect glitches from six (6) to one (1). This is a significant number in the reduction of unwanted glitches in digital circuit 400. As a result, the digital circuit 400 produces less wasted power consumption and significantly less noise as compared to digital circuit 200. As each GABUF 422 and 424 consumes power, it may not be desirable to place a GABUF in front of each combinational logic circuit as the power consumed by the GABUFs may be greater than the power saving due to the suppression of glitches. Accordingly, a script or algorithm may be employed to analyze a digital circuit, and place GABUFs where the most power benefit may be achieved. In this example, for instance, a GABUF was not placed at the output of the first hierarchical level combinational logic circuit 420-4; and thus, a small number of secondary glitches may occur.

### Detailed Two-Input GABUF

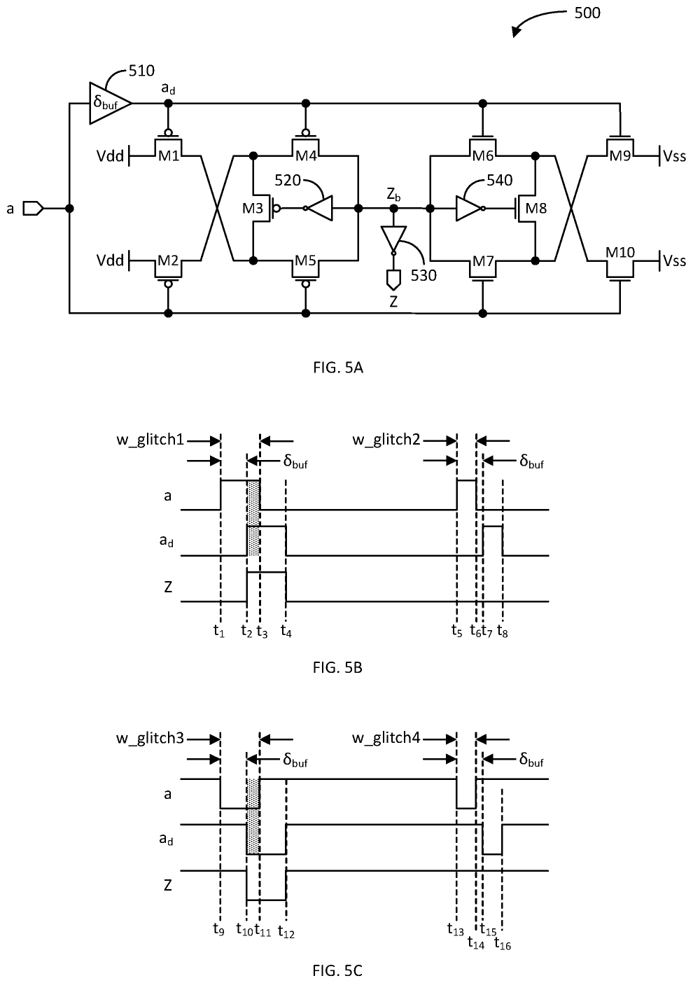

FIG. 5A illustrates a schematic diagram of another example two-input glitch absorbing buffer (GABUF) 500 in accordance with another aspect of the disclosure. The GABUF 500 may be an example detailed implementation of any of the GABUFs 300, 422, and 424 previously discussed. In particular, the GABUF 500 includes a delay element, such as a buffer 510, and a logic circuit including a set of p-channel metal oxide semiconductor field effect transistors (PMOS FETs) M1 to M5, a set of n-channel metal oxide semiconductor field effect transistors (NMOS FETs) M6 to M10, and a set of inverters 520, 530, and 540.

The buffer 510 is configured with a delay δ_{buf} to differentiate between a data pulse in an input signal “a” that the GABUF 500 propagates to an output “Z” (e.g., if the width of the pulse is greater than the buffer delay δ_{buf}) and a glitch in the input signal “a” that the GABUF 500 suppresses from propagating to the output “Z” (e.g., if the width of the glitch is less than the buffer delay δ_{buf}) The buffer 510 includes an input configured to receive the input signal “a”. The remaining logic circuitry, e.g., the PMOS FETs M1-M5, NMOS FETs M6-M10, and inverters 520, 530, and 540 may constitute the C-element of the GABUF 500.

More specifically, the PMOS FETs M1 and M4 and the NMOS FETs M6 and M9 include gates coupled to an output of the buffer 510. Accordingly, the buffer 510 is configured to generate a delayed input signal “a_{d}” at the gates of FETs M1, M4, M6, and M9. The PMOS FETs M2 and M5 and the NMOS FETs M7 and M10 include gates configured to receive the input signal “a”.

The PMOS FET M1 includes a source coupled to an upper voltage rail Vdd and a drain coupled to a source of PMOS FET M5. The PMOS FET M2 includes a source coupled to the upper voltage rail Vdd and a drain coupled to a source of PMOS FET M4. The PMOS FETs M4 and M5 include drains coupled to an inverted output node Z_{b}. The inverter 520 includes an input coupled to the inverted output node Z_{b}, and an output coupled to a gate of PMOS FET M3. The PMOS FET M3 includes source/drain and drain/source coupled between the sources of PMOS FETs M4 and M5, respectively. The circuitry including the PMOS FETs M1-M5 and the inverter 520 may constitute a pull-up circuit to selectively pull up the inverted output node Z_{b} to Vdd potential.

The NMOS FET M6 includes a drain coupled to the inverted output node Z_{b} and a source coupled to a drain of NMOS FET M10. The NMOS FET M7 includes a drain coupled to the inverted output node Z_{b} and a source coupled to a drain of NMOS FET M9. The NMOS FETs M10 and M9 include sources coupled to a lower voltage rail Vss (e.g., ground). The inverter 540 includes an input coupled to the inverted output node Z_{b} and an output coupled to a gate of NMOS FET M8. The NMOS FET M8 includes drain/source and source/drain coupled between the sources of NMOS FETs M6 and M7, respectively. The circuitry including the NMOS FETs M6-M10 and the inverter 540 may constitute a pull-down circuit to selectively pull down the inverted output node Z_{b} to Vss potential.

The inverter 530 includes an input coupled to the inverted output node Z_{b}, and an output serving as the output of the GABUF 500 for generating the output signal “Z” thereat. The positive pulse propagation and suppression operation of the GABUF 500 is discussed below with reference to FIG. 5B. The negative pulse propagation and suppression operation of the GABUF 500 is discussed below with reference to FIG. 5C.

FIG. 5B illustrates a timing diagram of an example positive pulse propagation and suppression operation of the GABUFs 500 in accordance with another aspect of the disclosure. The x- or horizontal-axis of the timing diagram represents time, and the y- or vertical-axis of the timing diagram represents, from top to bottom, the logic states of the input signal “a”, the delayed input signal “a_{d}”, and the output signal “Z”, respectively.

According to the timing diagram, prior to time t₁, the input signal “a” and the delayed input signal “a_{d}” are both at logic zeros (0s) (e.g., Vss potential). The input signal “a”, being at a logic zero (0), turns on PMOS FETs M2 and M5 and turns off NMOS FETs M7 and M10. The delayed input signal “a_{d}” also being at a logic zero (0), turns on PMOS FETs M1 and M4 and turns off NMOS FETs M6 and M9. The turned-on PMOS FETs M1, M2, M4, and M5 pull up the inverted output node Z_{b} to Vdd potential, and the inverter 530 inverts the Vdd potential to generate the output signal “Z” as a logic zero (0), as shown in the timing diagram. The turned-off NMOS FETs M6, M7, M9, and M10 electrically isolate (decouple) the inverted output node Z_{b} from Vss potential. In this configuration, the inverters 520 and 540 apply Vss potential to the gates of PMOS FET M3 and NMOS FET M8, respectively.

At time t₁, the input signal “a” transitions to a logic one (1) in accordance with a first (positive) pulse. The input signal “a”, being at a logic one (1), turns off PMOS FETs M2 and M5, and turns on NMOS FETs M7 and M10. As PMOS FET M3 is turned on due to Vss potential being applied to its gate by inverter 520, the Vdd potential is still routed to the inverted output node Z_{b} via turned-on PMOS FETs M1, M3 and M4. However, as NMOS FET M8 is turned off due to Vss potential being applied to its gate by inverter 540, the inverted output node Z_{b} is still isolated from Vss potential. The input signal “a” and the delayed input signal “a_{d}” are at logic one (1) and logic zero (0) during time interval t₁−t₂, respectively. Thus, the GABUF 500 continues to generate the output signal “Z” at the previous state of a logic zero (0) during this interval.

At time t₂, after the buffer delay δ_{buf} from time t₁, the delay input signal “a_{d}” transitions to a logic one (1). The delay input signal “a_{d}”, being at a logic one (1), turns off PMOS FETs M1 and M4, and turns on NMOS FETs M6 and M9. The turned-on NMOS FETs M6, M7, M9, and M10 pull down the inverted output node Z_{b} to Vss potential, and the output inverter 530 inverts the Vss potential to generate the output signal “Z” at a logic one (1), as shown in the timing diagram. The turned-off PMOS FETs M1, M2, M4, and M5 electrically isolate the inverted output node Z_{b} from Vdd potential. In this configuration, the inverters 520 and 540 apply Vdd potential to the gates of PMOS FET M3 and NMOS FET M8, respectively. The input signal “a” and the delayed input signal “a_{d}” are both at logic ones (1s) during time interval t₂−t₃. Thus, the GABUF 500 generates the output signal “Z” at a logic one (1) during this (shaded) interval.

At time t₃, the input signal “a” transitions back to a logic zero (0). Accordingly, the input signal “a”, being at a logic zero (0), turns on PMOS FETs M2 and M5, and turns off NMOS FETs M7 and M10. As NMOS FET M8 is turned on due to Vdd potential being applied to its gate by inverter 540, the Vss potential is still routed to the inverted output node Z_{b} via turned-on NMOS FETs M9, M8 and M6. However, as PMOS FET M3 is turned off due to Vdd potential being applied to its gate by inverter 520, the inverted output node Z_{b} is still isolated from Vdd potential. The input signal “a” and the delayed input signal “a_{d}” are at logic zero (0) and logic one (1) during time interval t₃−t₄, respectively. Thus, the GABUF 500 continues to generate the output signal “Z” at the previous state of a logic one (1) during this interval.

At time t₄, the delayed input signal “a_{d}” transitions back to a logic zero (0). The input signal “a”, being at a logic zero (0), maintains PMOS FETs M2 and M5 turned on (and maintains NMOS FETs M7 and M10 turned off), and the delayed input signal “a_{d}” now being at a logic zero (0), turns on PMOS FETs M1 and M4 (and turns off NMOS FETs M6 and M9). The turned-on PMOS FETs M1, M2, M4, and M5 pull up the inverted output node Z_{b} to Vdd potential, and the output inverter 530 inverts the Vdd potential to generate the output signal “Z” at a logic zero (0), as shown in the timing diagram. The turned-off NMOS FETs M6, M7, M9, and M10 isolate the inverted output node Z_{b} from Vss potential.

Thus, the GABUF 500 propagates the first (positive) pulse of the input signal “a” to the output signal “Z” because the width w_glitch1 (t₃−t₁) of the first (positive) pulse is greater than the buffer delay δ_{buf} (t₂−t₁).

Further, according to this example, at time t₅, the input signal “a” transitions again to a logic one (1) in accordance with a second (positive) pulse. The input signal “a”, being at a logic one (1), turns off PMOS FETs M2 and M5, and turns on NMOS FETs M7 and M10. As PMOS FET M3 is turned on due to Vss potential being applied to its gate by inverter 520, the Vdd potential is still routed to the inverted output node Z_{b} via PMOS FETs M1, M3 and M4. However, as NMOS FET M8 is turned off due to Vss potential being applied to its gate by inverter 540, the inverted output node Z_{b} is still isolated from Vss potential. The input signal “a” and the delayed input signal “a_{d}” are at logic one (1) and logic zero (0) during time interval t₅−t₆, respectively. Thus, the GABUF 500 continues to generate the output signal “Z” at the previous state of a logic zero (0) during this interval.

At time t₆, the input signal “a” transitions back to a logic zero (0). The input signal “a”,

being at a logic zero (0) turns on PMOS FETs M2 and M5 (and turns off NMOS FETs M7 and M10). As the input signal “a” transitions back to logic zero (0) before the delayed input signal “a_{d}” transitions to a logic one (1) (because the width w_glitch2 of the second pulse is less than the buffer delay δ_{buf}), the delayed input signal “a_{d}” also being at a logic zero (0) maintains PMOS FETs M1 and M4 turned on (and maintains NMOS FETs M6 and M9 turned off). The turned-on PMOS FETs M1, M2, M4, and M5 continues to pull up the inverted output node Z_{b} to Vdd potential, and the output inverter 530 continues to invert the Vdd potential to generate the output signal “Z” at a logic zero (0), as shown in the timing diagram. The turned-off NMOS FETs M6, M7, M9, and M10 continue to isolate the inverted output node Z_{b} from Vss potential.

At time t₇, the delayed input signal “a_{d}” transitions to a logic one (1). The delayed input signal “a_{d}”, being at a logic one (1), turns off PMOS FETs M1 and M4, and turns on NMOS FETs M6 and M9. As PMOS FET M3 is still turned on due to Vss potential being applied to its gate by inverter 520, the Vdd potential is still routed to the inverted output node Z_{b} via PMOS FETs M2, M3 and M5. However, as NMOS FET M8 is turned off due to Vss potential being applied to its gate by inverter 540, the inverted output node Z_{b} is still isolated from Vss potential. The input signal “a” and the delayed input signal “a_{d}” are at logic zero (0) and logic one (1) during time interval t₇−t₈, respectively. Thus, the GABUF 500 continues to generate the output signal “Z” at the previous state of a logic zero (0) during this interval.

At time t₈, the delayed input signal “a_{d}” transitions back to a logic zero (0). The input signal “a”, being at a logic zero (0), maintains PMOS FETs M2 and M5 turned on (and maintains NMOS FETs M7 and M10 turned off), and the delayed input signal “a_{d}” now being at a logic zero (0), turns on PMOS FETs M1 and M4 (and turns off NMOS FETs M6 and M9). The turned-on PMOS FETs M1, M2, M4, and M5 continue to pull up the inverted output node Z_{b} to Vdd potential, and the output inverter 530 continues to invert the Vdd potential to generate the output signal “Z” at a logic zero (0), as shown in the timing diagram. The turned-off NMOS FETs M6, M7, M9, and M10 isolate the inverted output node Z_{b} from Vss potential.

Thus, the GABUF 500 suppresses the propagation of the second (positive) pulse of the input signal “a” to the output signal “Z” because the width w_glitch2 (t₆−t₅) of the second (positive) pulse is less than the buffer delay δ_{buf} (t₇−t₅).

FIG. 5C illustrates a timing diagram of an example negative pulse propagation and suppression operation of the GABUF 500 in accordance with another aspect of the disclosure. Similarly, the x- or horizontal-axis of the timing diagram represents time, and the y- or vertical-axis of the timing diagram represents, from top to bottom, the logic states of the input signal “a”, the delayed input signal “a_{d}”, and the output signal “Z”, respectively.

According to the timing diagram, prior to time t₉, the input signal “a” and the delayed input signal “a_{d}” are both at logic ones (1s). The input signal “a”, being at a logic one (1), turns on NMOS FETs M7 and M10 and turns off PMOS FETs M2 and M5. The delayed input signal “a_{d}”, also being at a logic one (1), turns on NMOS FETs M6 and M9 and turns off PMOS FETs M1 and M4. The turned-on NMOS FETs M6, M7, M9, and M10 pull down the inverted output node Z_{b} to Vss potential, and the output inverter 530 inverts the Vss potential to generate the output signal “Z” as a logic one (1), as shown in the timing diagram. The turned-off PMOS FETs M1, M2, M4, and M5 electrically isolate (decouple) the inverted output node Z_{b} from Vdd potential. In this configuration, the inverters 520 and 540 apply Vdd potential to the gates of PMOS FET M3 and NMOS FET M8, respectively.

At time t₉, the input signal “a” transitions to a logic zero (0) in accordance with a third (negative) pulse. The input signal “a”, being at a logic zero (0), turns off NMOS FETs M7 and M10, and turns on PMOS FETs M2 and M5. As NMOS FET M8 is turned on due to Vdd potential being applied to its gate by inverter 540, the Vss potential is still routed to the inverted output node Z_{b} via NMOS FETs M9, M8 and M6. However, as PMOS FET M3 is turned off due to Vdd potential being applied to its gate by inverter 520, the inverted output node Z_{b} is still isolated from Vdd potential. The input signal “a” and the delayed input signal “a_{d}” are at logic zero (0) and logic one (1) during time interval t₉−t₁₀, respectively. Thus, the GABUF 500 continues to generate the output signal “Z” at the previous state of a logic one (1) during this interval.

At time t₁₀, after the buffer delay δ_{buf} from time t₉, the delay input signal “a_{d}” transitions to a logic zero (0). The delay input signal “a_{d}”, being at a logic zero (0), turns off NMOS FETs M6 and M9, and turns on PMOS FETs M1 and M4. The turned-on PMOS FETs M1, M2, M4, and M5 pull up the inverted output node Z_{b} to Vdd potential, and the output inverter 530 inverts the Vdd potential to generate the output signal “Z” at a logic zero (0), as shown in the timing diagram. The turned-off NMOS FETs M6, M7, M9, and M10 isolate the inverted output node Z_{b} from Vss potential. In this configuration, the inverters 520 and 540 apply Vss potential to the gates of PMOS FET M3 and NMOS FET M8, respectively. The input signal “a” and the delayed input signal “a_{d}” are both at logic zeros (0s) during time interval t₁₀−t₁₁. Thus, the GABUF 500 generates the output signal “Z” at a logic zero (0) during this (shaded) interval.

At time t₁₁, the input signal “a” transitions back to a logic one (1). Accordingly, the input signal “a”, being at a logic one (1), turns on NMOS FETs M7 and M10, and turns off PMOS FETs M2 and M5. As PMOS FET M3 is turned on due to Vss potential being applied to its gate by inverter 520, the Vdd potential is still routed to the inverted output node Z_{b} via PMOS FETs M1, M3 and M4. However, as NMOS FET M8 is turned off due to Vss potential being applied to its gate by inverter 540, the inverted output node Z_{b} is still isolated from Vss potential. The input signal “a” and the delayed input signal “a_{d}” are at logic one (1) and logic zero (0) during time interval t₁₁−t₁₂, respectively. Thus, the GABUF 500 continues to generate the output signal “Z” at the previous state of a logic zero (0) during this interval.

At time t₁₂, the delayed input signal “a_{d}” transitions back to a logic one (1). The input signal “a”, being at a logic one (1), maintains NMOS FETs M7 and M10 turned on and maintains PMOS FETs M2 and M5 turned off. The delayed input signal “a_{d}”, now being at a logic one (1), turns on NMOS FETs M6 and M9 and turns off PMOS FETs M1 and M4. The turned-on NMOS FETs M6, M7, M9, and M10 pull down the inverted output node Z_{b} to Vss potential, and the output inverter 530 inverts the Vss potential to generate the output signal “Z” at a logic one (1), as shown in the timing diagram. The turned-off PMOS FETs M1, M2, M4, and M5 isolate the inverted output node Z_{b} from Vdd potential.

Thus, the GABUF 500 propagates the third (negative) pulse of the input signal “a” to the output signal “Z” because the width w_glitch3 (t₁₁−t₉) of the third (negative) pulse is greater than the buffer delay δ_{buf} (t₁₀−t₉).

Further, according to this example, at time t₁₃, the input signal “a” transitions again to a logic zero (0) in accordance with a fourth (negative) pulse. The input signal “a”, being at a logic zero (0), turns off NMOS FETs M7 and M10, and turns on PMOS FETs M2 and M5. As NMOS FET M8 is turned on due to Vdd potential being applied to its gate by inverter 540, the Vss potential is still routed to the inverted output node Z_{b} via NMOS FETs M9, M8 and M6. However, as PMOS FET M3 is turned off due to Vdd potential being applied to its gate by inverter 520, the inverted output node Z_{b} is still isolated from Vdd potential. The input signal “a” and the delayed input signal “a_{d}” are at logic zero (0) and logic one (1) during time interval t₁₃−t₁₄, respectively. Thus, the GABUF 500 continues to generate the output signal “Z” at the previous state of a logic one (1) during this interval.

At time t₁₄, the input signal “a” transitions back to a logic one (1). The input signal “a”, being at a logic one (1), turns on NMOS FETs M7 and M10 (and turns off PMOS FETs M2 and M5). As the input signal “a” transitions back to logic one (1) before the delayed input signal “a_{d}” transitions to a logic zero (0) (because the width w_glitch4 of the fourth pulse is less than the buffer delay δ_{buf}), the delayed input signal “a_{d}” also being at a logic one (1) maintains NMOS FETs M6 and M9 turned on (and maintains PMOS FETs M1 and M4 turned off). The turned-on NMOS FETs M6, M7, M9, and M10 continue to pull down the inverted output node Z_{b} to Vss potential, and the output inverter 530 continues to invert the Vss potential to generate the output signal “Z” at a logic one (1), as shown in the timing diagram. The turned-off PMOS FETs M1, M2, M4, and M5 continue to isolate the inverted output node Z_{b} from Vdd potential.

At time t₁₅, the delayed input signal “a_{d}” transitions to a logic zero (0). The delayed input signal “a_{d}”, being at a logic zero (0), turns off NMOS FETs M6 and M9, and turns on PMOS FETs M1 and M4. As NMOS FET M8 is still turned on due to Vdd potential being applied to its gate by inverter 540, the Vss potential is still routed to the inverted output node Z_{b} via NMOS FETs M10, M8 and M7. However, as PMOS FET M3 is turned off due to Vdd potential being applied to its gate by inverter 520, the inverted output node Z_{b} is still isolated from Vdd potential. The input signal “a” and the delayed input signal “a_{d}” are at logic one (1) and logic zero (0) during time interval t₁₅−t₁₆, respectively. Thus, the GABUF 500 continues to generate the output signal “Z” at the previous state of a logic one (1) during this interval.

At time t₁₆, the delayed input signal “a_{d}” transitions back to a logic one (1). The input signal “a”, being at a logic one (1), maintains NMOS FETs M7 and M10 turned on and maintains PMOS FETs M2 and M5 turned off. The delayed input signal “a_{d}”, also being at a logic one (1), turns on NMOS FETs M6 and M9 and turns off PMOS FETs M1 and M4. The turned-on NMOS FETs M6, M7, M9, and M10 continue to pull-down the inverted output node Z_{b} to Vss potential, and the output inverter 530 continues to invert the Vss potential to generate the output signal “Z” at a logic one (1), as shown in the timing diagram. The turned-off PMOS FETs M1, M2, M4, and M5 isolate the inverted output node Z_{b} from Vdd potential.

Thus, the GABUF 500 suppresses the propagation of the fourth (negative) pulse of the input signal “a” to the output signal “Z” because the width w_glitch4 (t₁₄−t₁₃) of the fourth (negative) pulse is less than the buffer delay δ_{buf} (t₁₅−t₁₃).

The GABUF 500 performs the operation of pulse propagation and suppression well. However, the GABUF 500 includes many components to perform its operation. For example, the GABUF 500 includes 16 transistors (e.g., five (5) PMOS FETs, five (5) NMOS FETs, and two FETs per inverter), in addition to the buffer 510. Accordingly, the GABUF 500 may occupy a significant integrated circuit (IC) footprint. The large number of transistors also causes the GABUF 500 to consume significant power, which has the drawback of limiting the number of GABUFs that may be implemented in a digital circuit that would save power vis-à-vis power consumed by unwanted glitches.

### Two-Input GABUF—First Implementation

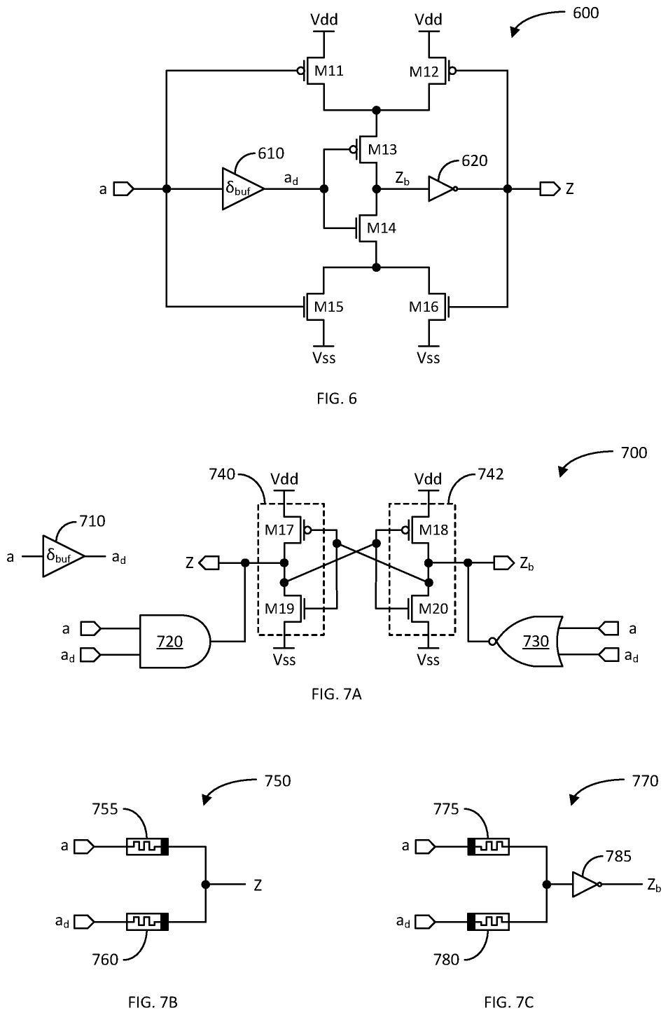

FIG. 6 illustrates a schematic diagram of another example two-input glitch absorbing buffer (GABUF) 600 in accordance with another aspect of the disclosure. The GABUF 600 may be configured to perform the pulse propagation and suppression operation of GABUF 500, while achieving this operation with significantly less components for power and IC footprint savings.

In particular, the GABUF 600 includes a delay element, such as a buffer 610, and a logic circuit including PMOS FETs M11, M12, and M13, NMOS FETs M14, M15, and M16, and an inverter 620. The PMOS FET M11 includes a source coupled to an upper voltage rail Vdd, and a gate configured to receive an input signal “a”. The PMOS FET M12 includes a source coupled to the upper voltage rail Vdd, and a gate configured to receive an output signal “Z”, and a drain coupled to a drain of the PMOS FET M11. The PMOS FET M13 includes a source coupled to the drains of PMOS FETs M11 and M12. The PMOS FETs M11 to M13 may constitute a pull-up circuit to selectively pull up an inverted output node Z_{b} to Vdd potential.

The NMOS FET M14 includes a drain coupled to a drain of PMOS FET M13, and a gate coupled to a gate of the PMOS FET M13. The inverted output node Z_{b} is at the drains of PMOS FET M13 and NMOS FET M14. The buffer 610 includes an input configured to receive the input signal “a”, and an output coupled to the gates of the PMOS FET M13 and NMOS FET M14 to produce a delayed input signal “a_{d}” thereat. Similarly, the buffer 610 is configured to delay the input signal “a” by a delay δ_{buf} to generate the delayed input signal “a_{d}”. The inverter 620 includes an input coupled to the inverted output node Z_{b} (drains of PMOS FET M13 and NMOS FET M14), and an output configured to produce the output signal “Z”.

The NMOS FET M15 includes a drain coupled to a source of the NMOS FET M14, a gate configured to receive the input signal “a”, and a source coupled to a lower voltage rail Vss. The NMOS FET M16 includes a drain coupled to the source of the NMOS FET M14, a gate configured to receive the output signal “Z”, and a source coupled to the lower voltage rail Vss. The NMOS FETs M14 to M16 may constitute a pull-down circuit to selectively pull down the inverted output node Z_{b} to Vss potential. The operation of the GABUF 600 is discussed below with further reference to the timing diagrams of FIGS. 5B-5C.

According to the timing diagram of FIG. 5B, prior to time t₁, the input signal “a”, the delayed input signal “a_{d}”, and the output signal “Z” are all at logic zeros (0s) (e.g., Vss potential). The input signal “a”, being at a logic zero (0), turns on PMOS FET M11 and turns off NMOS FET M15. The delayed input signal “a_{d}”, also being at a logic zero (0), turns on PMOS FET M13 and turns off NMOS FET M14. The output signal “Z”, also being at a logic zero (0), turns on PMOS FET M12 and turns off NMOS FET M16. Accordingly, the turned-on PMOS FETs M11, M12, and M3 pull up the inverted output node Z_{b} to Vdd potential, and the inverter 620 inverts the Vdd potential to generate the output signal “Z” at a logic zero (0), as shown in the timing diagram. The turned-off NMOS FETs M14, M15, and M16 electrically isolate (decouple) the inverted output node Z_{b} from Vss potential.

At time t₁, the input signal “a” transitions to a logic one (1) in accordance with a first (positive) pulse. The input signal “a”, being at a logic one (1), turns off PMOS FET M1 l and turns on NMOS FET M15. As PMOS FET M12 is still turned on due to the logic zero (0) of the output signal “Z” applied to its gate, the Vdd potential is still routed to the inverted output node Z_{b} via turned-on PMOS FETs M12 and M13. As NMOS FET M14 is still turned off due to the logic zero (0) of the delayed input signal “a_{d}”, the inverted output node Z_{b} is still isolated from Vss potential. The input signal “a” and the delayed input signal “a_{d}” are at logic one (1) and logic zero (0) during time interval t₁−t₂, respectively. Thus, the GABUF 600 continues to generate the output signal “Z” at the previous state of a logic zero (0) during this interval.

At time t₂, after the buffer delay δ_{buf} from time t₁, the delay input signal “a_{d}” transitions to a logic one (1). The delay input signal “a_{d}”, being at a logic one (1), turns off PMOS FET M13 and turns on NMOS FET M14. The turned-on NMOS FETs M14 and M15 pull down the inverted output node Z_{b} to Vss potential, and the inverter 620 inverts the Vss potential to generate the output signal “Z” at a logic one (1), as shown in the timing diagram. The output signal “Z”, being at a logic one (1), turns off PMOS FET M12 and turns on NMOS FET M16. The turned-off PMOS FETs M11, M12, and M13 electrically isolate (decouple) the inverted output node Z_{b} from Vdd potential. The input signal “a” and the delayed input signal “a_{d}” are both at logic ones (1s) during time interval t₂−t₃. Thus, the GABUF 600 generates the output signal “Z” at a logic one (1) during this (shaded) interval.

At time t₃, the input signal “a” transitions back to a logic zero (0). Accordingly, the input signal “a”, being at a logic zero (0), turns on PMOS FET M11 and turns off NMOS FET M15. As NMOS FETs M14 and M16 are still turned on due to the delayed input signal “a_{d}” and the output signal “Z” being logic ones (1s), the Vss potential is still routed to the inverted output node Z_{b} via NMOS FETs M16 and M14. As PMOS FET M13 is still turned off due to the delayed input signal “a_{d}” being a logic one (1), the inverted output node Z_{b} is still isolated from Vdd potential. The input signal “a” and the delayed input signal “a_{d}” are at logic zero (0) and logic one (1) during time interval t₃−t₄, respectively. Thus, the GABUF 600 continues to generate the output signal “Z” at the previous state of a logic one (1) during this interval.

At time t₄, the delayed input signal “a_{d}” transitions back to a logic zero (0). The input signal “a”, being at a logic zero (0), maintains PMOS FET M1 l turned on and maintains NMOS FET M15 turned off, and the delayed input signal “a_{d}” now being at a logic zero (0), turns on PMOS FET M13 and turns off NMOS FET M14. The turned-on PMOS FETs M11 and M13 pull up the inverted output node Z_{b} to Vdd potential, and the inverter 620 inverts the Vdd potential to generate the output signal “Z” at a logic zero (0), as shown in the timing diagram. The output signal “Z”, being a logic zero (0), turn on PMOS FET M12 and turns off NMOS FET M16. The turned-off NMOS FETs M14, M15, and M16 isolate the inverted output node Z_{b} from Vss potential.

Thus, the GABUF 600 propagates the first (positive) pulse of the input signal “a” to the output signal “Z” because the width w_glitch1 (t₃−t₁) of the first (positive) pulse is greater than the buffer delay δ_{buf} (t₂−t₁).

Further, according to this example, at time t₅, the input signal “a” transitions again to a logic one (1) in accordance with a second (positive) pulse. The input signal “a”, being at a logic one (1), turns off PMOS FET M11 and turns on NMOS FET M15. As PMOS FET M12 is still turned on due to the logic zero (0) of the output signal “Z” applied to its gate, the Vdd potential is still routed to the inverted output node Z_{b} via PMOS FETs M12 and M13. As NMOS FET M14 is still turned off due to the logic zero (0) of the delayed input signal “a_{d}”, the inverted output node Z_{b} is still isolated from Vss potential. The input signal “a” and the delayed input signal “a_{d}” are at logic one (1) and logic zero (0) during time interval t₅−t₆, respectively. Thus, the GABUF 600 continues to generate the output signal “Z” at the previous state of a logic zero (0) during this interval.

At time t₆, the input signal “a” transitions again to a logic zero (0) in accordance with the second pulse. The input signal “a”, being at a logic zero (0) turns on PMOS FET M11 and turns off NMOS FET M15. As the input signal “a” transitions back to logic zero (0) before the delayed input signal “a_{d}” transitions to a logic one (1) (because the width w_glitch2 of the second pulse is less than the buffer delay δ_{buf}), the delayed input signal “a_{d}”, also being at a logic zero (0), maintains PMOS FET M13 turned on and NMOS FET M14 turned off. The output signal “Z” still being at a logic zero (0) turns on PMOS FET M12 and turns off NMOS FET M16. Accordingly, the turned-on PMOS FETs M11, M12, and M3 continue to pull up the inverted output node Z_{b} to Vdd potential, and the inverter 620 continues to invert the Vdd potential to generate the output signal “Z” as a logic zero (0), as shown in the timing diagram. The turned-off NMOS FETs M14, M15, and M16 electrically isolate the inverted output node Z_{b} from Vss potential.

At time t₇, after the buffer delay δ_{buf} from time t₅, the delay input signal “a_{d}” transitions to a logic one (1). The delay input signal “a_{d}”, being at a logic one (1), turns off PMOS FET M13 and turns on NMOS FET M14. However, the NMOS FETs M15 and M16 are still turned off due to the logic zeros (0s) still present in the input signal “a” and the output signal “Z”, respectively. Accordingly, the inverted output node Z_{b} is tristated, and capacitively holds the Vdd potential. The inverter 620 continues to invert the Vdd potential to generate the output signal “Z” at the previous state of a logic zero (0), as shown in the timing diagram.

At time t₈, the delayed input signal “a_{d}” transitions back to a logic zero (0). The delayed input signal “a_{d}”, now being at a logic zero (0), turns on PMOS FET M13 and turns off NMOS FET M14. As PMOS FETs M11 and M12 are already turned on, the turned-on PMOS FET M13 pulls up the inverted output node Z_{b} to Vdd potential, and the inverter 620 inverts the Vdd potential to generate the output signal “Z” at a logic zero (0), as shown in the timing diagram. The turned-off NMOS FETs M14, M15, and M16 isolate the inverted output node Z_{b} from Vss potential.

Thus, the GABUF 600 suppresses the propagation of the second (positive) pulse of the input signal “a” to the output signal “Z” because the width w_glitch2 (t₆−t₅) of the second (positive) pulse is less than the buffer delay δ_{buf} (t₇−t₅).

According to the timing diagram of FIG. 5C, prior to time t₉, the input signal “a”, the delayed input signal “a_{d}”, and the output signal “Z” are all at logic ones (1s). The input signal “a”, being at a logic one (1), turns off PMOS FET M1 l and turns on NMOS FET M15. The delayed input signal “a_{d}”, also being at a logic one (1), turns off PMOS FET M13 and turns on NMOS FET M14. The output signal “Z”, being at a logic one (1), turns off PMOS FET M12 and turns on NMOS FET M16. The turned-on NMOS FETs M14, M15, and M16 pull down the inverted output node Z_{b} to Vss potential, and the inverter 620 inverts the Vss potential to generate the output signal “Z” as a logic one (1), as shown in the timing diagram. The turned-off PMOS FETs M11, M12, and M13 electrically isolate (decouple) the inverted output node Z_{b} from Vdd potential.

At time t₉, the input signal “a” transitions to a logic zero (0) in accordance with a third

(negative) pulse. The input signal “a”, being at a logic zero (0), turns on PMOS FET M11 and turns off NMOS FET M15. However, as NMOS FETs M14 and M16 are still turned on due to the delayed input signal “a_{d}” and the output signal “Z” both being at logic ones (1s), the Vss potential is still routed to the inverted output node Z_{b} via NMOS FETs M16 and M14. Also, as PMOS FET M13 is still turned off due to the delayed input signal “a_{d}” being a logic one (1), the inverted output node Z_{b} is still isolated from Vdd potential. The input signal “a” and the delayed input signal “a_{d}” are at logic zero (0) and logic one (1) during time interval t₉−t₁₀, respectively. Thus, the GABUF 600 continues to generate the output signal “Z” at the previous state of a logic one (1) during this interval.

At time t₁₀, after the buffer delay δ_{buf} from time t₉, the delay input signal “a_{d}” transitions to a logic zero (0). The delay input signal “a_{d}”, being at a logic zero (0), turns on PMOS FET M13 and turns off NMOS FET M14. The turned-on PMOS FETs M1 l and M13 pull up the inverted output node Z_{b} to Vdd potential, and the inverter 620 inverts the Vdd potential to generate the output signal “Z” at a logic zero (0), as shown in the timing diagram. The turned-off NMOS FETs M14, M15, and M16 isolate the inverted output node Z_{b} from Vss potential. The input signal “a” and the delayed input signal “a_{d}” are both at logic zeros (0s) during time interval t₁₀−t₁₁. Thus, the GABUF 600 generates the output signal “Z” at a logic zero (0) during this (shaded) interval.

At time t₁₁, the input signal “a” transitions back to a logic one (1). Accordingly, the input signal “a”, being at a logic one (1), turns off PMOS FET M11 and turns on NMOS FET M15. As PMOS FETs M12 and M13 are turned on due to the logic zeros (0s) present in the output signal “Z” and the delayed input signal “a_{d}”, the Vdd potential is still routed to the inverted output node Z_{b} via PMOS FETs M12 and M13. However, as NMOS FET M14 is turned off due to the logic zero (0) present in the delayed input signal “a_{d}”, the inverted output node Z_{b} is still isolated from Vss potential. The input signal “a” and the delayed input signal “a_{d}” are at logic one (1) and logic zero (0) during time interval t₁₁−t₁₂, respectively. Thus, the GABUF 600 continues to generate the output signal “Z” at the previous state of a logic zero (0) during this interval.

At time t₁₂, the delayed input signal “a_{d}” transitions back to a logic one (1). The input signal “a”, being at a logic one (1), maintains PMOS FET M11 turned off and NMOS FET M15 turned on, and the delayed input signal “a_{d}”, now being at a logic one (1), turns off PMOS FET M13 and turns on NMOS FET M14. The turned-on NMOS FETs M14 and M15 pull down the inverted output node Z_{b} to Vss potential, and the inverter 620 inverts the Vss potential to generate the output signal “Z” at a logic one (1), as shown in the timing diagram. The turned-off PMOS FETs M11, M12, and M15 isolate the inverted output node Z_{b} from Vdd potential.

Thus, the GABUF 600 propagates the third (negative) pulse of the input signal “a” to the output signal “Z” because the width w_glitch3 (t₁₁−t₉) of the third (negative) pulse is greater than the buffer delay δ_{buf} (t₁₀−t₉).

Further, according to this example, at time t₁₃, the input signal “a” transitions again to a logic zero (0) in accordance with a fourth (negative) pulse. The input signal “a”, being at a logic zero (0), turns on PMOS FET M11 and turns off NMOS FET M15. As NMOS FETs M14 and M16 are turned on due to the delay input signal “a_{d}” and the output signal “Z” being at logic ones (1s), the Vss potential is still routed to the inverted output node Z_{b} via NMOS FETs M14 and M16. However, as PMOS FET M13 is turned off due to the delay input signal “a_{d}” being a logic one (1), the inverted output node Z_{b} is still isolated from Vdd potential. The input signal “a” and the delayed input signal “a_{d}” are at logic zero (0) and logic one (1) during time interval t₁₃−t₁₄, respectively. Thus, the GABUF 600 continues to generate the output signal “Z” at the previous state of a logic one (1) during this interval.

At time t₁₄, the input signal “a” transitions back to a logic one (1). The input signal “a”,

being at a logic one (1), turns off PMOS FET M11 and turns on NMOS FET M14. As the input signal “a” transitions back to logic one (1) before the delayed input signal “a_{d}” transitions to a logic zero (0) (because the width w_glitch4 of the fourth pulse is less than the buffer delay δ_{buf}), the delayed input signal “a_{d}” also being at a logic one (1) maintains NMOS FET M14 turned on and PMOS FET M13 turned off. The turned-on NMOS FETs M14, M15, and M16 continue to pull down the inverted output node Z_{b} to Vss potential, and the inverter 620 continues to invert the Vss potential to generate the output signal “Z” at a logic one (1), as shown in the timing diagram. The turned-off PMOS FETs M11, M22, and M13 continue to isolate the inverted output node Z_{b} from Vdd potential.

At time t₁₅, the delayed input signal “a_{d}” transitions to a logic zero (0). The delayed input signal “a_{d}”, being at a logic zero (0), turns on PMOS FET M13 and turns off NMOS FET M14. As PMOS FETs M1 l and M12 are turned off due to the input signal “a” and the output signal “Z” being at logic ones (1s), the inverted output node Z_{b} is tristated, and retains its Vss potential. The inverter 620 continues to invert the Vss potential to generate the output signal “Z” at the previous state of a logic one (1), as shown in the timing diagram. The input signal “a” and the delayed input signal “a_{d}” are at logic one (1) and logic zero (0) during time interval t₁₅−t₁₆, respectively. Thus, the GABUF 600 continues to generate the output signal “Z” at the previous state of a logic one (1) during this interval.

At time t₁₆, the delayed input signal “a_{d}” transitions back to a logic one (1). The input signal “a”, being at a logic one (1), maintains PMOS FET M11 turned off and NMOS FET M15 turned on, and the delayed input signal “a_{d}” also being at a logic one (1) turns off PMOS FET M13 and turns on NMOS FET M13. The turned-on NMOS FETs M14, M15, and M16 pull down the inverted output node Z_{b} to Vss potential, and the inverter 620 continues to invert the Vss potential to generate the output signal “Z” at a logic one (1), as shown in the timing diagram. The turned-off PMOS FETs M11, M12, and M13 isolate the inverted output node Z_{b} from Vdd potential.

Thus, the GABUF 600 suppresses the propagation of the fourth (negative) pulse of the input signal “a” to the output signal “Z” because the width w_glitch4 (t₁₄−t₁₃) of the fourth (negative) pulse is less than the buffer delay δ_{buf} (t₁₅−t₁₃).

Comparing the GABUF 600 with the GABUF 500, the GABUF 600 includes eight (8) transistors compared to 16 transistors in GABUF 500. Thus, the GABUF 600 may occupy significantly less IC footprint, consume significantly less power, and may be included more in a digital circuit without drawing significant power vis-à-vis the power savings due to reduction in unwanted glitches.

### Two-Input GABUF—Second Implementation

FIG. 7A illustrates a schematic diagram of another example two-input glitch absorbing buffer (GABUF) 700 in accordance with another aspect of the disclosure. The GABUF 700 may also be configured to perform the pulse propagation and suppression operation of GABUF 500, while achieving this operation with significantly less components for power and IC footprint savings.

In particular, the GABUF 700 includes a delay element, such as a buffer 710, configured to delay an input signal “a” by δ_{buf} to generate a delayed input signal “a_{d}”. The GABUF 700 further includes a logic circuit including an AND gate 720 with inputs configured to receive the input signal “a” and the delayed input signal “a_{d}”, respectively. Additionally, the logic circuit includes a NOR gate 730 (e.g., an OR gate followed by an inverter) with inputs configured to receive the input signal “a” and the delayed input signal “a_{d}”, respectively.

Further, the logic circuit includes a data storage cell in the form of cross-coupled first and second inverters 740 and 742. The first inverter 740 includes a PMOS FET M17 and an NMOS FET M19 coupled in series between an upper voltage rail Vdd and a lower voltage rail Vss. The second inverter 742 includes a PMOS FET M18 and an NMOS FET M20 coupled in series between the upper voltage rail Vdd and the lower voltage rail Vss.

More specifically, the PMOS FET M17 includes a source coupled to the upper voltage rail Vdd, a gate coupled to drains of PMOS FET M18 and NMOS FET M20, and a drain coupled to a drain of NMOS FET M19. The NMOS FET M19 includes a gate coupled to the drains of PMOS FET M18 and NMOS FET M20, and a source coupled to the lower voltage rail Vss. Similarly, the PMOS FET M18 includes a source coupled to the upper voltage rail Vdd, a gate coupled to the drains of PMOS FET M17 and NMOS FET M19, and the drain coupled to the drain of NMOS FET M20. The NMOS FET M20 includes a gate coupled to the drains of PMOS FET M17 and NMOS FET M19, and a source coupled to the lower voltage rail Vss.

The first and second inverters 740 and 742 are cross-coupled because the output (drains of FETs M17/M19) of the first inverter 740 is coupled to the input (gates of FETs M18/M20) of the second inverter 742, and the output (drains of FETs M18/M20) of the second inverter 742 is coupled to the input (gates of FETs M17/M19) of the first inverter 740. The AND gate 720 includes an output coupled to the output (drains of FETs M17/M19) of the first inverter 740, and the NOR gate 730 includes an output coupled to the output (drains of FETs M18/M20) of the second inverter 742. The output of the first inverter 740 is configured to generate an output signal “Z”, and the output of the second inverter 742 is configured to generate a complementary output signal “Z_{b} ”. The operation of the GABUF 700 is discussed below with further reference to the timing diagrams of FIGS. 5B-5C.

According to the timing diagram of FIG. 5B, prior to time t₁, the input signal “a”, the delayed input signal “a_{d}”, and the output signal “Z” are all at logic zeros (0s) (e.g., Vss potential). The input signal “a” and the delayed input signal “a_{d}”, both at logic zeros (0s), cause the AND gate 720 to output a logic zero (0), which is consistent with the output signal “Z” being at a logic zero (0). Similarly, the input signal “a” and the delayed input signal “a_{d}”, both being at logic zeros (0s), cause the NOR gate 730 to output a logic one (1), which is consistent with the complementary output signal “Z_{b} ” being at a logic one (1). Similarly, the output signal “Z” being at a logic zero (0), being applied to the input of the second inverter 742, causes the second inverter 742 to generate the complementary output signal “Z_{b} ” at a logic one (1), and the complementary output signal “Z_{b} ” being at a logic one (1), being applied to the input of the first inverter 740, causes the first inverter 740 to generate the output signal “Z” at a logic zero (0).

At time t₁, the input signal “a” transitions to a logic one (1) in accordance with a first (positive) pulse. In response, the AND gate 720 continues to generate the output signal “Z” at the previous state of a logic zero (0), as indicated in the timing diagram; and the NOR gate 730 attempts to generate the complementary output signal “Z_{b} ” as a logic zero (0). However, the PMOS FETs M17 and M18 of the cross-coupled inverters 740 and 742 are made stronger (with a larger channel width to length ratio) than the NMOS FETs (not shown) of the AND gate 720 and NOR gate 730 (e.g., the turn-on resistances of the PMOS FETs M17 and M18 are less than the turn-on resistances of the NMOS FETs of the AND gate 720 and the NOR gate 730). Accordingly, the output signal “Z” at a logic zero (0) causes the stronger PMOS FET M18 to turn on and maintain the complementary output signal “Z_{b} ” at a logic one (1), although the NOR gate 730 is attempting to pull down the complementary output signal “Z_{b}”.

At time t₂, after the buffer delay δ_{buf} from time t₁, the delayed input signal “a_{d}” transitions to a logic one (1). In response, the AND gate 720 generates the output signal “Z” as a logic one (1) as indicated in the timing diagram, and the NOR gate 730 generates the complementary output signal “Z_{b} ” as a logic zero (0). The output signal “Z” at a logic one (1), being applied to the input of the second inverter 742, causes the second inverter 742 to generate the complementary output signal “Z_{b} ” at a logic zero (0), and the complementary output signal “Z_{b} ” at a logic zero (0), being applied to the input of the first inverter 740, causes the first inverter 740 to generate the output signal “Z” at a logic one (1).

At time t₃, the input signal “a” transitions back to a logic zero (0). In response, the NOR gate 730 continues to generate the complementary output signal “Z_{b} ” at a logic zero (0), which maintains the PMOS FET M17 of the first inverter 740 turned on. The AND gate 720 attempts to generate the output signal “Z” as a logic zero (0). However, as the PMOS FET M17 of the first inverter 740 is stronger than the pull-down NMOS FET (or device) of the AND gate 720, the output signal “Z” is maintained at the previous state of a logic one (1), as indicated in the timing diagram.

At time t₄, the delayed input signal “a_{d}” transitions back to a logic zero (0). As both the input signal “a” and the delayed input signal “a_{d}” are at logic zeros (0s), the AND gate 720 generate the output signal “Z” as a logic zero (0), as indicated in the timing diagram. Similarly, the input signal “a” and the delayed input signal “a_{d}”, both being at logic zeros (0s), cause the NOR gate 730 to output a logic one (1), which is consistent with the complementary output signal “Z_{b} ” being at a logic one (1). The output signal “Z” at a logic zero (0), being applied to the input of the second inverter 742, causes the second inverter 742 to generate the complementary output signal “Z_{b} ” at a logic one (1), and the complementary output signal “Z_{b} ” at a logic one (1), being applied to the input of the first inverter 740, causes the first inverter 740 to generate the output signal “Z” at a logic zero (0).

Thus, the GABUF 700 propagates the first (positive) pulse of the input signal “a” to the output signal “Z” because the width w_glitch1 (t₃−t₁) of the first (positive) pulse is greater than the buffer delay δ_{buf} (t₂−t₁).

Further, according to this example, at time t₅, the input signal “a” transitions to a logic one (1) in accordance with a second (positive) pulse. In response, the AND gate 720 continues to generate the output signal “Z” at the previous state of a logic zero (0), as indicated in the timing diagram. Similarly, the NOR gate 730 attempts to generate the complementary output signal “Z_{b} ” as a logic zero (0). However, as previously discussed, the PMOS FET M18 of the second inverter 742 is stronger than the pull-down NMOS FET (or device) of the NOR gate 730. Accordingly, the output signal “Z” at a logic zero (0) maintains PMOS FET M18 turned on to maintain the complementary output signal “Z_{b} ” at a logic one (1), although the NOR gate 730 is attempting to pull down the complementary output signal “Z_{b}”.

At time t₆, the input signal “a” transitions back to a logic zero (0) before the delayed input signal “a_{d}” transitions to a logic one (1) because the width w_glitch2 of the second pulse is less than the buffer delay δ_{buf}. Accordingly, the input signal “a” and the delayed input signal “a_{d}”, both at logic zeros (0s), cause the AND gate 720 to output a logic zero (0), which is consistent with the output signal “Z” being at a logic zero (0), as indicated by the timing diagram. Similarly, the input signal “a” and the delayed input signal “a_{d}”, both being at logic zeros (0s), cause the NOR gate 730 to output a logic one (1), which is consistent with the complementary output signal “Z_{b} ” being at a logic one (1). Similarly, the output signal “Z” being at a logic zero (0), being applied to the input of the second inverter 742, causes the second inverter 742 to generate the complementary output signal “Z_{b} ” at a logic one (1), and the complementary output signal “Z_{b} ” being at a logic one (1), being applied to the input of the first inverter 740, causes the first inverter 740 to generate the output signal “Z” at a logic zero (0).

At time t₇, after the buffer delay δ_{buf} from time t₅, the delayed input signal “a_{d}” transitions to a logic one (1). In response, the AND gate 720 continues to generate the output signal “Z” at the previous state of a logic zero (0), as indicated in the timing diagram. The NOR gate 730 attempts to generate the complementary output signal “Z_{b} ” as a logic zero (0). However, as previously discussed, the PMOS FET M18 of the second inverter 742 is stronger than the pull-down NMOS FET (or device) of the NOR gate 730. Accordingly, the output signal “Z” at a logic zero (0) maintains PMOS FET M18 turned on to maintain the complementary output signal “Z_{b} ” at a logic one (1), although the NOR gate 730 is attempting to pull down the complementary output signal “Z_{b}”.

At time t₈, the delayed input signal “a_{d}” transitions back to a logic zero (0). As both the input signal “a” and the delayed input signal “a_{d}” are at logic zeros (0s), the AND gate 720 generates the output signal “Z” as a logic zero (0), as indicated in the timing diagram. Similarly, the input signal “a” and the delayed input signal “a_{d}”, both being at logic zeros (0s), cause the NOR gate 730 to output a logic one (1), which is consistent with the complementary output signal “Z_{b} ” being at a logic one (1). The output signal “Z” at a logic zero (0), being applied to the input of the second inverter 742, causes the second inverter 742 to generate the complementary output signal “Z_{b} ” at a logic one (1), and the complementary output signal “Z_{b} ” at a logic one (1), being applied to the input of the first inverter 740, causes the first inverter 740 to generate the output signal “Z” at a logic zero (0).

Thus, the GABUF 700 suppresses the propagation of the second (positive) pulse of the input signal “a” to the output signal “Z” because the width w_glitch2 (t₆−t₅) of the second (positive) pulse is less than the buffer delay δ_{buf} (t₇−t₅).

According to the timing diagram of FIG. 5C, prior to time t₉, the input signal “a”, the delayed input signal “a_{d}”, and the output signal “Z” are all at logic ones (1s) (e.g., Vdd potential). The input signal “a” and the delayed input signal “a_{d}”, both at logic ones (1s), cause the AND gate 720 to output a logic one (1), which is consistent with the output signal “Z” being at a logic one (1). Similarly, the input signal “a” and the delayed input signal “a_{d}”, both at logic ones (1s), cause the NOR gate 730 to output a logic zero (0), which is consistent with the complementary output signal “Z_{b} ” being at a logic zero (0). Similarly, the output signal “Z” being at a logic one (1), being applied to the input of the second inverter 742, causes the second inverter 742 to generate the complementary output signal “Z_{b} ” at a logic zero (0), and the complementary output signal “Z_{b} ” being at a logic zero (0), being applied to the input of the first inverter 740, causes the first inverter 740 to generate the output signal “Z” at a logic one (1).

At time t₉, the input signal “a” transitions to a logic zero (0) in accordance with a third (negative) pulse. In response, the NOR gate 730 continues to generate the complementary output signal “Z_{b} ” at the previous state of a logic zero (0); and the AND gate 730 attempts to generate the output signal “Z” as a logic zero (0). However, the PMOS FET M17 of the inverter 740 is stronger than the pull-down NMOS FET (or device) of the AND gate 720. Thus, the complementary output signal “Z_{b} ” at a logic zero (0) turns on PMOS FET M17 to continue to generate the output signal “Z” at the previous state of a logic one (1) as indicated in the timing diagram, even though the AND gate 720 is attempting to pull down the output signal “Z” to a logic zero (0).

At time t₁₀, after the buffer delay δ_{buf} from time t₉, the delayed input signal “a_{d}” transitions to a logic zero (0). In response, the AND gate 720 generates the output signal “Z” as a logic zero (0) as indicated in the timing diagram, and the NOR gate 730 generates the complementary output signal “Z_{b} ” as a logic one (1). The output signal “Z” at a logic zero (0), being applied to the input of the second inverter 742, causes the second inverter 742 to generate the complementary output signal “Z_{b} ” at a logic one (1), and the complementary output signal “Z_{b} ” at a logic one (1), being applied to the input of the first inverter 740, causes the first inverter 740 to generate the output signal “Z” at a logic zero (0).

At time t₁₁, the input signal “a” transitions back to a logic one (1), and the delayed input signal “a_{d}” is still at logic zero (0). In response, the AND gate 720 generates the output signal “Z” at the previous state of a logic zero (0), as indicated in the timing diagram. The output signal “Z”, being at a logic zero (0), turns on PMOS FET M18 of the second inverter 742. In response to a=1 and a_{d}=0, the NOR gate 730 attempts to generate the complementary output signal “Z_{b} ” as a logic zero (0). However, as the turned-on PMOS FET M18 is stronger than the pull-down NMOS FET (or device) of the NOR gate 730, the complementary output signal “Z_{b} ” is maintained at the previous state of a logic one (1).

At time t₁₂, the delayed input signal “a_{d}” transitions back to a logic one (1). As both the input signal “a” and the delayed input signal “a_{d}” are at logic ones (1s), the AND gate 720 outputs a logic one (1), as indicated in the timing diagram. Similarly, the input signal “a” and the delayed input signal “a_{d}”, both being at logic ones (1s), cause the NOR gate 730 to output a logic zero (0). The output signal “Z” at a logic one (1), being applied to the input of the second inverter 742, causes the second inverter 742 to generate the complementary output signal “Z_{b} ” at a logic zero (0), and the complementary output signal “Z_{b} ” at a logic zero (0), being applied to the input of the first inverter 740, causes the first inverter 740 to generate the output signal “Z” at a logic one (1).

Thus, the GABUF 700 propagates the third (negative) pulse of the input signal “a” to the output signal “Z” because the width w_glitch3 (t₁₁−t₉) of the third (negative) pulse is greater than the buffer delay δ_{buf} (t₁₀−t₉).

Further, according to this example, at time t₁₃, the input signal “a” transitions to a logic zero (0) in accordance with a fourth (negative) pulse. In response, the NOR gate 730 continues to generate the complementary output signal “Z_{b} ” at the previous state of a logic zero (0). In response to a=1 and ad=0, the AND gate 720 attempts to generate the output signal “Z” as a logic zero (0). However, the PMOS FET M17 of the second inverter 742, which is turned on by the logic zero (0) generated by the NOR gate 730, is stronger than the pull-down NMOS FET (or device) of the AND gate 720. Accordingly, the output signal “Z” remains at the previous state of a logic one (1), as indicated in the timing diagram.

At time t₁₄, the input signal “a” transitions back to a logic one (1) before the delayed input signal “a_{d}” transitions to a logic zero (0) because the width w_glitch4 of the fourth pulse is less than the buffer delay δ_{buf}. Accordingly, the input signal “a” and the delayed input signal “a_{d}”, both at logic ones (1s), cause the AND gate 720 to output a logic one (1), as indicated by the timing diagram. Similarly, the input signal “a” and the delayed input signal “a_{d}”, both at logic ones (1s), cause the NOR gate 730 to output a logic zero (0). Similarly, the output signal “Z” being at a logic one (1), being applied to the input of the second inverter 742, causes the second inverter 742 to generate the complementary output signal “Z_{b} ” at a logic zero (0), and the complementary output signal “Z_{b} ” being at a logic zero (0), being applied to the input of the first inverter 740, causes the first inverter 740 to generate the output signal “Z” at a logic one (1).

At time t₁₅, after the buffer delay δ_{buf} from time t₁₃, the delayed input signal “a_{d}” transitions to a logic zero (0). In response, the NOR gate 730 generates the complementary output signal “Z_{b} ” at the previous state of a logic zero (0). The AND gate 720 attempts to generate the output signal “Z” as a logic zero (0). However, as previously discussed, the PMOS FET M17 of the first inverter 740, being turned on by the complementary output signal “Z_{b} ” being a logic zero (0), is stronger than the pull-down NMOS FET (or device) of the AND gate 720. Accordingly, the output signal “Z” remains at the previous state of a logic one (1) as indicated by the timing diagram.

At time t₁₆, the delayed input signal “a_{d}” transitions back to a logic one (1). As both the input signal “a” and the delayed input signal “a_{d}” are at logic ones (1s), the AND gate 720 outputs a logic one (1), as indicated in the timing diagram. Similarly, the input signal “a” and the delayed input signal “a_{d}”, both at logic ones (1s), cause the NOR gate 730 to output a logic zero (0). The cross-coupled inverters 740 and 742 hold the Z=1 and Z_{b} =0 logic states: the output signal “Z” at a logic one (1), being applied to the input of the second inverter 742, causes the second inverter 742 to generate the complementary output signal “Z_{b}” at a logic zero (0), and the complementary output signal “Z_{b}” at a logic zero (0), being applied to the input of the first inverter 740, causes the first inverter 740 to generate the output signal “Z” at a logic one (1).

Thus, the GABUF 700 suppresses the propagation of the fourth (negative) pulse of the input signal “a” to the output signal “Z” because the width w_glitch4 (t₁₄−t₁₃) of the fourth (negative) pulse is less than the buffer delay δ_{buf} (t₁₅−t₁₃).

FIG. 7B illustrates a schematic diagram of an example two-input logic AND gate 750 in accordance with another aspect of the disclosure. The AND gate 720 of two-input GABUF 700 may be implemented as a transistor-based AND gate. Alternatively, the AND gate 720 may be implemented with memristors to save IC area and power consumption.

In particular, the AND gate 750 includes a first memristor 755 and a second memristor 760. The first memristor 755 has an undoped-side terminal configured to receive the input signal “a” and a doped-side terminal coupled to a doped-side terminal of the second memristor 760. The second memristor 760 includes an undoped-side terminal configured to receive the delayed input signal “a_{d}”. As discussed, the coupled-together doped-side terminals of the first and second memristors 755 and 760 form an output of the AND gate 750 for generating the output signal “Z”.

In operation, if the input signal “a” and delayed input signal “a_{d}” are both at logic zeros (0s), there is substantially no current flowing through the first and second memristors 755 and 760. Thus, the output signal “Z” is also at a logic zero (0). If the input signal “a” is at a logic one (1) and the delayed input signal “a_{d}” is at a logic zero (0), there is current flowing from the undoped-side terminal to the doped-side terminal of the first memristor 755, and from the doped-side terminal to the undoped-side terminal of the second memristor 760. Thus, the first memristor 755 achieves a relatively high resistance R_{OFF}, and the second memristor 760 achieves a relatively low resistance R_{ON}. Due to voltage division, the output signal “Z” is at a logic zero (0) (V_{z}=Vdd*R_{ON}/(R_{ON}+R_{OFF})≈0V).

Similarly, if the input signal “a” is at a logic zero (0) and the delayed input signal “a_{d}” is at a logic one (1), there is current flowing from the undoped-side terminal to the doped-side terminal of the second memristor 760, and from the doped-side terminal to the undoped-side terminal of the first memristor 755. Thus, the second memristor 760 achieves a relatively high resistance R_{OFF}, and the first memristor 755 achieves a relatively low resistance R_{ON}. Similarly, due to voltage division, the output signal “Z” is at a logic zero (0) (V_{z}=Vdd*R_{ON}/(R_{ON}+R_{OFF})≈0V). If the input signal “a” and delayed input signal “a_{d}” are both at logic ones (1s), there is substantially no current flowing through the first and second memristors 755 and 760. Thus, the output signal “Z” is also at a logic one (1).

FIG. 7C illustrates a schematic diagram of an example two-input logic NOR gate 770 in accordance with another aspect of the disclosure. The NOR gate 730 of two-input GABUF 700 may be implemented as a transistor-based NOR gate. Alternatively, the NOR gate 730 may be implemented with memristors to effectuate the OR logic operation, and a transistor-based inverter to effectuate the NOR logic operation. The memristor-based NOR gate 770 may save IC area and power consumption.

In particular, the NOR gate 770 includes a first memristor 775, a second memristor 780, and an inverter 785. The first memristor 775 has a doped-side terminal configured to receive the input signal “a” and an undoped-side terminal coupled to an undoped-side terminal of the second memristor 780. The second memristor 780 includes a doped-side terminal configured to receive the delayed input signal “a_{d}”. As discussed, the coupled-together undoped-side terminals of the first and second memristors 775 and 780 is coupled to an input of the inverter 785. The inverter 785 includes an output for generating the complementary output signals “Z_{b}”.

In operation, if the input signal “a” and delayed input signal “a_{d}” are both at logic zeros (0s), there is substantially no current flowing through the first and second memristors 775 and 780. Thus, the input to the inverter 785 is also at a logic zero (0). In response, the inverter 785 generates the complementary output signals “Z_{b} ” at a logic one (1). If the input signal “a” is at a logic one (1) and the delayed input signal “a_{d}” is at a logic zero (0), there is current flowing from the doped-side terminal to the undoped-side terminal of the first memristor 775, and from the undoped-side terminal to the doped-side terminal of the second memristor 780. Thus, the first memristor 775 achieves a relatively low resistance R_{ON}, and the second memristor 760 achieves a relatively high resistance R_{OFF}. Due to voltage division, the input of the inverter 785 is at a logic one (1) (V_{INV-IN}=Vdd*R_{OFF}/(R_{ON}+R_{OFF})≈Vdd). In response, the inverter 785 generates the complementary output signals “Z_{b} ” at a logic zero (0).

Similarly, if the input signal “a” is at a logic zero (0) and the delayed input signal “a_{d}” is at a logic one (1), there is current flowing from the doped-side terminal to the undoped-side terminal of the second memristor 780, and from the undoped-side terminal to the doped-side terminal of the first memristor 775. Thus, the second memristor 780 achieves a relatively low resistance R_{ON}, and the first memristor 775 achieves a relatively high resistance R_{OFF}. Similarly, due to voltage division, the input of the inverter 785 is at a logic one (1) (V_{INV-IN}=Vdd*R_{OFF}/(R_{ON}+R_{OFF})≈Vdd). In response, the inverter 785 generates the complementary output signals “Z_{b} ” at a logic zero (0). If the input signal “a” and delayed input signal “a_{d}” are both at logic ones (1s), there is substantially no current flowing through the first and second memristors 775 and 780. Thus, the input to the inverter 785 is also at a logic one (1). In response, the inverter 785 generates the complementary output signals “Z_{b} ” at a logic zero (0).

Comparing the GABUF 700 with the GABUF 500, the transistor-based GABUF 700 includes 12 transistors compared to 16 transistors in GABUF 500. The memristor-based GABUF 700 may include six (6) transistors and four (4) memristors compared to the 16 transistors in GABUF 500. Thus, in both the transistor-based and memristor-based GABUF 700, the GABUF 700 may occupy significantly less IC footprint, consume significantly less power, and may be included more in a digital circuit without drawing significant power vis-à-vis the power savings due to reduction in unwanted glitches.

### Two-Input GABUF—Third Implementation

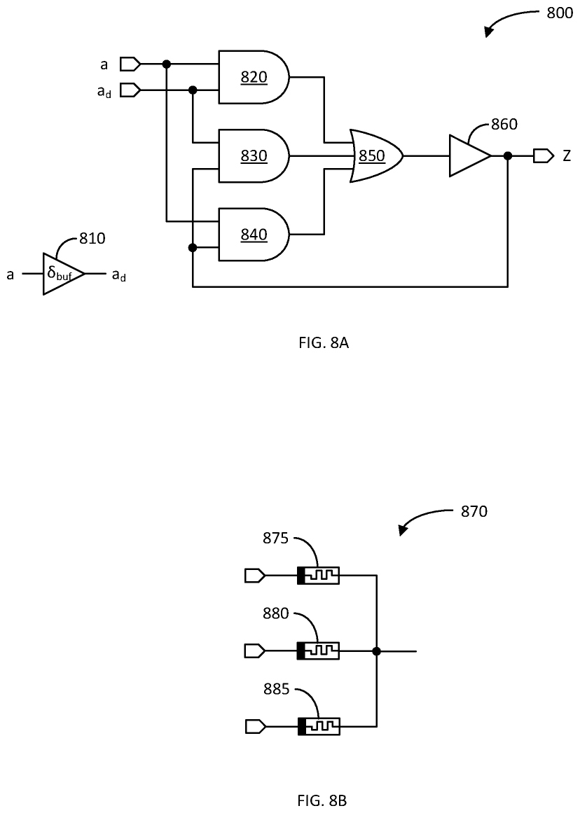

FIG. 8A illustrates a schematic diagram of another example two-input glitch absorbing buffer (GABUF) 800 in accordance with another aspect of the disclosure. The GABUF 800 may also be configured to perform the pulse propagation and suppression operation of GABUF 500, while achieving this operation with significantly less components for power and IC footprint savings.

In particular, the GABUF 800 includes a delay element, such as a buffer 810, configured to delay an input signal “a” by δ_{buf} to generate a delayed input signal “a_{d}”. The GABUF 800 further includes a logic circuit including first, second, and third AND gates 820, 830, and 840, a three-input OR gate 850, and a buffer 860. The first AND gate 820 includes a first input configured to receive the input signal “a” and a second input configured to receive the delayed input signal “a_{d}”. The first AND gate 820 includes an output coupled to a first input of the OR gate 850.

The second AND gate 830 includes a first input configured to receive the delayed input signal “a_{d}” and a second input coupled to an output of the buffer 860 to receive an output signal “Z”. The second AND gate 830 includes an output coupled to a second input of the OR gate 850. The third AND gate 840 includes a first input configured to receive the input signal “a” and a second input coupled to the output of the buffer 860 to receive the output signal “Z”. The third AND gate 840 includes an output coupled to a third input of the OR gate 850.

The OR gate 850 includes an output coupled to an input of the buffer 860. The buffer 860 is configured to generate the output signal “Z”. The operation of the GABUF 800 is discussed below with further reference to the timing diagrams of FIGS. 5B-5C.

According to the timing diagram of FIG. 5B, prior to time t₁, the input signal “a”, the delayed input signal “a_{d}”, and the output signal “Z” are all at logic zeros (0s) (e.g., Vss potential). The input signal “a” and the delayed input signal “a_{d}”, both at logic zeros (0s), cause the first AND gate 820 to output a logic zero (0). The delayed input signal “a_{d}” and the output signal “Z”, both at logic zeros (0s), cause the second AND gate 830 to output a logic zero (0). The input signal “a” and the output signal “Z”, both at logic zeros (0s), cause the third AND gate 840 to output a logic zero (0). In response to all three inputs being logic zeros (0s), the OR gate 850 outputs a logic zero (0). In response, the buffer 860 generates the output signal “Z” as a logic zero (0), as shown in the timing diagram.

At time t₁, the input signal “a” transitions to a logic one (1) in accordance with a first (positive) pulse. In response, the first AND gate 820 continues to output a logic zero (0) as the delayed input signal “a_{d}” is at a logic zero (0); the second AND gate 830 continues to output a logic zero (0) as the delayed input signal “a_{d}” is at a logic zero (0); and the third AND gate 840 continues to output a logic zero (0) as the output signal “Z” is at a logic zero (0). In response to all three inputs being logic zeros (0s), the OR gate 850 outputs a logic zero (0). In response, the buffer 860 continues to generate the output signal “Z” at the previous state of a logic zero (0), as shown in the timing diagram.

At time t₂, after the buffer delay δ_{buf} from time t₁, the delayed input signal “a_{d}” transitions to a logic one (1). In response, the first AND gate 820 outputs a logic one (1) as both the input signal “a” and the delayed input signal “a_{d}” are at logic ones (1s). In response to the logic one (1) generated by the first AND gate 840, the OR gate 850 outputs a logic one (1). In response, the buffer 860 generates the output signal “Z” as a logic one (0), as shown in the timing diagram.

At time t₃, the input signal “a” transitions back to a logic zero (0). In response, the first AND gate 820 outputs a logic zero (0) as the input signal “a” is at a logic zero (0); the second AND gate 830 outputs a logic one (1) as both the delayed input signal “a_{d}” and the output signal “Z” are at logic ones (1s); and the third AND gate 850 outputs a logic zero (0) as the input signal “a” is at a logic zero (0). In response to the logic one (1) generated by the second AND gate 830, the OR gate 850 outputs a logic one (1). In response, the buffer 860 generates the output signal “Z” at the previous state of a logic one (1), as shown in the timing diagram.

At time t₄, the delayed input signal “a_{d}” transitions back to a logic zero (0). As both the input signal “a” and the delayed input signal “a_{d}” are at logic zeros (0s): the first AND gate 830 outputs a logic zero (0); the second AND gate 830 outputs a logic zero (0); and the third AND gate 840 outputs a logic zero (0). In response to the logic zeros (0s) at its inputs, the OR gate 850 outputs a logic zero (0). In response, the buffer 860 generates the output signal “Z” at a logic zero (0), as shown in the timing diagram.

Thus, the GABUF 800 propagates the first (positive) pulse of the input signal “a” to the output signal “Z” because the width w_glitch 1 (t₃−t₁) of the first (positive) pulse is greater than the buffer delay δ_{buf} (t₂−t₁).

Further, according to this example, at time t₅, the input signal “a” transitions to a logic one (1) in accordance with a second pulse. In response, the first AND gate 820 continues to output a logic zero (0) as the delayed input signal “a_{d}” is at a logic zero (0); the second AND gate 830 continues to output a logic zero (0) as the delayed input signal “a_{d}” is at a logic zero (0); and the third AND gate 840 continues to output a logic zero (0) as the output signal “Z” is at a logic zero (0). In response to all three inputs being logic zeros (0s), the OR gate 850 outputs a logic zero (0). In response, the buffer 860 continues to generate the output signal “Z” at the previous state of a logic zero (0), as shown in the timing diagram.

At time t₆, the input signal “a” transitions back to a logic zero (0) before the delayed input signal “a_{d}” transitions to a logic one (1) because the width w_glitch2 of the second pulse is less than the buffer delay δ_{buf} In response to the input signal “a” and the delayed input signal “a_{d}” being both at logic zeros (0s), the first AND gate 820 outputs a logic zero (0); the second AND gate 830 outputs a logic zero (0); and the third AND gate 840 outputs a logic zero (0). In response to all three inputs being logic zeros (0s), the OR gate 850 outputs a logic zero (0). In response, the buffer 860 generates the output signal “Z” as a logic zero (0), as shown in the timing diagram.

At time t₇, after the buffer delay δ_{buf} from time t₅, the delayed input signal “a_{d}” transitions to a logic one (1). In response, the first AND gate 820 outputs a logic zero (0) due to the input signal “a” being at a logic zero (0); the second AND gate 830 continues to output a logic zero (0) due to the output signal “Z” being at a logic zero (0); and the third AND gate 840 continues to output a logic zero (0) due to the input signal “a” and the output signal “Z” being at logic zeros (0s). In response to the logic zeros (0s) at all of its inputs, the OR gate 850 outputs a logic zero (0). In response, the buffer 860 generates the output signal “Z” at the previous state of a logic zero (0), as shown in the timing diagram.

At time t₈, the delayed input signal “a_{d}” transitions back to a logic zero (0). As both the input signal “a” and the delayed input signal “a_{d}” are at logic zeros (0s): the first AND gate 830 outputs a logic zero (0); the second AND gate 830 outputs a logic zero (0); and the third AND gate 840 outputs a logic zero (0). In response to the logic zeros (0s) at all of its inputs, the OR gate 850 outputs a logic zero (0). In response, the buffer 860 generates the output signal “Z” at a logic zero (0), as shown in the timing diagram.

Thus, the GABUF 800 suppresses the propagation of the second (positive) pulse of the input signal “a” to the output signal “Z” because the width w_glitch2 (t₆−t₅) of the second (positive) pulse is less than the buffer delay δ_{buf} (t₇−t₅).

According to the timing diagram of FIG. 5C, prior to time t₉, the input signal “a”, the delayed input signal “a_{d}”, and the output signal “Z” are all at logic ones (1s) (e.g., Vdd potential). The input signal “a” and the delayed input signal “a_{d}”, both at logic ones (1s), cause the first AND gate 820 to output a logic one (1). The delayed input signal “a_{d}” and the output signal “Z”, both at logic ones (1s), cause the second AND gate 830 to output a logic one (1). The input signal “a” and the output signal “Z”, both at logic ones (1s), cause the third AND gate 840 to output a logic one (1). In response to any of the inputs being a logic one (1), the OR gate 850 outputs a logic one (1). In response, the buffer 860 generates the output signal “Z” as a logic one (1), as shown in the timing diagram.

At time t₉, the input signal “a” transitions to a logic zero (0) in accordance with a third (negative) pulse. In response, the first AND gate 820 outputs a logic zero (0); the second AND gate 830 continues to output a logic one (1) as the delayed input signal “a_{d}” and the output signal “Z” are at logic ones (1s); and the third AND gate 840 outputs a logic zero (0). In response to the logic one (1) generated by the second AND gate 830, the OR gate 850 outputs a logic one (1). In response, the buffer 860 continues to generate the output signal “Z” at the previous state of a logic one (1), as shown in the timing diagram.

At time t₁₀, after the buffer delay δ_{buf} from time t₁, the delayed input signal “a_{d}” transitions to a logic zero (0). In response, the first AND gate 820 continues to output a logic zero (0); the second AND gate 830 outputs a logic zero (0) due to the delayed input signal “a_{d}” being at a logic zero (0); and the third AND gate 840 continues to output a logic zero (0). In response to logic zeros (0s) at all its inputs, the OR gate 850 outputs a logic zero (0). In response, the buffer 860 generates the output signal “Z” as a logic one (0), as shown in the timing diagram.

At time t₁₁, the input signal “a” transitions back to a logic one (1). In response, the first AND gate 820 outputs a logic zero (0); the second AND gate 830 outputs a logic zero (0) as the output signal “Z” is at logic zero (0); and the third AND gate 840 outputs a logic zero (0). In response to the logic zeros (0s) at all its inputs, the OR gate 850 outputs a logic zero (0). In response, the buffer 860 generates the output signal “Z” at the previous state of a logic zero (0), as shown in the timing diagram.

At time t₁₂, the delayed input signal “a_{d}” transitions back to a logic one (1). As both the input signal “a” and the delayed input signal “a_{d}” are at logic ones (1s): the first AND gate 830 outputs a logic one (1). In response to the logic one (1) at its input, the OR gate 850 outputs a logic one (1). In response, the buffer 860 generates the output signal “Z” at a logic one (1), as shown in the timing diagram.

Thus, the GABUF 800 propagates the third (negative) pulse of the input signal “a” to the output signal “Z” because the width w_glitch3 (t₁₁−t₉) of the third (negative) pulse is greater than the buffer delay δ_{buf} (t₁₀−t₉).

Further, according to this example, at time t₁₃, the input signal “a” transitions to a logic zero (0) in accordance with a fourth (negative) pulse. In response, the first AND gate 820 outputs a logic zero (0); the second AND gate 830 continues to output a logic one (1) as the delayed input signal “a_{d}” and the output signal “Z” are both at logic ones (1s); and the third AND gate 840 outputs a logic zero (0). In response to the logic one (1) generated by the second AND gate 830, the OR gate 850 outputs a logic one (1). In response, the buffer 860 continues to generate the output signal “Z” at the previous state of a logic one (1), as shown in the timing diagram.

At time t₁₄, the input signal “a” transitions back to a logic one (1) before the delayed input signal “a_{d}” transitions to a logic zero (0) because the width w_glitch4 of the fourth pulse is less than the buffer delay δ_{buf} In response to the input signal “a” and the delayed input signal “a_{d}” being both at logic ones (1s), the first AND gate 820 outputs a logic one (1). In response to the logic one (1) generated by the first AND gate 820, the OR gate 850 outputs a logic one (1). In response, the buffer 860 generates the output signal “Z” as a logic one (1), as shown in the timing diagram.

At time t₁₅, after the buffer delay δ_{buf} from time t₁₃, the delayed input signal “a_{d}”

transitions to a logic zero (0). In response, the first AND gate 820 outputs a logic zero (0); the second AND gate 830 outputs a logic zero (0); and the third AND gate 840 continues to output a logic one (1). In response to the logic one (1) generated by the third AND gate 840, the OR gate 850 outputs a logic one (1). In response, the buffer 860 generates the output signal “Z” at the previous state of a logic one (1), as shown in the timing diagram.

At time t₁₆, the delayed input signal “a_{d}” transitions back to a logic one (1). As both the input signal “a” and the delayed input signal “a_{d}” are at logic ones (1s): the first AND gate 830 outputs a logic one (1). In response to the logic one (1) generated by the first AND gate 820, the OR gate 850 outputs a logic one (1). In response, the buffer 860 generates the output signal “Z” at a logic one (1), as shown in the timing diagram.

Thus, the GABUF 800 suppresses the propagation of the fourth (negative) pulse of the input signal “a” to the output signal “Z” because the width w_glitch4 (t₁₄−t₁₃) of the fourth (negative) pulse is less than the buffer delay δ_{buf} (t₁₅−t₁₃).

FIG. 8B illustrates a schematic diagram of an example three-input logic OR gate 870 in accordance with another aspect of the disclosure. The OR gate 850 of the two-input GABUF 800 may be implemented as a transistor-based OR gate. Alternatively, the OR gate 850 may be implemented with memristors to save IC area and power consumption. The three-input logic OR gate 870 is an example of a memristor-based OR gate.

In particular, the OR gate 870 includes a first memristor 875, a second memristor 880, and a third memristor 885. The first memristor 875 has a doped-side terminal coupled to the output of the first AND gate 820 and an undoped-side terminal coupled to the input of the buffer 860. The second memristor 880 has a doped-side terminal coupled to the output of the second AND gate 830 and an undoped-side terminal coupled to the input of the buffer 860. The third memristor 885 has a doped-side terminal coupled to the output of the third AND gate 840 and an undoped-side terminal coupled to the input of the buffer 860.

In operation, if the first, second, and third AND gates 820, 830, and 840 all output logic zeros (0s), there is substantially no current flowing through the first, second, and third memristors 875, 880, and 850. Thus, the OR gate 870 outputs a logic zero (0). Similarly, if the first, second, and third AND gates 820, 830, and 840 all output logic ones (1s), there is substantially no current flowing through the first, second, and third memristors 875, 880, and 850. Thus, the OR gate 870 outputs a logic one (1).

If one or two of the AND gates 820, 830, and 840 output a logic one (1) and the rest outputs a logic zero (0), then there is current flowing from the output(s) of such AND gate(s) to the output(s) of the AND gate(s) outputting a logic zero (0). The resistance of the one or two memristors coupled to the outputs of the AND gates generating a logic one (1) is relatively low at R_{ON}, and the resistance of the one or two memristors coupled to the outputs of the AND gates generating a logic zero (0) is relatively high at R_{OFF} Due to voltage division, the output of the OR gate 870 is at a logic one (1) (V_{INV-IN}=Vdd*R_{OFF}/(R_{ON}+R_{OFF})≈Vdd).

### Succession of Pulses or Pulse Burst

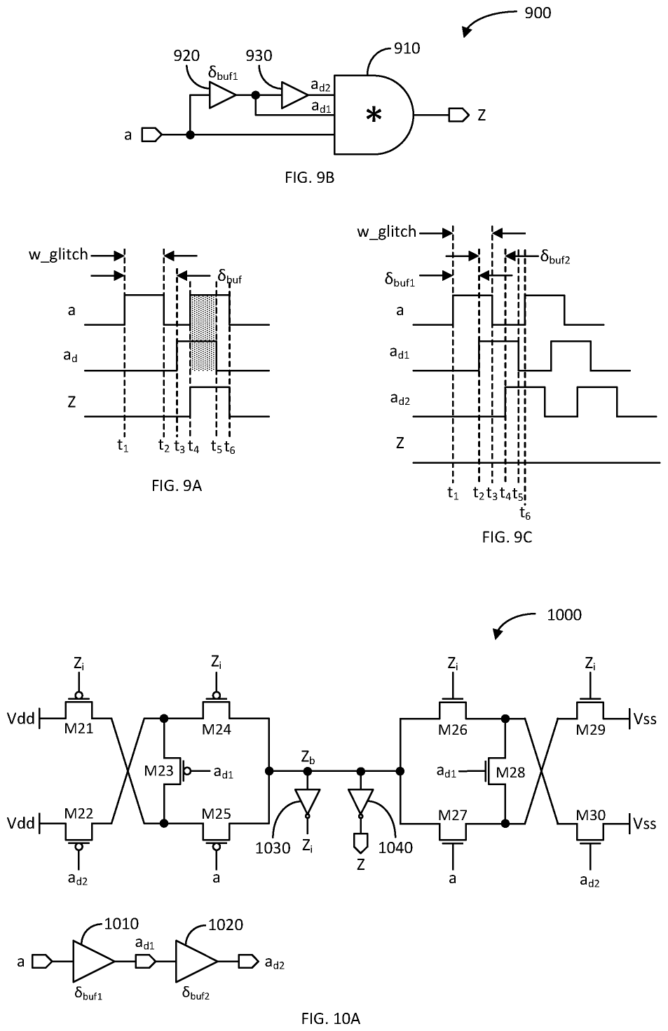

FIG. 9A illustrates a timing diagram of an example operation of the two-input GABUF 300 in response to a pair of consecutive pulses (pulse burst) in accordance with another aspect of the disclosure. When two pulses occur in rapid succession, the GABUF 300 may be tricked into unintentionally outputting a pulse. This is explained in more detail with reference to the timing diagram of FIG. 9A. Similarly, the x- or horizontal-axis of the timing diagram represents time, and the vertical axis, from top to bottom, represent the logic states of the input signal “a”, the delayed input signal “a_{d}”, and the output signal “Z”, respectively.

As previously discussed, the transfer function of the GABUF 300 is that if the input signals “a” and “a_{d}” are both at logic zeros (0s), the GABUF 300 generates the output signal “Z” as a logic zero (0); if the input signals “a” and “a_{d}” are both at logic ones (1s), the GABUF 300 generates the output signal “Z” as a logic one (1); and if the input signals “a” and “a_{d}” are at different logic states, the GABUF 300 generates the output signal “Z” at the previous logic state.

With the aforementioned transfer function in mind, prior to time t₁, the input signal “a” and the delayed input signal “a_{d}” are at logic zeros (0s); and thus, the C-element 310 generates the output signal “Z” at a logic zero (0). At time t₁, the input signal “a” transitions to a logic one (1). As the input signal “a” and the delayed input signal “a_{d}” are at different logic states, the C-element 310 maintains the output signal “Z” at the previous state of a logic zero (0). At time t₂, the input signal “a” transitions back to a logic zero (0); and thus, the C-element 310 continues to maintain the output signal “Z” at a logic zero (0). At time t₃, the delayed input signal “a_{d}” transitions to a logic one (1). As the input signal “a” and the delayed input signal “a_{d}” are at different logic states, the C-element 310 maintains the output signal “Z” at the previous state of a logic zero (0). Thus, as of time t₃, the GABUF 300 is able to suppress the pulse because its width w_glitch (t₂−t₁) is less than the delay δ_{buf} (t₃−t₁) of the buffer 320.

However, at time t₄, the input signal “a” transitions again to a logic one (1), while the delayed input signal “a_{d}” is still at a logic one (1). The rising transitions of the input signal “a” may pertain to a second pulse following the first pulse. This may be an example of a succession of pulses or a pulse burst. As both the input signal “a” and the delayed input signal “a_{d}” are at logic ones (1s), the C-element 310 generates the output signal “Z” at a logic one (1). At time t₅, the delayed input signal “a_{d}” transitions back to a logic zero (0). As the input signal “a” and the delayed input signal “a_{d}” are at different logic states, the C-element 310 maintains the output signal “Z” at the previous state of a logic one (1). At time t₆, the input signal “a” transitions again to a logic zero (0). As both the input signal “a” and the delayed input signal “a_{d}” are at logic zeros (0s), the C-element 310 generates the output signal “Z” at a logic zero (0).

Note that in this example, the GABUF 300 was not able to suppress the outputting of a pulse even though the pulse width (t₂−t₁) of the first pulse is less than the buffer delay δ_{buf}. This is because the rising transition of the second pulse of the input signal “a” occurred before the falling transition of the delayed input signal “a”; resulting in a time interval (t₅−t₄, the shaded region), where both signals “a” and “a_{d}” are at logic ones (1), and causing the C-element 310 to generate the output signal “Z” at logic one (1). Thus, so that the GABUF 300 is able to suppress consecutive pulses, the pulse width w_glitch has to be less that the delay buffer δ_{buf}, and the period T (t₃−t₁) has to be greater than the sum of the pulse width w_glitch and the buffer delay δ_{buf} (e.g., the two conditions are: w_glitch<δ_{buf} and T>w_glitch+δ_{buf}).

There may be a need to further relax the second condition of T>w_glitch+δ_{buf}). In other words, if the second condition is relaxed to T>w_glitch+δ_{buf}/2), then if the second rising transition of the input signal “a” occurs between w_glitch+δ_{buf}/2 and w_glitch+δ_{buf}, a GABUF would suppress such pulse, whereas the GABUF 300 would not. The following describes various implementations of a GABUF that is able to suppress pulses according to the following conditions: w_glitch<δ_{buf} and T>w_glitch+δ_{buf}/2.

FIG. 9B illustrates a schematic diagram of an example three-input glitch absorbing buffer (GABUF) 900 in accordance with another aspect of the disclosure. The GABUF 900 includes a three-input C-element 910, a first buffer 920, and a second buffer 930. The C-element 910 and the first buffer 920 include inputs configured to receive an input signal “a”, respectively. The C-element 910 and the second buffer 930 include inputs coupled to an output of the first buffer 920 to receive a first delayed input signal “a_{d1}” therefrom. The C-element 910 includes a third input coupled to an output of the second buffer 930 to receive a second delayed input signal “a_{d2}” therefrom.

The first buffer 920 is configured to delay the input signal “a” by a first delay δ_{buf1} to generate the first delayed input signal “a_{d1}”. The second buffer 930 is configured to delay the first delayed input signal “a_{d1}” by a second delay δ_{buf2} to generate the second delayed input signal “a_{d2}”. The first delay δ_{buf1} may be substantially equal to the second delay δ_{buf2}, or different. The C-element 910 is configured to generate an output signal “Z” based on the input signals “a”, “a_{d1}”, and “a_{d2}”. The transfer function of the GABUF 900 is as follows: if the input signals “a”, “a_{d1}”, and “a_{d2}” are all at logic zeros (0s), the GABUF 900 generates the output signal “Z” as a logic zero (0); if the input signals “a”, “a_{d1}”, and “a_{d2}” are all at logic ones (1s), the GABUF 900 generates the output signal “Z” as a logic one (1); and if two of the input signals “a”, “a_{d1}”, and “a_{d2}” are at different logic states, the GABUF 900 generates the output signal “Z” at the previous logic state.

FIG. 9C illustrates a timing diagram of another example operation of the GABUF 900 in accordance with another aspect of the disclosure. As mentioned above, the GABUF 900 is able to suppress a pulse if the following two conditions are met: w_glitch<δ_{buf} and T>w_glitch+δ_{buf}/2, where δ_{buf}=δ_{buf1}+δ_{buf2} and δ_{buf1}=δ_{buf2}). This is explained in more detail with reference to the timing diagram of FIG. 9C. Similarly, the x- or horizontal-axis of the timing diagram represents time, and the vertical axis, from top to bottom, represents the logic states of the input signal “a”, the first delayed input signal “a_{d1}”, the second delayed input signal “a_{d2}”, and the output signal “Z”, respectively.

Prior to time t₁, the input signals “a”, “a_{d1}”, and “a_{d2}” are all at logic zeros (0s); and thus, the C-element 910 generates the output signal “Z” at a logic zero (0). At time t₁, the input signal “a” transitions to a logic one (1) in accordance with a first pulse. As two of the input signals are at different logic states (a=1 and a_{d1}=0 or a_{d2}=0), the C-element 910 maintains the output signal “Z” at the previous state of a logic zero (0). At time t₂, after the first delay δ_{buf1} from time t₁, the first delayed input signal “a_{d1}” transitions to a logic one (1). Similarly, as two of the input signals continue to be at different logic states (a_{d2}=0 and a=1 or a_{d1}=1), the C-element 910 continues to maintain the output signal “Z” at the previous state of a logic zero (0).

At time t₃, the input signal “a” transitions back to a logic zero (0) in accordance with the first pulse. As two of the input signals continue to be at different logic states (a_{d1}=1 and a=0 or a_{d2}=0), the C-element 910 continues to maintain the output signal “Z” at the previous state of a logic zero (0). At time t₄, after a sum of the first delay δ_{buf1} and the second delay δ_{buf2} from time t₁, the second delayed input signal “a_{d2}” transitions to a logic one (1). Similarly, as two of the input signals continue to be at different logic states (a=0 and a_{d1}=1 or a_{d2}=1), the C-element 910 continues to maintain the output signal “Z” at the previous state of a logic zero (0).

At time t₅, the first delayed input signal “a_{d1}” transitions back to a logic zero (0). As two input signals continue to be at different logic states (a_{d2}=1 and a=0 or a_{d1}=0), the C-element 910 continues to maintain the output signal “Z” at the previous state of a logic zero (0). At time t₆, the input signal “a” transitions to a logic one (1) in accordance with a second pulse. As two of the input signals are at different logic states (a_{d1}=0 and a=1 or a_{d2}=1), the C-element 910 maintains the output signal “Z” at the previous state of a logic zero (0).

Thus, the GABUF 900 is able to suppress the outputting of pulses in this example. This is because the two conditions are met: w_glitch<δ_{buf} and T>w_glitch +δ_{buf}/2 (or δ_{buf1} in the general case). For example, the pulse width w_glitch (t₃−t₁) is less than the δ_{buf} (t₄−t₁); and the period T (t₆−t₁) of the pulses is greater than w_glitch+δ_{buf}/2 (t₅−t₁). Thus, in contrast to the two-input GABUF 300, the three-input GABUF 900 is able to suppress or absorb pulses where the pulse period T lies between δ_{buf}/2 and δ_{buf}. The following describes various example more detailed implementations of the three-input GABUF 900.

### Three-Input GABUF—First Implementation

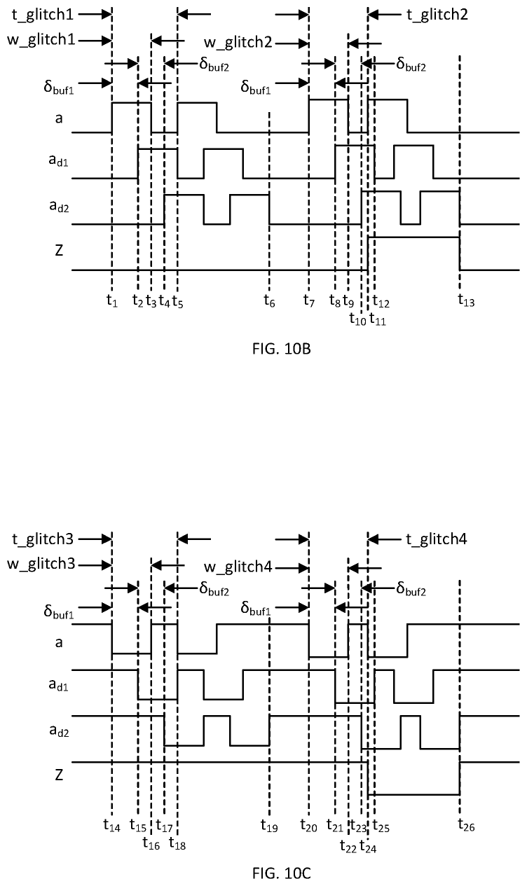

FIG. 10A illustrates a schematic diagram of another example three-input glitch absorbing buffer (GABUF) 1000 in accordance with another aspect of the disclosure. The GABUF 1000 may be an example detailed implementation of the GABUF 900 previously discussed.

The GABUF 1000 includes a first delay element, such as buffer 1010 and a second delay element, such as buffer 1020. The first buffer 1010 is configured to receive an input signal “a”, and delay the input signal “a” by a first delay δ_{buf1} to generate a first delayed input signal “a_{d1}”. The second buffer 1020 includes an input coupled to an output of the first buffer 1010 to receive the first delayed input signal “a_{d1}” therefrom. The second buffer 1020 is configured to delay the first delayed input signal “a_{d1}” by a second delay δ_{buf2} to generate a second delayed input signal “a_{d2}” at an output thereof.

The GABUF 1000 further includes a logic circuit including: a pull-up circuit including PMOS FETs M21, M22, M23, M24, and M25, a pull-down circuit including NMOS FETs M26, M27, M28, M29, and M30, and a pair of inverters 1030 and 1040.

With regard to the pull-up circuit, the PMOS FET M21 includes a source coupled to an upper voltage rail Vdd, a gate coupled to an output of the inverter 1030 to receive an internal output signal “Zᵢ” therefrom, and a drain coupled to a source of PMOS FET M25. The PMOS FET M25 includes a gate configured to receive the input signal “a” and a drain coupled to an inverted output node Z_{b}. Similarly, the PMOS FET M22 includes a source coupled to the upper voltage rail Vdd, a gate coupled to the output of the second buffer 1020 to receive the second delayed input signal “a_{d2}” therefrom, and a drain coupled to a source of PMOS FET M24. The PMOS FET M24 includes a gate coupled to the output of the inverter 1030 to receive the internal output signal “Zᵢ” therefrom, and a drain coupled to the inverted output node Z_{b}. The PMOS FET M23 includes source/drain and drain/source coupled to the sources of PMOS FETs M24 and M25, respectively, and a gate coupled to the output of the first buffer 1010 to receive the first delayed input signal “a_{d1}” therefrom.

With regard to the pull-down circuit, the NMOS FET M26 includes a drain coupled to the inverted output node Z_{b}, a gate coupled to the output of the inverter 1030 to receive the internal output signal “Zᵢ” therefrom, and a source coupled to a drain of NMOS FET M30. The NMOS FET M30 includes a gate coupled to the output of the second buffer 1020 to receive the second delayed input signal “a_{d2}” therefrom, and a source coupled to a lower voltage rail Vss. Similarly, the NMOS FET M27 includes a drain coupled to the inverted output node Z_{b}, a gate configured to receive the input signal “a”, and a source coupled to a drain of NMOS FET M29. The NMOS FET M29 includes a gate coupled to the output of the inverter 1030 to receive the internal output signal “Zᵢ” therefrom, and a source coupled to the lower voltage rail Vss. The NMOS FET M28 includes drain/source and source/drain coupled to the sources of NMOS FETs M26 and M27, respectively, and a gate coupled to the output of the first buffer 1010 to receive the first delayed input signal “a_{d1}” therefrom.

The inverter 1030 includes an input coupled to the inverted output node Z_{b}, and an output coupled to the gates of FETs M21, M24, M26, and M29 as previously discussed. The inverter 1040 includes an input coupled to the inverted output node Z_{b}, and an output configured to produce an output signal “Z”. Although the output signal “Z” and the internal output signal “Zᵢ” are logically the same, the internal output signal “Zᵢ” is used for internal operation so as not to overload the output of the inverter 1040. The pulse suppression and propagation operation of the GABUF 1000 is discussed further herein.

FIG. 10B illustrates a timing diagram of an example operation of the GABUF 1000 in accordance with another aspect of the disclosure. The x- or horizontal-axis of the timing diagram represents time, and the vertical axis, from top to bottom, represents the logic states of the input signal “a”, the first delayed input signal “a_{d1}”, the second delayed input signal “a_{d2}”, and the output signal “Z”, respectively.

With further reference to FIG. 10A, prior to time t₁, the input signals “a”, “a_{d1}”, and “a_{d2}” are all at logic zeros (0s). The input signals “a”, “a_{d1}”, and “a_{d2}” at logic zeros (0s) turn on PMOS FETs M25, M23, and M22, respectively. Accordingly, inverted output node Z_{b} is pulled up to a logic one (1) (e.g., Vdd potential) via turned-on PMOS FETs M22, M23, and M25. The inverter 1030 inverts the logic one (1) at the inverted output node Z_{b} to produce the internal output signal “Zᵢ” at a logic zero (0). The internal output signal “Zᵢ” at a logic zero (0) turns on PMOS FETs M21 and M24 by way the inverted output node Z_{b} is also pulled up to a logic one (1).

The signals “a”, “a_{d1}”, and “a_{d2}” at logic zeros (0s) turn off NMOS FETs M27, M28, and M30, respectively; and the internal output signal “Zᵢ” at a logic zero (0) turns off NMOS FETs M26 and M29. Thus, the inverted output node Z_{b} is electrically isolated (decoupled) from Vss potential due to turned-off NMOS FETs M26-M30. The inverter 1040 also inverts the logic one (1) at the inverted output node Z_{b} to produce the output signal “Z” at a logic zero (0), as shown in the timing diagram.

At time t₁, the input signal “a” transitions to a logic one (1) in accordance with a first (positive) pulse burst. The input signal “a” being at a logic one (1) turns off PMOS FET M25 and turns on NMOS FET M27. However, the inverted output node Z_{b} remains pulled up to a logic one (1) via PMOS FETs M22 and M24 path, and PMOS FETs M21, M23, and M24 path. The inverted output node Z_{b} also remains electrically isolated from Vss potential via turned-off NMOS FETs M26, M28, M29, and M30. Thus, the inverter 1040 continues to invert the logic one (1) at the inverted output node Z_{b} to produce the output signal “Z” at a logic zero (0), as shown in the timing diagram.

At time t₂, the first delayed input signal “a_{d1}” transitions to a logic one (1). The first delayed input signal “a_{d1}” being at a logic one (1) turns off PMOS FET M23 and turns on NMOS FET M28. However, the inverted output node Z_{b} remains pulled up to a logic one (1) via PMOS FETs M22 and M24 path. The inverted output node Z_{b} also remains electrically isolated from Vss potential due to turned-off NMOS FETs M29 and M30. Thus, the inverter 1040 continues to invert the logic one (1) at the inverted output node Z_{b} to produce the output signal “Z” at a logic zero (0), as shown in the timing diagram.

At time t₃, the input signal “a” transitions back to a logic zero (0) in accordance with the first pulse burst. The input signal “a” being at a logic zero (0) turns on PMOS FET M25 and turns off NMOS FET M27. The inverted output node Z_{b} remains pulled up to a logic one (1) via PMOS FETs M22 and M24 path, and PMOS FETs M21 and M25 path. The inverted output node Z_{b} also remains electrically isolated from Vss potential due to turned-off NMOS FETs M26, M27, M29, and M30. Thus, the inverter 1040 continues to invert the logic one (1) at the inverted output node Z_{b} to produce the output signal “Z” at a logic zero (0), as shown in the timing diagram.

At time t₄, the second delayed input signal “a_{d2}” transitions to a logic one (1). The second delayed input signal “a_{d2}” being at a logic one (1) turns off PMOS FET M22 and turns on NMOS FET M30. However, the inverted output node Z_{b} remains pulled up to a logic one (1) via PMOS FETs M21 and M25 path. The inverted output node Z_{b} also remains electrically isolated from Vss potential due to turned-off NMOS FETs M26 and M27. Thus, the inverter 1040 continues to invert the logic one (1) at the inverted output node Z_{b} to produce the output signal “Z” at a logic zero (0), as shown in the timing diagram.

At time t₅, the input signal “a” transitions again to a logic one (1) in accordance with the first (positive) pulse burst, and the first delayed input signal “a_{d1}” transitions back to a logic zero (0). The input signal “a” being at a logic one (1) turns off PMOS FET M25 and turns on NMOS FET M27. The first delayed input signal “a_{d1}” being at a logic zero (0) turns on PMOS FET M23 and turns off NMOS FET M28. However, the inverted output node Z_{b} remains pulled up to a logic one (1) via PMOS FETs M21, M23, and M24 path. The inverted output node Z_{b} also remains electrically isolated from Vss potential due to turned-off NMOS FETs M26, M28, and M29. Thus, the inverter 1040 continues to invert the logic one (1) at the inverted output node Z_{b} to produce the output signal “Z” at a logic zero (0), as shown in the timing diagram.

Thus, the GABUF 1000 is able to suppress the outputting of positive pulses in this example. This is because the two conditions are met: w_glitch1<δ_{buf} and t_glitch1>w_glitch1+δ_{buf}/2. For example, the pulse width w_glitch1 (t₃−t₁) is less than the δ_{buf} (t₄−t₁); and the period t_glitch1 (t₅−t₁) of the pulses is greater or equal to w_glitch1+δ_{buf}/2 (t₅−t₁).

Further, according to this example, at time t₆, all signals “a”, “a_{d1}”, “a_{d2}”, and “Z” are again at logic zeros (0s), which is the same state as prior to time t₁. The configuration of the GABUF 1000 at such state has been previously discussed. At time t₇, the input signal “a” transitions to a logic one (1) in accordance with a second (positive) pulse burst. Similarly, the states at times t₇ to t₁₀ are the same as the states at times t₁ to t₄, respectively, where the configurations of the GABUF 1000 at such states have been previously discussed.

In this example, the second pulse burst differs from the first pulse burst in that the period t_glitch2 (t₁₁−t₇) is less than the pulse width w_glitch2 plus the delay δ_{buf}/2 (t₁₂−t₇). Thus, the condition t_glitch2>w_glitch2+δ_{buf}/2 is not met; and therefore, the GABUF 1000 propagates a pulse. More specifically, at time t₁₁, the input signal “a” transitions to a logic one (1) in accordance with the second pulse burst. This occurs before the first delayed input signal “a_{d1}” transitions to a logic zero (0) at time t₁₂. As a result, all the input signals “a”, “a_{d1}”, and “a_{d2}” are at logic ones (1s) between times t₁₁ and t₁₂. During this interval, all NMOS FETs M26-M30 are turned on to pull down the inverted output node Z_{b} to Vss potential, and all the PMOS FETs M21-M25 are turned off to electrically isolate the inverted output node Z_{b} from Vdd potential. Accordingly, the inverted output node Z_{b} is at a logic zero (0), and the inverter 1040 generates the output signal “Z” as a logic one (1), as shown in the timing diagram.

The output signal “Z” remains at a logic one (1) until time t₁₃, when all input signals “a”, “a_{d1}”, and “a_{d2}” become logic zeros (0s). At which time, the output signal “Z” becomes a logic zero (0). Between times t₁₂ and t₁₃, the signals are at: (1) a=1, a_{d1}=0, a_{d2}=1, and Zᵢ=Z=1; (2) a=1, a_{d1}=1, a_{d2}=1, and Zᵢ=Z=1; (3) a=1, a_{d1}=1, a_{d2}=0, and Zᵢ=Z=1; (4) a=0, a_{d1}=1, a_{d2}=0, and Zᵢ=Z=1; (5) a=0, a_{d1}=1, a_{d2}=1, and Zᵢ=Z=1; and (6) a=0, a_{d1}=0, a_{d2}=1, and Zᵢ=Z=1. With Zᵢ being at a logic one (1) and one of “a”, “a_{d1}” and “a_{d2}” being a logic one (1) per states (1) to (6), the inverted output node Z_{b} remains pulled down to Vss potential via turned-on NMOS FETs M26 and M29 and another turned-on NMOS FET corresponding to the one of “a”, “a_{d1}” and “a_{d2}” being at a logic one (1); and the inverted output node Z_{b} remains electrically isolated from Vdd potential due to turned-off PMOS FETs M21 and M24 and another turned-off PMOS FET corresponding to the one of “a”, “a_{d1}” and “a_{d2}” being at a logic one (1). Thus, between times t₁₂−t₁₃, the GABUF 1000 generates the output signal “Z” at a logic one (1).

FIG. 10C illustrates a timing diagram of another example operation of three-input glitch absorbing buffers (GABUF) described herein in accordance with another aspect of the disclosure. Similarly, the x- or horizontal-axis of the timing diagram represents time, and the vertical axis, from top to bottom, represents the logic states of the input signal “a”, the first delayed input signal “a_{d1}”, the second delayed input signal “a_{d2}”, and the output signal “Z”, respectively.

With further reference to FIG. 10A, prior to time t₁₄, the input signals “a”, “a_{d1}”, and “a_{d2}” are all at logic ones (1s). The input signals “a”, “a_{d1}”, and “a_{d2}” at logic ones (1s) turn on NMOS FETs M27, M28, and M30, respectively. Accordingly, the inverted output node Z_{b} is pulled down to a logic zero (0) (e.g., Vss potential) via turned-on NMOS FETs M27, M28, and M30. The inverter 1030 inverts the logic zero (0) at the inverted output node Z_{b} to produce the internal output signal “Zᵢ” at a logic one (1). The internal output signal “Zᵢ” at a logic one (1) turns on NMOS FETs M26 and M29 by way the inverted output node Z_{b} is also pulled down to a logic zero (0).

The signals “a”, “a_{d1}”, and “a_{d2}” at logic ones (1s) turn off PMOS FETs M25, M23, and M22, respectively; and the internal output signal “Zᵢ” at a logic one (1) turns off PMOS FETs M21 and M24. Thus, the inverted output node Z_{b} is electrically isolated (decoupled) from Vdd potential due to turned-off PMOS FETs M21-M25. The inverter 1040 also inverts the logic zero (0) at the inverted output node Z_{b} to produce the output signal “Z” at a logic one (1), as shown in the timing diagram.

At time t₁₄, the input signal “a” transitions to a logic zero (0) in accordance with a third (negative) pulse burst. The input signal “a” being at a logic zero (0) turns off NMOS FET M27 and turns on PMOS FET M25. However, the inverted output node Z_{b} remains pulled down to a logic zero (0) via NMOS FETs M26 and M30 path, as well as NMOS FETs M26, M28, and M29 path. The inverted output node Z_{b} also remains electrically isolated from Vdd potential via turned-off PMOS FETs M21, M22, M23, and M24. Thus, the inverter 1040 continues to invert the logic zero (0) at the inverted output node Z_{b} to produce the output signal “Z” at a logic one (0), as shown in the timing diagram.

At time t₁₅, the first delayed input signal “a_{d1}” transitions to a logic zero (0). The first delayed input signal “a_{d1}” being at a logic zero (0) turns off NMOS FET M28 and turns on PMOS FET M23. However, the inverted output node Z_{b} remains pulled down to a logic zero (0) via PMOS FETs M26 and M30 path. The inverted output node Z_{b} also remains electrically isolated from Vdd potential due to turned-off PMOS FETs M21 and M22. Thus, the inverter 1040 continues to invert the logic zero (0) at the inverted output node Z_{b} to produce the output signal “Z” at a logic one (1), as shown in the timing diagram.

At time t₁₆, the input signal “a” transitions back to a logic one (1) in accordance with the third pulse burst. The input signal “a” being at a logic one (1) turns on NMOS FET M27 and turns off PMOS FET M25. The inverted output node Z_{b} remains pulled down to a logic zero (0) via NMOS FETs M26 and M30 path, as well as via NMOS FETs M27 and M29 path. The inverted output node Z_{b} also remains electrically isolated from Vdd potential due to turned-off NMOS FETs M21, M22, M24, and M25. Thus, the inverter 1040 continues to invert the logic zero (0) at the inverted output node Z_{b} to produce the output signal “Z” at a logic one (1), as shown in the timing diagram.

At time t₁₇, the second delayed input signal “a_{d2}” transitions to a logic zero (0). The second delayed input signal “a_{d2}” being at a logic zero (0) turns off NMOS FET M30 and turns on NMOS FET M22. However, the inverted output node Z_{b} remains pulled down to a logic zero (0) via NMOS FETs M27 and M29 path. The inverted output node Z_{b} also remains electrically isolated from Vdd potential due to turned-off PMOS FETs M24 and M25. Thus, the inverter 1040 continues to invert the logic zero (0) at the inverted output node Z_{b} to produce the output signal “Z” at a logic one (1), as shown in the timing diagram.

At time t₁₈, the input signal “a” transitions again to a logic zero (0) in accordance with the third pulse burst, and the first delayed input signal “a_{d1}” transitions back to a logic one (1). The input signal “a” being at a logic zero (0) turns off NMOS FET M27 and turns on PMOS FET M25. The first delayed input signal “a_{d1}” being at a logic one (1) turns on NMOS FET M28 and turns off PMOS FET M23. However, the inverted output node Z_{b} remains pulled down to a logic zero (0) via NMOS FETs M26, M28, and M29 path. The inverted output node Z_{b} also remains electrically isolated from Vdd potential due to turned-off PMOS FETs M21, M23, and M24. Thus, the inverter 1040 continues to invert the logic zero (0) at the inverted output node Z_{b} to produce the output signal “Z” at a logic one (1), as shown in the timing diagram.

Thus, the GABUF 1000 is able to suppress the outputting of negative pulses in this example. This is because the two conditions are met: w_glitch3<δ_{buf} and t_glitch1>w_glitch3+δ_{buf}/2. For example, the pulse width w_glitch3 (t₁₆−t₁₄) is less than the δ_{buf} (t₁₇−t₁₄); and the period t_glitch3 (t₁₈−t₁₄) of the pulses is greater or equal to w_glitch3+δ_{buf}/2 (t₁₈−t₁₄).

Further, according to this example, at time t₁₉, all signals “a”, “a_{d1}”, “a_{d2}”, and “Z” are again at logic ones (1s), which is the same state as prior to time t₁₄. The configuration of the GABUF 1000 at such state has been previously discussed. At time t₂₀, the input signal “a” transitions to a logic zero (0) in accordance with a fourth (negative) pulse burst. Similarly, the states at times t₂₀ to t₂₃ are the same as the states at times t₁₄ to t₁₇, respectively, where the configurations of the GABUF 1000 at such states has been previously discussed.

In this example, the second pulse burst differs from the first pulse burst in that the period t_glitch4 (t₂₄−t₂₀) is less than the pulse width w_glitch4 plus the delay δ_{buf}/2 (t₂₅−t₂₀). Thus, the condition t_glitch4>w_glitch4+δ_{buf}/2 is not met; and therefore, the GABUF 1000 propagates a pulse. More specifically, at time t₂₄, the input signal “a” transitions to a logic zero (0) in accordance with the fourth pulse burst. This occurs before the first delayed input signal “a_{d1}” transitions to a logic one (1) at time t₂₅. As a result, all the input signals “a”, “a_{d1}”, and “a_{d2}” are at logic zeros (0s) between times t₂₄ and t₂₅. During this interval, all PMOS FETs M21-M25 are turned on to pull up the inverted output node Z_{b} to Vdd potential, and all the NMOS FETs M26-M30 are turned off to electrically isolate (decouple) the inverted output node Z_{b} from Vss potential. Accordingly, the inverted output node Z_{b} is at a logic one (1), and the inverter 1040 generates the output signal “Z” as a logic zero (0), as shown in the timing diagram.

The output signal “Z” remains at a logic zero (0) until time t₂₆, when all input signals “a”, “a_{d1}”, and “a_{d2}” become logic ones (1s). At which time, the output signal “Z” becomes a logic one (1). Between times t₂₅ and t₂₆, the signals are at: (1) a=0, a_{d1}=1, a_{d2}=0, and Zᵢ=Z=0; (2) a=0, a_{d1}=0, a_{d2}=0, and Zᵢ=Z=0; (3) a=0, a_{d1}=0, a_{d2}=1, and Zᵢ=Z=0; (4) a=1, a_{d1}=0, a_{d2}=1, and Zᵢ=Z=0; (5) a=1, a_{d1}=0, a_{d2}=0, and Zᵢ=Z=0; and (6) a=1, a_{d1}=1, a_{d2}=0, and Zᵢ=Z=0. With Zᵢ being at a logic zero (0) and one of “a”, “a_{d1}” and “a_{d2}” being a logic zero (0) per states (1) to (6), the inverted output node Z_{b} remains pulled up to Vdd potential via turned-on PMOS FETs M21 and M24 and another turned-on PMOS FET corresponding to the one of “a”, “a_{d1}” and “a_{d2}” being at a logic zero (0); and the inverted output node Z_{b} remains electrically isolated from Vss potential due to turned-off NMOS FETs M26 and M29 and another turned-off NMOS FET corresponding to the one of “a”, “a_{d1}” and “a_{d2}” being at a logic zero (0). Thus, between times t₂₅−t₂₆, the GABUF 1000 generates the output signal “Z” at a logic zero (0).

### Three-Input GABUF—Second Implementation

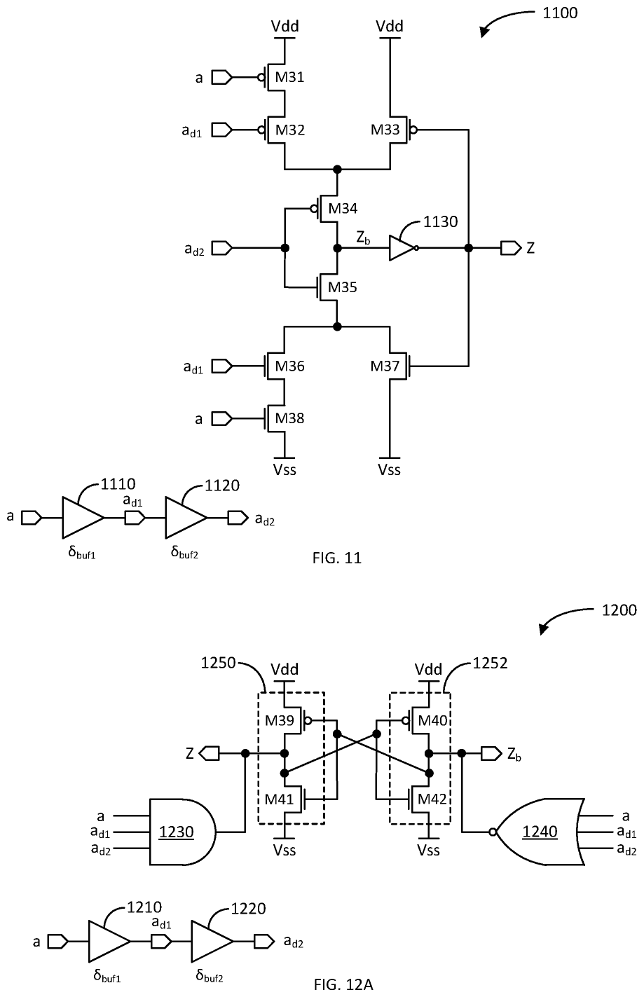

FIG. 11 illustrates a schematic diagram of another example three-input glitch absorbing buffer (GABUF) 1100 in accordance with another aspect of the disclosure. The GABUF 1100 may be another example detailed implementation of the GABUF 900 previously discussed.

The GABUF 1100 includes a first delay element, such as buffer 1110, and a second delay element, such as buffer 1120. The first buffer 1110 is configured to receive an input signal “a”, and delay the input signal “a” by a first delay δ_{buf1} to generate a first delayed input signal “a_{d1}”. The second buffer 1120 includes an input coupled to an output of the first buffer 1110 to receive the first delayed input signal “a_{d1}” therefrom. The second buffer 1120 is configured to delay the first delayed input signal “a_{d1}” by a second delay δ_{buf2} to generate a second delayed input signal “a_{d2}” at an output thereof.

The GABUF 1100 further includes a logic circuit including: a pull-up circuit including PMOS FETs M31, M32, M33, and M34, a pull-down circuit including NMOS FETs M35, M36, M37, and M38, and an inverter 1130. The PMOS FET M31 includes a source coupled to an upper voltage rail Vdd, a gate configured to receive the input signal “a”, and a drain coupled to a source of PMOS FET M32. The PMOS FET M32 includes a gate coupled to the output of the first buffer 1110 to receive the first delayed input signal “a_{d1}” therefrom, and a drain coupled to a source of PMOS FET M34. The PMOS FET M33 includes a source coupled to the upper voltage rail, a gate coupled to an output of the inverter 1130 to receive an output signal “Z” therefrom, and a drain coupled to the source of PMOS FET M34.

The PMOS FET M34 includes a gate coupled to a gate of NMOS FET M35, both gates being coupled to the output of the second buffer 1120 to receive the second delayed input signal “a_{d2}” therefrom. The PMOS FET M34 includes a drain coupled to a source of NMOS FET M35, both such drain and source are coupled to an input of the inverter 1130, and serve as an inverted output node Z_{b}. The NMOS FET M35 includes a source coupled to the drains of NMOS FETs M36 and M37.

The NMOS FET M36 includes a gate coupled to the output of the first buffer 1110 to receive the first delayed input signal “a_{d1}” therefrom, and a source coupled to a drain of NMOS FET M38. The NMOS FET M38 includes a gate configured to receive the input signal “a”, and a source coupled to a lower voltage rail Vss (e.g., ground). The NMOS FET M37 includes a gate coupled to the output of the inverter 1130 to receive the output signal “Z” therefrom, and a source coupled to the lower voltage rail Vss. The pulse suppression and propagation operation of the GABUF 1100 is discussed further herein with reference to the timing diagrams of FIGS. 10B-10C.

With further reference to FIG. 10B, prior to time t₁, the input signals “a”, “a_{d1}”, and “a_{d2}” are all at logic zeros (0s). The input signals “a”, “a_{d1}”, and “a_{d2}” at logic zeros (0s) turn on PMOS FETs M31, M32, and M34, and turn off NMOS FETs M38, M36, and M35, respectively. Accordingly, the inverted output node Z_{b} is pulled up to a logic one (1) (e.g., Vdd potential) via turned-on PMOS FETs M31, M32, and M34, and is electrically isolated (decoupled) from Vss potential via turned-off NMOS FETs M38, M36, and M35. The inverter 1130 inverts the logic one (1) at the inverted output node Z_{b} to produce the output signal “Z” at a logic zero (0), as indicated in the timing diagram. The output signal “Z” at a logic zero (0) turns on PMOS FET M33 and turns off NMOS FET M37.

At time t₁, the input signal “a” transitions to a logic one (1) in accordance with a first (positive) pulse burst. The input signal “a” being at a logic one (1) turns off PMOS FET M31 and turns on NMOS FET M38. However, the inverted output node Z_{b} remains pulled up to a logic one (1) via turned-on PMOS FETs M33 and M34, and electrically isolated from Vss potential via turned-off NMOS FETs M35, M36 and M37. Thus, the inverter 1130 continues to invert the logic one (1) at the inverted output node Z_{b} to produce the output signal “Z” at a logic zero (0), as shown in the timing diagram.

At time t₂, the first delayed input signal “a_{d1}” transitions to a logic one (1). The first delayed input signal “a_{d1}” being at a logic one (1) turns off PMOS FET M32 and turns on NMOS FET M36. However, the inverted output node Z_{b} remains pulled up to a logic one (1) via turned-on PMOS FETs M33 and M34, and electrically isolated from Vss potential due to turned-off NMOS FET M35. Thus, the inverter 1130 continues to invert the logic one (1) at the inverted output node Z_{b} to produce the output signal “Z” at a logic zero (0), as shown in the timing diagram.

At time t₃, the input signal “a” transitions back to a logic zero (0) in accordance with the first pulse burst. The input signal “a” being at a logic zero (0) turns on PMOS FET M31 and turns off NMOS FET M38. However, the inverted output node Z_{b} remains pulled up to a logic one (1) via turned-on PMOS FETs M33 and M34, and electrically isolated from Vss potential due to turned-off NMOS FETs M35, M37, and M38. Thus, the inverter 1130 continues to invert the logic one (1) at the inverted output node Z_{b} to produce the output signal “Z” at a logic zero (0), as shown in the timing diagram.

At time t₄, the second delayed input signal “a_{d2}” transitions to a logic one (1). The second delayed input signal “a_{d2}” being at a logic one (1) turns off PMOS FET M34 and turns on NMOS FET M35. In this configuration, the inverted output node Z_{b} is tristated (e.g., no electrical paths to Vdd and Vss), and capacitively holds a logic one (1). Thus, the inverter 1130 continues to invert the logic one (1) at the inverted output node Z_{b} to produce the output signal “Z” at a logic zero (0), as shown in the timing diagram.

At time t₅, the input signal “a” transitions again to a logic one (1) in accordance with the first (positive) pulse burst, and the first delayed input signal “a_{d1}” transitions back to a logic zero (0). The input signal “a” being at a logic one (1) turns off PMOS FET M31 and turns on NMOS FET M38. The first delayed input signal “a_{d1}” being at a logic zero (0) turns on PMOS FET M32 and turns off NMOS FET M36. However, the inverted output node Z_{b} remains tristated to capacitively hold a logic one (1). Thus, the inverter 1130 continues to invert the logic one (1) at the inverted output node Z_{b} to produce the output signal “Z” at a logic zero (0), as shown in the timing diagram.

Thus, the GABUF 1100 is able to suppress the outputting of positive pulses in this example. This is because the two conditions are met: w_glitch1<δ_{buf}and t_glitch1>w_glitch1+δ_{buf}/2. For example, the pulse width w_glitch1 (t₃−t₁) is less than the δ_{buf} (t₄−t₁); and the period t_glitch1 (t₅31 t₁) of the pulses is greater or equal to w_glitch1+δ_{buf}/2 (t₅−t₁).

Further, according to this example, at time t₆, all signals “a”, “a_{d1}”, “a_{d2}”, and “Z” are again at logic zeros (0s), which is the same state as prior to time t₁. The configuration of the GABUF 1100 at such state has been previously discussed. At time t₇, the input signal “a” transitions to a logic one (1) in accordance with a second (positive) pulse burst. Similarly, the states at times t₇ to t₁₀ are the same as the states at times t₁ to t₄, respectively, where the configurations of the GABUF 1100 at such states has been previously discussed.

In this example, the second pulse burst differs from the first pulse burst in that the period t_glitch2 (t₁₁−t₇) is less than the pulse width w_glitch2 plus the delay δ_{buf}/2 (t₁₂31 t₇). Thus, the condition t_glitch2>w_glitch2+δ_{buf}/2 is not met; and therefore, the GABUF 1100 propagates a pulse. More specifically, at time t₁₁, the input signal “a” transitions to a logic one (1) in accordance with the second pulse burst. This occurs before the first delayed input signal “a_{d1}” transitions to a logic zero (0) at time t₁₂. As a result, all the input signals “a”, “a_{d1}”, and “a_{d2}” are at logic ones (1s) between times t₁₁ and t₁₂. During this interval, NMOS FETs M35, M36, and M38 are turned on to pull down the inverted output node Z_{b} to Vss potential, and PMOS FETs M31, M32, and M34 are turned off to electrically isolate (decouple) the inverted output node Z_{b} from Vdd potential. Accordingly, the inverted output node Z_{b} is at a logic zero (0), and the inverter 1130 generates the output signal “Z” as a logic one (1), as shown in the timing diagram. The output signal “Z” at a logic one (1) further turns off PMOS FET M33 and turns on NMOS FET M37.

The output signal “Z” remains at a logic one (1) until time t₁₃, when all input signals “a”, “a_{d1}”, and “a_{d2}” become logic zeros (0s). At which time, the output signal “Z” becomes a logic zero (0). Between times t₁₂ and t₁₃, the signals are at: (1) a=1, a_{d1}=0, a_{d2}=1, and Zᵢ=Z=1; (2) a=1, a_{d1}=1 a_{d2}=1, and Zᵢ=Z=1; (3) a=1, a_{d1}=1, a_{d2}=0, and Zᵢ=Z=1; (4) a=0, a_{d1}=1, a_{d2}=0, and Zᵢ=Z=1; (5) a=0, a_{d1}=1, a_{d2}=1, and Zᵢ=Z=1; and (6) a=0, a_{d1}=0, a_{d2}=1, and Zᵢ=Z=1. With Z being at a logic one (1) and one of “a”, “a_{d1}” and “a_{d2}” being a logic one (1) per states (1) to (6), the inverted output node Z_{b} either remains pulled down to Vss potential via turned-on NMOS FET M35, or tristated to capacitively hold a logic zero (0) at the inverted output node Z_{b}. Thus, between times t₁₂−t₁₃, the GABUF 1100 generates the output signal “Z” at a logic one (1).

With further reference to FIG. 10C, prior to time t₁₄, the input signals “a”, “a_{d1}”, and “a_{d2}” are all at logic ones (1s). The input signals “a”, “a_{d1}”, and “a_{d2}” at logic ones (1s) turn off PMOS FETs M31, M32, and M34, and turn on NMOS FETs M38, M36, and M35, respectively. Accordingly, the inverted output node Z_{b} is pulled down to a logic zero (0) (e.g., Vss potential) via turned-on NMOS FETs M35, M36, and M38, and is electrically isolated (decoupled) from Vdd potential via turned-off NMOS FETs M31, M32, and M34. The inverter 1130 inverts the logic zero (0) at the inverted output node Z_{b} to produce the output signal “Z” at a logic one (1), as indicated in the timing diagram. The output signal “Z” at a logic zero (1) turns off PMOS FET M33 and turns on NMOS FET M37.

At time t₁₄, the input signal “a” transitions to a logic zero (0) in accordance with a third (negative) pulse burst. The input signal “a” being at a logic zero (0) turns on PMOS FET M31 and turns off NMOS FET M38. However, the inverted output node Z_{b} remains pulled down to a logic zero (0) via turned-on NMOS FETs M35 and M37, and electrically isolated from Vdd potential via turned-off PMOS FETs M32, M34 and M33. Thus, the inverter 1130 continues to invert the logic zero (0) at the inverted output node Z_{b} to produce the output signal “Z” at a logic one (1), as shown in the timing diagram.

At time t₁₅, the first delayed input signal “a_{d1}” transitions to a logic zero (0). The first delayed input signal “a_{d1}” being at a logic zero (0) turns on PMOS FET M32 and turns off NMOS FET M36. However, the inverted output node Z_{b} remains pulled down to a logic zero (0) via turned-on NMOS FETs M35 and M37, and electrically isolated from Vdd potential due to turned-off PMOS FETs M34 and M33. Thus, the inverter 1130 continues to invert the logic zero (0) at the inverted output node Z_{b} to produce the output signal “Z” at a logic one (1), as shown in the timing diagram.

At time t₁₆, the input signal “a” transitions back to a logic one (1) in accordance with the third pulse burst. The input signal “a” being at a logic one (1) turns off PMOS FET M31 and turns on NMOS FET M38. However, the inverted output node Z_{b} remains pulled down to a logic zero (0) via turned-on NMOS FETs M35 and M37, and electrically isolated from Vdd potential due to turned-off NMOS FETs M31, M34, and M33. Thus, the inverter 1130 continues to invert the logic zero (0) at the inverted output node Z_{b} to produce the output signal “Z” at a logic one (1), as shown in the timing diagram.

At time t₁₇, the second delayed input signal “a_{d2}” transitions to a logic zero (0). The second delayed input signal “a_{d2}” being at a logic zero (0) turns on PMOS FET M34 and turns off NMOS FET M35. In this configuration, the inverted output node Z_{b} is tristated (e.g., no electrical paths to Vdd and Vss), and capacitively holds a logic zero (0). Thus, the inverter 1130 continues to invert the logic zero (0) at the inverted output node Z_{b} to produce the output signal “Z” at a logic one (1), as shown in the timing diagram.

At time t₁₈, the input signal “a” transitions again to a logic zero (0) in accordance with the third (negative) pulse burst, and the first delayed input signal “a_{d1}” transitions back to a logic one (1). The input signal “a” being at a logic zero (0) turns on PMOS FET M31 and turns off NMOS FET M38. The first delayed input signal “a_{d1}” being at a logic one (1) turns off PMOS FET M32 and turns on NMOS FET M36. However, the inverted output node Z_{b} remains tristated to capacitively hold a logic zero (0). Thus, the inverter 1130 continues to invert the logic zero (0) at the inverted output node Z_{b} to produce the output signal “Z” at a logic zone (1), as shown in the timing diagram.

Thus, the GABUF 1100 is able to suppress the outputting of negative pulses in this example. This is because the two conditions are met: w_glitch3<δ_{buf} and t_glitch3>w_glitch3+δ_{buf}/2. For example, the pulse width w_glitch3 (t₁₆−t₁₄) is less than the δ_{buf} (t₁₇−t₁₄); and the period t_glitch1 (t₁₈−t₁₄) of the pulses is greater or equal to w_glitch3+δ_{buf}/2 (t₁₈−t₁₄).

Further, according to this example, at time t₁₉, all signals “a”, “a_{d1}”, “a_{d2}”, and “Z” are again at logic ones (1s), which is the same state as prior to time t₁₄. The configuration of the GABUF 1100 at such state has been previously discussed. At time t₂₀, the input signal “a” transitions to a logic zero (0) in accordance with a fourth (negative) pulse burst. Similarly, the states at times t₂₀ to t₂₃ are the same as the states at times t₁₄ to t₁₇, respectively, where the configurations of the GABUF 1100 at such states has been previously discussed.

In this example, the fourth pulse burst differs from the third pulse burst in that the period t_glitch4 (t₂₄−t₂₀) is less than the pulse width w_glitch4 plus the delay δ_{buf}/2 (t₂₅−t₂₀). Thus, the condition t_glitch4>w_glitch4+δ_{buf}/2 is not met; and therefore, the GABUF 1100 propagates a pulse. More specifically, at time t₂₄, the input signal “a” transitions to a logic zero (0) in accordance with the fourth pulse burst. This occurs before the first delayed input signal “a_{d1}” transitions to a logic one (1) at time t₂₅. As a result, all the input signals “a”, “a_{d1}”, and “a_{d2}” are at logic zeros (0s) between times t₂₄ and t₂₅. During this interval, PMOS FETs M31, M32, and M34 are turned on to pull up the inverted output node Z_{b} to Vdd potential, and NMOS FETs M35, M36, and M38 are turned off to electrically isolate the inverted output node Z_{b} from Vss potential. Accordingly, the inverted output node Z_{b} is at a logic one (1), and the inverter 1130 generates the output signal “Z” as a logic zero (0), as shown in the timing diagram. The output signal “Z” at a logic zero (0) turns on PMOS FET M33 and turns off NMOS FET M37.

The output signal “Z” remains at a logic zero (0) until time t₂₆, when all input signals “a”, “a_{d1}”, and “a_{d2}” become logic ones (1s). At which time, the output signal “Z” becomes a logic one (1). Between times t₂₅ and t₂₆, the signals are at: (1) a=0, a_{d1}=1, a_{d2}=0, and Zᵢ=Z=0; (2) a=0, a_{d1}=0, a_{d2}=0, and Zᵢ=Z=0; (3) a=0, a_{d1}=0, a_{d2}=1, and Zᵢ=Z=0; (4) a=1, a_{d1}=0, a_{d2}=1, and Zᵢ=Z=0; (5) a=1, a_{d1}=0, a_{d2}=0, and Zᵢ=Z=0; and (6) a=1, a_{d1}=1, a_{d2}=0, and Zᵢ=Z=0. With Z being at a logic zero (0) and one of “a”, “a_{d1}” and “a_{d2}” being a logic zero (0) per states (1) to (6), the inverted output node Z_{b} either remains pulled up to Vdd potential via turned-on PMOS FET M34, or tristated to capacitively hold a logic one (1) at the inverted output node Z_{b}. Thus, between times t₂₅−t₂₆, the GABUF 1100 generates the output signal “Z” at a logic zero (0).

### Three-Input GABUF—Third Implementation

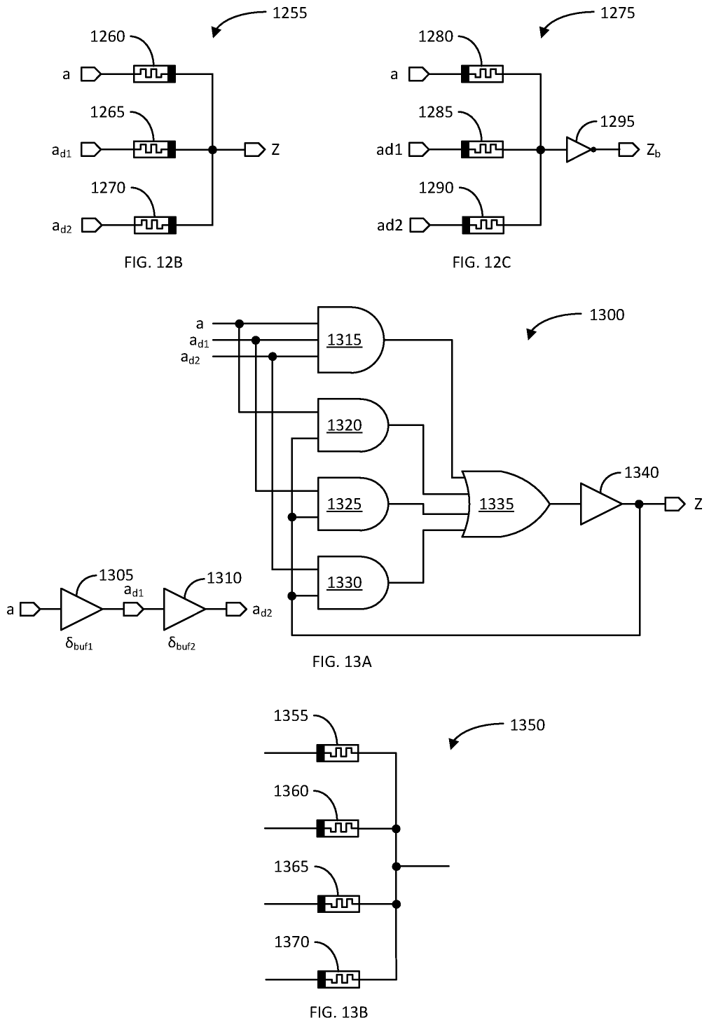

FIG. 12A illustrates a schematic diagram of another example three-input glitch absorbing buffer (GABUF) 1200 in accordance with another aspect of the disclosure. The GABUF 1200 may be another example detailed implementation of the GABUF 900 previously discussed.

The GABUF 1200 includes a first delay element, such as buffer 1210, and a second delay element, such as buffer 1220. The first buffer 1210 is configured to receive an input signal “a”, and delay the input signal “a” by a first delay δ_{buf1} to generate a first delayed input signal “a_{d1}”. The second buffer 1220 includes an input coupled to an output of the first buffer 1210 to receive the first delayed input signal “a_{d1}” therefrom. The second buffer 1220 is configured to delay the first delayed input signal “a_{d1}” by a second delay δ_{buf2} to generate a second delayed input signal “a_{d2}” at an output thereof.

The GABUF 1200 further includes a logic circuit including a three-input AND gate 1230 including inputs configured to receive the input signal “a”, the first delayed input signal “a_{d1}”, and the delayed input signal “a_{d2}”, respectively. Additionally, the logic circuit further includes a three-input NOR gate 1240 (e.g., an OR gate followed by an inverter) including inputs configured to receive the input signal “a”, the first delayed input signal “a_{d1}”, and the second delayed input signal “a_{d2}”, respectively.

Further, the logic circuit includes a data storage cell in the form of cross-coupled first and second inverters 1250 and 1252. The first inverter 1250 includes a PMOS FET M39 and an NMOS FET M41 coupled in series between an upper voltage rail Vdd and a lower voltage rail Vss (e.g., ground). The second inverter 1252 includes a PMOS FET M40 and an NMOS FET M42 coupled in series between the upper voltage rail Vdd and the lower voltage rail Vss.

More specifically, the PMOS FET M39 includes a source coupled to the upper voltage rail Vdd, a gate coupled to drains of PMOS FET M40 and NMOS FET M42, and a drain coupled to a drain of NMOS FET M41. The NMOS FET M41 includes a gate coupled to the drains of PMOS FET M40 and NMOS FET M42, and a source coupled to the lower voltage rail Vss. Similarly, the PMOS FET M40 includes a source coupled to the upper voltage rail Vdd, a gate coupled to the drains of PMOS FET M39 and NMOS FET M41, and the drain coupled to the drain of NMOS FET M42. The NMOS FET M42 includes a gate coupled to the drains of PMOS FET M39 and NMOS FET M41, and a source coupled to the lower voltage rail Vss.

The first and second inverters 1250 and 1252 are cross-coupled because the output (drains of FETs M39/M41) of the first inverter 1250 is coupled to the input (gates of FETs M40/M42) of the second inverter 1252, and the output (drains of FETs M40/M42) of the second inverter 1252 is coupled to the input (gates of FETs M39/M41) of the first inverter 1250. The AND gate 1230 includes an output coupled to the output (drains of FETs M39/M41) of the first inverter 1250, and the NOR gate 1240 includes an output coupled to the output (drains of FETs M40/M42) of the second inverter 1252. The output of the inverter first 1250 is configured to generate an output signal “Z”, and the output of the second inverter 1252 is configured to generate a complementary output signal “Z_{b} ”. The operation of the GABUF 1200 is discussed below with further reference to the timing diagrams of FIGS. 10B-10C.

With further reference to FIG. 10B, prior to time t₁, the input signals “a”, “a_{d1}”, and “a_{d2}” are all at logic zeros (0s). The input signals “a”, “a_{d1}”, and “a_{d2}” at logic zeros (0s) cause the AND gate 1230 to output a logic zero (0), and cause the NOR gate 1240 to output a logic one (1). The logic zero (0), at the output of the AND gate 1230, being coupled to the input of the second inverter 1252, causes the second inverter 1252 to output the complementary output signal “Z_{b} ” as a logic one (1) (consistent with the output of the NOR gate 1240). And, the logic zero (1), at the output of the NOR gate 1240, being coupled to the input of the first inverter 1250, causes the first inverter 1250 to generate the output signal “Z” as a logic zero (0) (consistent with the output of the AND gate 1230), as shown in the timing diagram.

At time t₁, the input signal “a” transitions to a logic one (1) in accordance with a first (positive) pulse burst. In response, the AND gate 1230 continues to output a logic zero (0), and the NOR gate 1240 attempts to output a logic zero (0). The logic zero (0), at the output of the AND gate 1230, being coupled to the input of the second inverter 1252, causes the second inverter 1252 to output the complementary output signal “Z_{b} ” as a logic one (1) (which is inconsistent with the output of the NOR gate 1240) Similar to GABUF 700 previously discussed, the pull-up PMOS FET M40 is implemented stronger (larger in size or W/L) than the pull-down NMOS FET or device (not shown) of the NOR gate 1240 to maintain the complementary output signal “Z_{b} ” at a logic one (1). The complementary output signal “Z_{b} ”, being coupled to the input of the first inverter 1250, causes the first inverter 1250 to generate the output signal “Z” as a logic zero (0) (consistent with the output of the AND gate 1230), as shown in the timing diagram.

At time t₂, the first delayed input signal “a_{d1}” transitions to a logic one (1). In response, the AND gate 1230 continues to output a logic zero (0), and the NOR gate 1240 still attempts to output a logic zero (0). The logic zero (0), at the output of the AND gate 1230, being coupled to the input of the second inverter 1252, causes the second inverter 1252 to output the complementary output signal “Z_{b} ” as a logic one (1). As discussed, the pull-up PMOS FET M40 is implemented stronger than the pull-down NMOS FET (or device) of the NOR gate 1240 to maintain the complementary output signal “Z_{b} ” at a logic one (1). The complementary output signal “Z_{b} ”, being coupled to the input of the first inverter 1250, causes the first inverter 1250 to generate the output signal “Z” as a logic zero (0) (consistent with the output of the AND gate 1230), as shown in the timing diagram.

At time t₃, the input signal “a” transitions back to a logic zero (0) in accordance with the first pulse burst. In response, the AND gate 1230 continues to output a logic zero (0), and the NOR gate 1240 still attempts to output a logic zero (0). The logic zero (0), at the output of the AND gate 1230, being coupled to the input of the second inverter 1252, causes the second inverter 1252 to output the complementary output signal “Z_{b} ” as a logic one (1). As discussed, the pull-up PMOS FET M40 is implemented stronger than the pull-down NMOS FET (or device) of the NOR gate 1240 to maintain the complementary output signal “Z_{b} ” at a logic one (1). The complementary output signal “Z_{b} ”, being coupled to the input of the first inverter 1250, causes the first inverter 1250 to generate the output signal “Z” as a logic zero (0) (consistent with the output of the AND gate 1230), as shown in the timing diagram.

At time t₄, the second delayed input signal “a_{d2}” transitions to a logic one (1). In response, the AND gate 1230 continues to output a logic zero (0), and the NOR gate 1240 still attempts to output a logic zero (0). The logic zero (0), at the output of the AND gate 1230, being coupled to the input of the second inverter 1252, causes the second inverter 1252 to output the complementary output signal “Z_{b} ” as a logic one (1). As discussed, the pull-up PMOS FET M40 is implemented stronger than the pull-down NMOS FET (or device) of the NOR gate 1240 to maintain the complementary output signal “Z_{b} ” at a logic one (1). The complementary output signal “Z_{b} ”, being coupled to the input of the first inverter 1250, causes the first inverter 1250 to generate the output signal “Z” as a logic zero (0) (consistent with the output of the AND gate 1230), as shown in the timing diagram.

At time t₅, the input signal “a” transitions again to a logic one (1) in accordance with the first (positive) pulse burst, and the first delayed input signal “a_{d1}” transitions back to a logic zero (0). In response, the AND gate 1230 continues to output a logic zero (0), and the NOR gate 1240 still attempts to output a logic zero (0). The logic zero (0), at the output of the AND gate 1230, being coupled to the input of the second inverter 1252, causes the second inverter 1252 to output the complementary output signal “Z_{b} ” as a logic one (1). As discussed, the pull-up PMOS FET M40 is implemented stronger than the pull-down NMOS FET (or device) of the NOR gate 1240 to maintain the complementary output signal “Z_{b} ” at a logic one (1). The complementary output signal “Z_{b} ”, being coupled to the input of the first inverter 1250, causes the first inverter 1250 to generate the output signal “Z” as a logic zero (0) (consistent with the output of the AND gate 1230), as shown in the timing diagram.

Thus, the GABUF 1200 is able to suppress the outputting of positive pulses in this example. This is because the two conditions are met: w_glitch1<δ_{buf} and t_glitch1>w_glitch1+δ_{buf}/2. For example, the pulse width w_glitch 1 (t₃−t₁) is less than the δ_{buf} (t₄−t₁); and the period t_glitch1 (t₅−t₁) of the pulses is greater or equal to w_glitch 1+δ_{buf}/2 (t₅31 t₁).

Further, according to this example, at time t₆, all signals “a”, “a_{d1}”, “a_{d2}”, and “Z” are again at logic zeros (0s), which is the same state as prior to time t₁. The configuration of the GABUF 1200 at such state has been previously discussed. At time t₇, the input signal “a” transitions to a logic one (1) in accordance with a second (positive) pulse burst. Similarly, the states at times t₇ to t₁₀ are the same as the states at times t₁ to t₄, respectively, where the configurations of the GABUF 1200 at such states has been previously discussed.

In this example, the second pulse burst differs from the first pulse burst in that the period t_glitch2 (t₁₁−t₇) is less than the pulse width w_glitch2 plus the delay δ_{buf}/2 (t₁₂−t₇). Thus, the condition t_glitch2>w_glitch2+δ_{buf}/2 is not met; and therefore, the GABUF 1200 propagates a pulse. More specifically, at time t₁₁, the input signal “a” transitions to a logic one (1) in accordance with the second pulse burst. This occurs before the first delayed input signal “a_{d1}” transitions to a logic zero (0) at time t₁₂. As a result, all the input signals “a”, “a_{d1}”, and “a_{d2}” are at logic ones (1s) between times t₁₁ and t₁₂.

The input signals “a”, “a_{d1}”, and “a_{d2}” at logic ones (1s) cause the AND gate 1230 to output a logic one (1), and cause the NOR gate 1240 to output a logic zero (0). The logic one (1), at the output of the AND gate 1230, being coupled to the input of the second inverter 1252, causes the second inverter 1252 to output the complementary output signal “Z_{b} ” as a logic zero (0) (consistent with the output of the NOR gate 1240). And, the logic zero (0), at the output of the NOR gate 1240, being coupled to the input of the first inverter 1250, causes the first inverter 1250 to output the output signal “Z” as a logic one (1) (consistent with the output of the AND gate 1230), as shown in the timing diagram.

The output signal “Z” remains at a logic one (1) until time t₁₃, when all input signals “a”, “a_{d1}”, and “a_{d2}” become logic zeros (0s). At which time, the output signal “Z” becomes a logic zero (0). Between times t₁₂ and t₁₃, the signals are at: (1) a=1, a_{d1}=0, a_{d2}=1, and Zᵢ=Z=1; (2) a=1, a_{d1}=1 , a_{d2}=1, and Zᵢ=Z=1; (3) a=1, a_{d1}=1, a_{d2}=0, and Zᵢ=Z=1; (4) a=0, a_{d1}=1, a_{d2}=0, and Zᵢ=Z=1; (5) a=0, a₁=1, a_{d2}=1, and Zᵢ=Z=1; and (6) a=0, a₁=0, a_{d2}=1, and Zᵢ=Z=1. With Z being at a logic one (1) and one of “a”, “a_{d1}” and “a_{d2}” being a logic one (1) per states (1) to (6), the output signal “Z” remains at a logic one (1), although the AND gate 1230 attempts to output a logic zero (0) due to at least one of the “a”, “a_{d1}” and “a_{d2}” being a logic zero (0). Similarly, the pull-up PMOS FET M39 is implemented stronger (larger in size or W/L) than the pull-down NMOS FET or device (not shown) of the AND gate 1230 to maintain the output signal “Z” at a logic one (1).

With further reference to FIG. 10C, prior to time t₁₄, the input signals “a”, “a_{d1}”, and “a_{d2}”

are all at logic ones (1s). The input signals “a”, “a_{d1}”, and “a_{d2}” at logic ones (1s) cause the AND gate 1230 to output a logic one (1), and cause the NOR gate 1240 to output a logic zero (0). The logic one (1), at the output of the AND gate 1230, being coupled to the input of the second inverter 1252, causes the second inverter 1252 to output the complementary output signal “Z_{b} ” as a logic zero (0) (consistent with the output of the NOR gate 1240). And, the logic zero (0), at the output of the NOR gate 1240, being coupled to the input of the first inverter 1250, causes the first inverter 1250 to output the output signal “Z” as a logic one (1) (consistent with the output of the AND gate 1230), as shown in the timing diagram.

At time t₁₄, the input signal “a” transitions to a logic zero (0) in accordance with a third (negative) pulse burst. In response, the AND gate 1230 attempts to output a logic zero (0), and the NOR gate 1240 outputs a logic zero (0). The logic zero (0), at the output of the NOR gate 1240, being coupled to the input of the first inverter 1250, causes the first inverter 1250 to output the output signal “Z” as a logic one (1), as shown in the timing diagram. As discussed, the pull-up PMOS FET M39 is implemented stronger than the pull-down NMOS FET (or device) of the AND gate 1230 to maintain the output signal “Z” at a logic one (1). The output signal “Z”, being coupled to the input of the second inverter 1252, causes the second inverter 1252 to output the complementary output signal “Z_{b} ” as a logic zero (0) (consistent with the output of the NOR gate 1240).

At time t₁₅, the first delayed input signal “a_{d1}” transitions to a logic zero (0). In response, the AND gate 1230 still attempts to output a logic zero (0), and the NOR gate 1240 continues to output a logic zero (0). The logic zero (0), at the output of the NOR gate 1240, being coupled to the input of the first inverter 1250, causes the first inverter 1250 to output the output signal “Z” as a logic one (1), as shown in the timing diagram. As discussed, the pull-up PMOS FET M39 is implemented stronger than the pull-down NMOS FET (or device) of the AND gate 1230 to maintain the output signal “Z” at a logic one (1). The output signal “Z”, being coupled to the input of the second inverter 1252, causes the second inverter 1252 to output the complementary output signal “Z_{b} ” as a logic zero (0) (consistent with the output of the NOR gate 1240).

At time t₁₆, the input signal “a” transitions back to a logic one (1) in accordance with the first pulse burst. In response, the AND gate 1230 still attempts to output a logic zero (0), and the NOR gate 1240 continues to output a logic zero (0). The logic zero (0), at the output of the NOR gate 1240, being coupled to the input of the first inverter 1250, causes the first inverter 1250 to output the output signal “Z” as a logic one (1), as shown in the timing diagram. As discussed, the pull-up PMOS FET M39 is implemented stronger than the pull-down NMOS FET (or device) of the AND gate 1230 to maintain the output signal “Z” at a logic one (1). The output signal “Z”, being coupled to the input of the second inverter 1252, causes the second inverter 1252 to output the complementary output signal “Z_{b} ” as a logic zero (0) (consistent with the output of the NOR gate 1240).

At time t₁₇, the second delayed input signal “a_{d2}” transitions to a logic zero (0). In response, the AND gate 1230 still attempts to output a logic zero (0), and the NOR gate 1240 continues to output a logic zero (0). The logic zero (0), at the output of the NOR gate 1240, being coupled to the input of the first inverter 1250, causes the first inverter 1250 to output the output signal “Z” as a logic one (1), as shown in the timing diagram. As discussed, the pull-up PMOS FET M39 is implemented stronger than the pull-down NMOS FET (or device) of the AND gate 1230 to maintain the output signal “Z” at a logic one (1). The output signal “Z”, being coupled to the input of the second inverter 1252, causes the second inverter 1252 to output the complementary output signal “Z_{b} ” as a logic zero (0) (consistent with the output of the NOR gate 1240).

At time t₁₈, the input signal “a” transitions again to a logic zero (0) in accordance with the third (negative) pulse burst, and the first delayed input signal “a_{d1}” transitions back to a logic one (1). In response, the AND gate 1230 still attempts to output a logic zero (0), and the NOR gate 1240 continues to output a logic zero (0). The logic zero (0), at the output of the NOR gate 1240, being coupled to the input of the first inverter 1250, causes the first inverter 1250 to output the output signal “Z” as a logic one (1), as shown in the timing diagram. As discussed, the pull-up PMOS FET M39 is implemented stronger than the pull-down NMOS FET (or device) of the AND gate 1230 to maintain the output signal “Z” at a logic one (1). The output signal “Z”, being coupled to the input of the second inverter 1252, causes the second inverter 1252 to output the complementary output signal “Z_{b} ” as a logic zero (0) (consistent with the output of the NOR gate 1240).

Thus, the GABUF 1200 is able to suppress the outputting of negative pulses in this example. This is because the two conditions are met: w_glitch3<δ_{buf} and t_glitch3>w_glitch3+δ_{buf}/2. For example, the pulse width w_glitch1 (t₁₆−t₁₄) is less than the δ_{buf} (t₁₇−t₁₄); and the period t_glitch1 (t₁₈−t₁₄) of the pulses is greater or equal to w_glitch1+δ_{buf}/2 (t₁₈−t₁₄).

Further, according to this example, at time t₁₉, all signals “a”, “a_{d1}”, “a_{d2}”, and “Z” are again at logic ones (1s), which is the same state as prior to time t₁₄. The configuration of the GABUF 1200 at such state has been previously discussed. At time t₂₀, the input signal “a” transitions to a logic zero (0) in accordance with a fourth (negative) pulse burst. Similarly, the states at times t₂₀ to t₂₃ are the same as the states at times t₁₄ to t₁₇, respectively, where the configurations of the GABUF 1200 at such states has been previously discussed.

In this example, the fourth pulse burst differs from the third pulse burst in that the period t_glitch4 (t₂₄−t₂₀) is less than the pulse width w_glitch4 plus the delay δ_{buf}/2 (t₂₅−t₂₀). Thus, the condition t_glitch4>w_glitch4 +δ_{buf}/2 is not met; and therefore, the GABUF 1200 propagates a pulse. More specifically, at time t₂₄, the input signal “a” transitions to a logic zero (0) in accordance with the fourth pulse burst. This occurs before the first delayed input signal “a_{d1}” transitions to a logic one (1) at time t₂₅. As a result, all the input signals “a”, “a_{d1}”, and “a_{d2}” are at logic zeros (0s) between times t₂₄ and t₂₅.

The input signals “a”, “a_{d1}”, and “a_{d2}” at logic zeros (0s) cause the AND gate 1230 to output a logic zero (0), and cause the NOR gate 1240 to output a logic one (1). The logic zero (0), at the output of the AND gate 1230, being coupled to the input of the second inverter 1252, causes the second inverter 1252 to output the complementary output signal “Z_{b} ” as a logic one (1) (consistent with the output of the NOR gate 1240). And, the logic one (1), at the output of the NOR gate 1240, being coupled to the input of the first inverter 1250, causes the first inverter 1250 to output the output signal “Z” as a logic zero (0) (consistent with the output of the AND gate 1230), as shown in the timing diagram.

The output signal “Z” remains at a logic zero (0) until time t₂₆, when all input signals “a”, “a_{d1}”, and “a_{d2}” become logic ones (1s). At which time, the output signal “Z” becomes a logic one (1). Between times t₂₅ and t₂₆, the signals are at: (1) a=0, a_{d1}=1, a_{d2}=0, and Zᵢ=Z=0; (2) a=0, a_{d1}=0, a_{d2}=0, and Zᵢ=Z=0; (3) a=0, a_{d1}=0, a_{d2}=1, and Zᵢ=Z=0; (4) a=1, a_{d1}=0, a_{d2}=1, and Zᵢ=Z=0; (5) a=1, a_{d1}=0, a_{d2}=0, and Zᵢ=Z=0; and (6) a=1, a_{d1}=1, a_{d2}=0, and Zᵢ=Z=0. With Z being at a logic zero (0) and one of “a”, “a_{d1}” and “a_{d2}” being a logic one (1) per states (1) to (6), the output signal “Z” remains at a logic zero (0), while the complementary output signal “Z_{b} ” remains at a logic one (1). Although the NOR gate 1240 attempts to output a logic zero (0) due to at least one of the “a”, “a_{d1}” and “a_{d2}” being a logic one (1), the pull-up PMOS FET M40 is implemented stronger than the pull-down NMOS FET (or device) of the NOR gate 1240 to maintain the complementary output signal “Z_{b} ” at a logic one (1).

FIG. 12B illustrates a schematic diagram of an example three-input logic AND gate 1255 in accordance with another aspect of the disclosure. The AND gate 1230 of three-input GABUF 1200 may be implemented as a transistor-based AND gate. Alternatively, the AND gate 1230 may be implemented with memristors to save IC area and power consumption. The AND gate 1255 is an example of a memristor-based AND gate.

In particular, the AND gate 1255 includes a first memristor 1260, a second memristor 1265, and a third memristor 1270. The first memristor 1260 has an undoped-side terminal configured to receive the input signal “a”. The second memristor 1265 has an undoped-side terminal configured to receive the first delayed input signal “a_{d1}”. The third memristor 1270 has an undoped-side terminal configured to receive the second delayed input signal “a_{d2}”. The first, second, and third memristors 1260, 1265, and 1270 include doped-side terminals coupled together at a node at which the output signal “Z” is produced.

In operation, if the signals “a”, “a_{d1}”, and “a_{d2}” are all at logic zeros (0s), there is substantially no current flowing through the first, second, and third memristors 1260, 1265, and 1270. Thus, the AND gate 1255 outputs or attempts to output a logic zero (0). Similarly, if the signals “a”, “a_{d1}”, and “a_{d2}” are all at logic ones (1s), there is substantially no current flowing through the first, second, and third memristors 1260, 1265, and 1270. Thus, the AND gate 1255 outputs a logic one (1).

If one or two of the signals “a”, “a_{d1}”, and “a_{d2}” are at logic one (1) and the rest is at logic zero (0), then there is current flowing from the input(s) at logic one (1) to the input(s) at logic zero (0). The resistance of the one or two memristors coupled to the inputs at logic zero (0) is relatively low at R_{ON}, and the resistance of the one or two memristors coupled to the inputs at logic zero (0) is relatively high at R_{OFF} Due to voltage division, and assuming no influence from the data storage cell, the output of the AND gate 1255 is at a logic zero (0) (V_{z}=Vdd*R_{ON}/(R_{ON}+R_{OFF})≈Vss).

FIG. 12C illustrates a schematic diagram of an example three-input logic NOR gate 1275 in accordance with another aspect of the disclosure. The NOR gate 1240 of three-input GABUF 1200 may be implemented as a transistor-based NOR gate. Alternatively, the NOR gate 1240 may be implemented with memristors to save IC area and power consumption. The NOR gate 1275 is an example of a memristor-based NOR gate.

In particular, the NOR gate 1275 includes a first memristor 1280, a second memristor 1285, a third memristor 1290, and an inverter 1295. The first memristor 1280 has a doped-side terminal configured to receive the input signal “a”. The second memristor 1285 has a doped-side terminal configured to receive the first delayed input signal “a_{d1}”. The third memristor 1290 has a doped-side terminal configured to receive the second delayed input signal “a_{d2}”. The first, second, and third memristors 1280, 1285, and 1290 include undoped-side terminals coupled together at an input of the inverter 1295. The inverter 1295 includes an output at which the complementary output signal “Z_{b} ” is produced.

In operation, if the signals “a”, “a_{d1}”, and “a_{d2}” are all at logic zeros (0s), there is substantially no current flowing through the first, second, and third memristors 1280, 1285, and 1290. Thus, the input of the inverter 1295 is at a logic zero (0); and thus, the inverter 1295 outputs a logic one (1). Similarly, if the signals “a”, “a_{d1}”, and “a_{d2}” are all at logic ones (1s), there is substantially no current flowing through the first, second, and third memristors 1280, 1285, and 1290. Thus, the input of the inverter 1295 is at a logic one (1); and thus, the inverter 1295 outputs or attempts to output a logic zero (0).

If one or two of the signals “a”, “a_{d1}”, and “a_{d2}” are at logic one (1) and the rest is at logic zero (0), then there is current flowing from the input(s) at logic one (1) to the input(s) at logic zero (0). The resistance of the one or two memristors coupled to the inputs at logic zero (0) is relatively high at R_{OFF}, and the resistance of the one or two memristors coupled to the inputs at logic one (1) is relatively low at R_{ON}. Due to voltage division, the input of the inverter 1295 is at a logic one (1) (V_{INV-IN}=Vdd*R_{OFF}/(R_{ON}+R_{OFF})≈Vdd). The inverter 1295 inverts or attempts to invert the logic one (1) to output a logic zero (0).

### Three-Input GABUF—Fourth Implementation

FIG. 13A illustrates a schematic diagram of another example three-input glitch absorbing buffer (GABUF) 1300 in accordance with another aspect of the disclosure. The GABUF 1300 may be another example detailed implementation of the GABUF 900 previously discussed.

The GABUF 1300 includes a first delay element, such as buffer 1305, and a second delay element, such as buffer 1310. The first buffer 1305 is configured to receive an input signal “a”, and delay the input signal “a” by a first delay δ_{buf1} to generate a first delayed input signal “a_{d1}”. The second buffer 1310 includes an input coupled to an output of the first buffer 1305 to receive the first delayed input signal “a_{d1}” therefrom. The second buffer 1310 is configured to delay the first delayed input signal “a_{d1}” by a second delay δ_{buf2} to generate a second delayed input signal “a_{d2}” at an output thereof.

The GABUF 1300 further includes a logic circuit including a three-input AND gate 1315, a first two-input AND gate 1320, a second two-input AND gate 1325, a third two-input AND gate 1330, a four-input OR gate 1335, and a buffer 1340. The three-input AND gate 1315 includes a first input configured to receive the input signal “a”, a second input coupled to an output of the first buffer 1305 to receive the first delayed input signal “a_{d1}” therefrom, and a third input coupled to an output of the second buffer 1310 to receive the second delayed input signal “a_{d2}” therefrom.

The two-input AND gate 1320, in turn, includes a first input configured to receive the input signal “a”, and a second input coupled to an output of the buffer 1340 to receive an output signal “Z” therefrom. The two-input AND gate 1325, in turn, includes a first input coupled to the output of the first buffer 1305 to receive the first delayed input signal “a_{d1}” therefrom, and a second input coupled to the output of the buffer 1340 to receive the output signal “Z” therefrom. The two-input AND gate 1330, in turn, includes a first input coupled to the output of the second buffer 1310 to receive the second delayed input signal “a_{d2}” therefrom, and a second input coupled to the output of the buffer 1340 to receive the output signal “Z” therefrom.

The four-input OR gate 1335 includes inputs coupled to outputs of the AND gates 1315, 1320, 1325, and 1330, respectively. The four-input OR gate 1335 includes an output coupled to an input of the buffer 1340. The operation of the GABUF 1300 is discussed below with further reference to the timing diagrams of FIGS. 10B-10C.

With further reference to FIG. 10B, prior to time t₁, the signals “a”, “a_{d1}”, “a_{d2}” and “Z” are all at logic zeros (0s). In response, all the AND gates 1315, 1320, 1325, and 1330 output logic zeros (0s). In response, the OR gate 1335 outputs a logic zero (0). And, in response, the buffer 1340 generates the output signal “Z” as a logic zero (0), as shown in the timing diagram.

At time t₁, the input signal “a” transitions to a logic one (1) in accordance with a first (positive) pulse burst. In response, the affected AND gates 1315 and 1320 continue to output logic zeros (0s) due to the first delayed input signal “a_{d1}” and the output signal “Z” both being a logic zero (0), respectively. In response, the OR gate 1335 continues to output a logic zero (0). And, in response, the buffer 1340 continues to generate the output signal “Z” as a logic zero (0), as shown in the timing diagram.

At time t₂, the first delayed input signal “a_{d1}” transitions to a logic one (1). In response, the affected AND gates 1315 and 1325 continue to output logic zeros (0s) due to the second delayed input signal “a_{d2}” and the output signal “Z” both being a logic zero (0), respectively. In response, the OR gate 1335 continues to output a logic zero (0). And, in response, the buffer 1340 continues to generate the output signal “Z” as a logic zero (0), as shown in the timing diagram.

At time t₃, the input signal “a” transitions back to a logic zero (0) in accordance with the first pulse burst. In response, the affected AND gates 1315 and 1320 continue to output logic zeros (0s). In response, the OR gate 1335 continues to output a logic zero (0). And, in response, the buffer 1340 continues to generate the output signal “Z” as a logic zero (0), as shown in the timing diagram.

At time t₄, the second delayed input signal “a_{d2}” transitions to a logic one (1). In response, the affected AND gates 1315 and 1330 continue to output logic zeros (0s) due to the input signal “a” and the output signal “Z” both being at logic zeros (0s), respectively. In response, the OR gate 1335 continues to output a logic zero (0). And, in response, the buffer 1340 continues to generate the output signal “Z” as a logic zero (0), as shown in the timing diagram.

At time t₅, the input signal “a” transitions again to a logic one (1) in accordance with the first (positive) pulse burst, and the first delayed input signal “a_{d1}” transitions back to a logic zero (0). In response, the affected AND gates 1315, 1320, and 1325 continue to output logic zero(s). In response, the OR gate 1335 continues to output a logic zero (0). And, in response, the buffer 1340 continues to generate the output signal “Z” as a logic zero (0), as shown in the timing diagram.

Thus, the GABUF 1300 is able to suppress the outputting of positive pulses in this example. This is because the two conditions are met: w_glitch1<δ_{buf} and t_glitch1>w_glitch1+δ_{buf}/2. For example, the pulse width w_glitch1 (t₃−t₁) is less than the δ_{buf} (t₄−t₁); and the period t_glitch1 (t₅−t₁) of the pulses is greater or equal to w_glitch1+δ_{buf}/2 (ₜ−t₁).

Further, according to this example, at time t₆, all signals “a”, “a_{d1}”, “a_{d2}”, and “Z” are again at logic zeros (0s), which is the same state as prior to time t₁. The configuration of the GABUF 1300 at such state has been previously discussed. At time t₇, the input signal “a” transitions to a logic one (1) in accordance with a second (positive) pulse burst. Similarly, the states at times t₇ to t₁₀ are the same as the states at times t₁ to t₄, respectively, where the configurations of the GABUF 1300 at such states has been previously discussed.

In this example, the second pulse burst differs from the first pulse burst in that the period t_glitch2 (t₁₁−t₇) is less than the pulse width w_glitch2 plus the delay δ_{buf} /2 (t₁₂−t₇). Thus, the condition t_glitch2>w_glitch2+≡_{buf}/2 is not met; and therefore, the GABUF 1300 propagates a pulse. More specifically, at time t₁₁, the input signal “a” transitions to a logic one (1) in accordance with the second pulse burst. This occurs before the first delayed input signal “a_{d1}” transitions to a logic zero (0) at time t₁₂. As a result, all the input signals “a”, “a_{d1}”, and “a_{d2}” are at logic ones (1s) between times t₁₁ and t₁₂.

The input signals “a”, “a_{d1}”, and “a_{d2}” at logic ones (1s) cause the AND gate 1315 to output a logic one (1). In response, the OR gate 1335 outputs a logic one (1). And, in response, the buffer 1340 generates the output signal “Z” as a logic one (1), as shown in the timing diagram.

The output signal “Z” remains at a logic one (1) until time t₁₃, when all input signals “a”, “a_{d1}”, and “a_{d2}” become logic zeros (0s). At which time, the output signal “Z” becomes a logic zero (0). Between times t₁₂ and t₁₃, the signals are at: (1) a=1, a_{d1}=0, a_{d2}=1, and Zᵢ=Z=1; (2) a=1, a_{d1}=1, a_{d2}=1, and Zᵢ=Z=1; (3) a=1, a_{d1}=1, a_{d2}=0, and Zᵢ=Z=1; (4) a=0, a_{d1}=1, a_{d2}=0, and Zᵢ=Z=1; (5) a=0, a_{d1}=1, a_{d2}=1, and Zᵢ=Z=1; and (6) a=0, a_{d1}=0, a_{d2}=1, and Zᵢ=Z=1. With Z being at a logic one (1) and one of “a”, “a_{d}1” and “a_{d}2” being a logic one (1) per states (1) to (6) cause a corresponding one of the AND gates 1320, 1325, and 1330 to output a logic one (1). In response, the OR gate 1335 outputs a logic one (1). And, in response, the buffer 1340 generates the output signal “Z” as a logic one (1), as shown in the timing diagram.

With further reference to FIG. 10C, prior to time t₁₄, the signals “a”, “a_{d1}”, “a_{d2}” and “Z” are all at logic ones (1s). In response, all the AND gates 1315, 1320, 1325, and 1330 output logic ones (1s). In response, the OR gate 1335 outputs a logic one (1). And, in response, the buffer 1340 generates the output signal “Z” as a logic one (1), as shown in the timing diagram.

At time t₁₄, the input signal “a” transitions to a logic zero (0) in accordance with a third (negative) pulse burst. In response, the affected AND gates 1315 and 1320 output logic zeros (0s). However, the unaffected AND gates 1325 and 1330 continue to output a logic one (1). In response, the OR gate 1335 continues to output a logic one (1). And, in response, the buffer 1340 continues to generate the output signal “Z” as a logic one (1), as shown in the timing diagram.

At time t₁₅, the first delayed input signal “a_{d1}” transitions to a logic zero (0). In response, the affected AND gates 1325 outputs a logic zero (0). However, the unaffected AND gate 1330 continues to output a logic one (1). In response, the OR gate 1335 continues to output a logic one (1). And, in response, the buffer 1340 continues to generate the output signal “Z” as a logic one (1), as shown in the timing diagram.

At time t₁₆, the input signal “a” transitions back to a logic one (1) in accordance with the third pulse burst. In response, the affected AND gates 1315 and 1320 output a logic one (0) and one (1), respectively. In response, the OR gate 1335 continues to output a logic one (1). And, in response, the buffer 1340 continues to generate the output signal “Z” as a logic one (1), as shown in the timing diagram.

At time t₁₇, the second delayed input signal “a_{d2}” transitions to a logic zero (0). In response, the affected AND gates 1315 and 1330 output logic zeros (0s). However, the unaffected AND gate 1320 continues to output a logic one (1). In response, the OR gate 1335 continues to output a logic one (1). And, in response, the buffer 1340 continues to generate the output signal “Z” as a logic one (1), as shown in the timing diagram.

At time t₁₈, the input signal “a” transitions again to a logic zero (0) in accordance with the third pulse burst, and the first delayed input signal “a_{d1}” transitions back to a logic one (1). In response, the affected AND gates 1315, 1320, and 1325 output logic zero (0), logic zero (0), and logic one (1), respectively. In response, the OR gate 1335 continues to output a logic one (1). And, in response, the buffer 1340 continues to generate the output signal “Z” as a logic one (1), as shown in the timing diagram.

Thus, the GABUF 1300 is able to suppress the outputting of negative pulses in this example. This is because the two conditions are met: w_glitch3<δ_{buf} and t_glitch3>w_glitch3+δ_{buf}/2. For example, the pulse width w_glitch3 (t₁₆−t₁₄) is less than the δ_{buf} (t₁₇−t₁₄); and the period t_glitch3 (t₁₈−t₁₄) of the pulses is greater or equal to w_glitch3+δ_{buf}/2 (t₁₈−t₁₄).

Further, according to this example, at time t₁₉, all signals “a”, “a_{d1}”, “a_{d2}”, and “Z” are again at logic ones (1s), which is the same state as prior to time t₁₄. The configuration of the GABUF 1300 at such state has been previously discussed. At time t₂₀, the input signal “a” transitions to a logic zero (0) in accordance with a fourth (negative) pulse burst. Similarly, the states at times t₂₀ to t₂₃ are the same as the states at times t₁₄ to t₁₇, respectively, where the configurations of the GABUF 1300 at such states has been previously discussed.

In this example, the fourth pulse burst differs from the third pulse burst in that the period t_glitch4 (t₂₄−t₂₀) is less than the pulse width w_glitch4 plus the delay δ_{buf}/2 (t₂₅−t₂₀). Thus, the condition t_glitch4>w_glitch4+δ_{buf}/2 is not met; and therefore, the GABUF 1300 propagates a pulse. More specifically, at time t₂₄, the input signal “a” transitions to a logic zero (0) in accordance with the fourth pulse burst. This occurs before the first delayed input signal “a_{d1}” transitions to a logic one (1) at time t₂₅. As a result, all the input signals “a”, “a_{d1}”, and “a_{d2}” are at logic ones (0s) between times t₂₄ and t₂₅.

The input signals “a”, “a_{d1}”, and “a_{d2}” at logic ones (0s) cause all the AND gates 1315, 1320, 1325, and 1330 to output a logic zero (0). In response, the OR gate 1335 outputs a logic zero (0). And, in response, the buffer 1340 generates the output signal “Z” as a logic zero (0), as shown in the timing diagram.

The output signal “Z” remains at a logic zero (0) until time t₂₆, when all input signals “a”, “a_{d1}”, and “a_{d2}” become logic ones (1s). At which time, the output signal “Z” becomes a logic one (1). Between times t₂₅ and t₂₆, the signals are at: (1) a=0, a_{d1}=1, a_{d2}=0, and Zᵢ=Z=0; (2) a=0, a_{d1}=0, a_{d2}=0, and Zᵢ=Z=0; (3) a=0, a_{d1}=0, a_{d2}=1, and Zᵢ=Z=0; (4) a=1, a_{d1}=0, a_{d2}=1, and Zᵢ=Z=0; (5) a=1, a_{d1}=0, a_{d2}=0, and Zᵢ=Z=0; and (6) a=1, a_{d1}=1, a_{d2}=0, and Zᵢ=Z=0. With Z being at a logic zero (0) and one of “a”, “a_{d1}” and “a_{d2}” being a logic zero (0) per states (1) to (6), the AND gates 1315, 1320, 1325, and 1330 all output a logic zero (0). In response, the OR gate 1335 outputs a logic zero (0). And, in response, the buffer 1340 generates the output signal “Z” as a logic zero (0), as shown in the timing diagram.

FIG. 13B illustrates a schematic diagram of an example four-input logic OR gate 1350 in accordance with another aspect of the disclosure. The OR gate 1335 of three-input GABUF 1300 may be implemented as a transistor-based OR gate. Alternatively, the OR gate 1335 may be implemented with memristors to save IC area and power consumption. The OR gate 1350 is an example of a memristor-based OR gate.

In particular, the OR gate 1350 includes a first memristor 1355, a second memristor 1360, a third memristor 1365, and a fourth memristor 1370. The first memristor 1355 has a doped-side terminal coupled to the output of AND gate 1315. The second memristor 1360 has a doped-side terminal coupled to the output of AND gate 1320. The third memristor 1365 has a doped-side terminal coupled to the output of AND gate 1325. The third memristor 1370 has a doped-side terminal coupled to the output of AND gate 1330. The first, second, third, and fourth memristors 1355, 1360, 1365, and 1370 include undoped-side terminals coupled together and to an input of the buffer 1340.

In operation, if the AND gates 1315, 1320, 1325, and 1330 all output logic zeros (0s), there is substantially no current flowing through the first, second, third, and fourth memristors 1355, 1360, 1365, and 1370. Thus, the OR gate 1350 outputs a logic zero (0). Similarly, if the AND gates 1315, 1320, 1325, and 1330 all output logic ones (1s), there is substantially no current flowing through the first, second, third, and fourth memristors 1355, 1360, 1365, and 1370. Thus, the OR gate 1350 outputs a logic one (1).

If one or more of the AND gates 1315, 1320, 1325, and 1330 outputs a logic one (1) and the rest outputs a logic zero (0), then there is current flowing from the input(s) at logic one (1) to the input(s) at logic zero (0). The resistance of the one or more memristors coupled to the input(s) at logic zero (0) is relatively high at R_{OFF}, and the resistance of the one or two memristors coupled to the input(s) at logic one (1) is relatively low at R_{ON}. Due to voltage division, the OR gate 1350 outputs a logic one (1) (V_{BUF-IN}=Vdd*R_{OFF}/(R_{ON}+R_{OFF})≈Vdd).

### Wireless Communication Device

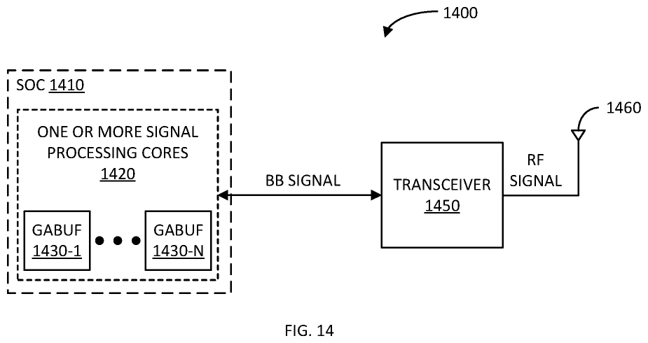

FIG. 14 illustrates a block diagram of an example wireless communication device 1400 in accordance with another aspect of the disclosure. The wireless communication device 1400 may be a smart phone, a desktop computer, laptop computer, tablet device, Internet of Things (IoT), wearable wireless device (e.g., wireless watch), and other types of wireless device.

In particular, the wireless communication device 1400 includes an integrated circuit (IC), which may be implemented as a system on chip (SOC) 1410. The SOC 1410 includes one or more signal processing cores 1420 including a set of glitch absorbing buffers (GABUFs) 1430-1 to 1430-N. The one or more signal processing cores 1420 may use the set of GABUFs 1430-1 to 1430-N to generate a transmit baseband (BB) signal and process a received baseband (BB) signal.

The wireless communication device 1400 may further include a transceiver 1450 and at least one antenna 1460 (e.g., an antenna array). The transceiver 1450 is coupled to the one or more signal processing cores 1420 to receive therefrom the transmit BB signal and provide thereto the received BB signal. The transceiver 1450 is configured to convert the transmit BB signal into a transmit radio frequency (RF) signal, and convert a received RF signal into the received BB signal. The transceiver 1450 is coupled to the at least one antenna 1460 to provide thereto the transmit RF signal for electromagnetic radiation into a wireless medium for wireless transmission, and receive the received RF signal electromagnetically picked up from the wireless medium by the least one antenna 1460.

The following provides an overview of aspects of the present disclosure:

Aspect 1: An apparatus, comprising: a glitch absorbing buffer (GABUF), comprising: a delay element configured to delay an input signal by a delay to generate a delayed input signal; and a logic circuit, responsive to the input signal, the delayed input signal, and an output signal, configured to propagate a pulse in the input signal to the output signal if a width of the pulse is greater than the delay, and suppress the propagating of the pulse to the output signal if the width of the pulse is less than the delay.

Aspect 2: The apparatus of aspect 1, wherein the logic circuit comprises: a pull-up circuit configured to selectively couple a node to a first voltage rail in response to the input signal, the delayed input signal, and the output signal; and a pull-down circuit configured to selectively couple the node to a second voltage rail in response to the input signal, the delayed input signal, and the output signal.

Aspect 3: The apparatus of aspect 2, wherein the pull-up circuit comprises: a first p-channel metal oxide semiconductor field effect transistor (PMOS FET) including a first PMOS source, a first PMOS gate, and a first PMOS drain, wherein the first PMOS source is coupled to the first voltage rail, and wherein the first PMOS gate is configured to receive the input signal; a second PMOS FET including a second PMOS source, a second PMOS gate, and a second PMOS drain, wherein the second PMOS source is coupled to the first voltage rail, and wherein the second PMOS gate is configured to receive the output signal; and a third PMOS FET including a third PMOS source, a third PMOS gate, and a third PMOS drain, wherein the third PMOS source is coupled to the first and second PMOS drains, wherein the third PMOS gate is configured to receive the delayed input signal, and wherein the third PMOS drain is coupled to the node.

Aspect 4: The apparatus of aspect 2 or 3, wherein the pull-down circuit comprises: a first n-channel metal oxide semiconductor field effect transistor (NMOS FET) including a first NMOS drain, a first NMOS gate, and a first NMOS source, wherein the first NMOS drain is coupled to the node, and wherein the first NMOS gate is configured to receive the delayed input signal; a second NMOS FET including a second NMOS drain, a second NMOS gate, and a second NMOS source, wherein the second NMOS drain is coupled to the first NMOS source, wherein the second NMOS gate is configured to receive the input signal, and wherein the second NMOS source is coupled to the second voltage rail; and a third NMOS FET including a third NMOS drain, a third NMOS gate, and a third NMOS source, wherein the third NMOS drain is coupled to the first NMOS source, wherein the third NMOS gate is configured to receive the output signal, and wherein the third NMOS source is coupled to the second voltage rail.

Aspect 5: The apparatus of any one of aspects 2-4, wherein the logic circuit further comprises an inverter including an input coupled to the node, and an output configured to generate the output signal.

Aspect 6: The apparatus of any one of aspects 1-5, wherein the delay element comprises a buffer.

Aspect 7: The apparatus of aspect 1, wherein the logic circuit comprises: a first inverter including a first inverter input and a first inverter output, wherein the first inverter output is configured to produce the output signal; a second inverter including a second inverter input and a second inverter output, wherein the first inverter output is coupled to the second inverter input, wherein the second inverter output is coupled to the first inverter input, and wherein the second inverter output is configured to produce a complementary output signal; an AND gate including a set of AND inputs configured to receive the input signal and the delayed input signal, respectively, and an AND output coupled to the second inverter input; and a NOR gate including a set of NOR inputs configured to receive the input signal and the delayed input signal, respectively, and a NOR output coupled to the first inverter input.

Aspect 8: The apparatus of aspect 7, wherein the first inverter comprises: a first p-channel metal oxide semiconductor field effect transistor (PMOS FET) including a first PMOS source, a first PMOS gate, and a first PMOS drain, wherein the first PMOS source is coupled to a first voltage rail, wherein the first PMOS gate is coupled to the NOR output, and wherein the first PMOS drain is coupled to the AND output; and a first n-channel metal oxide semiconductor field effect transistor (NMOS FET) including a first NMOS drain, a first NMOS gate, and a first NMOS source, wherein the first NMOS drain is coupled to the AND output, wherein the first NMOS gate is coupled to the NOR output, and wherein the first NMOS source is coupled to a second voltage rail.

Aspect 9: The apparatus of aspect 8, wherein the AND gate comprises a pull-down NMOS FET, wherein a first channel width to length ratio of the first PMOS FET is greater than a second channel width to length ratio of the pull-down NMOS FET.

Aspect 10: The apparatus of any one of aspects 7-9, wherein the second inverter comprises: a second PMOS FET including a second PMOS source, a second PMOS gate, and a second PMOS drain, wherein the second PMOS source is coupled to a first voltage rail, wherein the second PMOS gate is coupled to the AND output, and wherein the second PMOS drain is coupled to the NOR output; and a second NMOS FET including a second NMOS drain, a second NMOS gate, and a second NMOS source, wherein the second NMOS drain is coupled to the NOR output, wherein the second NMOS gate is coupled to the AND output, and wherein the second NMOS source is coupled to a second voltage rail.

Aspect 11: The apparatus of aspect 10, wherein the NOR gate comprises a pull-down NMOS FET, wherein a first channel width to length ratio of the second PMOS FET is greater than a second channel width to length ratio of the pull-down NMOS FET.

Aspect 12: The apparatus of any one of aspects 7-8 and 10-11, wherein the AND gate comprises: a first memristor including a first undoped-side terminal configured to receive the input signal, and a first doped-side terminal serving as the AND output; and a second memristor including a second undoped-side terminal configured to receive the delayed input signal, and a second doped-side terminal coupled to the first doped-side terminal of the first memristor.

Aspect 13: The apparatus of any one of aspects 7-12, wherein the NOR gate comprises: a first memristor including a first doped-side terminal configured to receive the input signal, and a first undoped-side terminal; a second memristor including a second doped-side terminal configured to receive the delayed input signal, and a second undoped-side terminal coupled to the first undoped-side terminal of the first memristor; and an inverter including an input coupled to the first and second undoped-side terminals of the first and second inverters, and an output serving as the NOR output.

Aspect 14: The apparatus of aspect 1, wherein the logic circuit comprises: a first AND gate including a first set of inputs configured to receive the input signal and the delayed input signal, respectively; a second AND gate including a second set of inputs configured to receive the delayed input signal and the output signal, respectively; a third AND gate including a third set of inputs configured to receive the input signal and the output signal, respectively; and an OR gate including a fourth set of inputs coupled to outputs of the first, second, and third AND gates, respectively.

Aspect 15: The apparatus of aspect 14, wherein the logic circuit further comprises a buffer including an input coupled to an output of the OR gate, and an output configured to produce the output signal.

Aspect 16: The apparatus of aspect 14 or 15, wherein one or more of the first, second, and third AND gates, each comprises: a first memristor including a first undoped-side terminal serving as one of the corresponding inputs, and a first doped-side terminal serving as a corresponding output; and a second memristor including a second undoped-side terminal serving as another one of the corresponding inputs, and a second doped-side terminal coupled to the first doped-side terminal of the first memristor.

Aspect 17: The apparatus of any one of aspects 14-16, wherein the OR gate comprises: a first memristor including a first doped-side terminal serving as one of the fourth set of inputs coupled to an output of the first AND gate, and a first undoped-side terminal; a second memristor including a second doped-side terminal serving as one of the fourth set of inputs coupled to an output of the second AND gate, and a second undoped-side terminal coupled to the first undoped-side terminal of the first memristor; and a third memristor including a third doped-side terminal serving as one of the fourth set of inputs coupled to the output of the third AND gate, and a second undoped-side terminal coupled to the second undoped-side terminal of the second memristor.

Aspect 18: An apparatus, comprising: a glitch absorbing buffer (GABUF), comprising: a first delay element configured to delay an input signal by a first delay to generate a first delayed input signal; a second delay element configured to delay the first delayed input signal by a second delay to generate a second delayed input signal, wherein a sum of the first delay and the second delay is equal to a delay; and a logic circuit, responsive to the input signal, the first delayed input signal, the second delayed input signal, and an output signal, configured to propagate a pulse in the input signal to the output signal if a width of the pulse of a pulse burst is greater than the delay, and suppress the propagating of the pulse to the output signal if the width of the pulse of the pulse burst is less than the delay and a period of the pulse burst is greater than the width of the pulse plus the first delay.

Aspect 19: The apparatus of aspect 18, wherein the logic circuit comprises: a pull-up circuit configured to selectively couple a node to a first voltage rail in response to the input signal, the first delayed input signal, the second delayed input signal, and the output signal; and a pull-down circuit configured to selectively couple the node to a second voltage rail in response to the input signal, the first delayed input signal, the second delayed input signal, and the output signal.

Aspect 20: The apparatus of aspect 19, wherein the pull-up circuit comprises: a first p-channel metal oxide semiconductor field effect transistor (PMOS FET) including a first PMOS source, a first PMOS gate, and a first PMOS drain, wherein the first PMOS source is coupled to the first voltage rail, and wherein the first PMOS gate is configured to receive the output signal; a second PMOS FET including a second PMOS source, a second PMOS gate, and a second PMOS drain, wherein the second PMOS source is coupled to the first voltage rail, and wherein the second PMOS gate is configured to receive the second delayed input signal; a third PMOS FET including a third PMOS source, a third PMOS gate, and a third PMOS drain, wherein the third PMOS source is coupled to the first PMOS drain, wherein the third PMOS gate is configured to receive the input signal, and wherein the third PMOS drain is coupled to the node; a fourth PMOS FET including a fourth PMOS source, a fourth PMOS gate, and a fourth PMOS drain, wherein the fourth PMOS source is coupled to the second PMOS drain, wherein the fourth PMOS gate is configured to receive the output signal, and wherein the fourth PMOS drain is coupled to the node; and a fifth PMOS FET including a PMOS source/drain, a fifth PMOS gate, and a PMOS drain/source, wherein the PMOS source/drain is coupled to the second PMOS drain, wherein the fifth PMOS gate is configured to receive the first delayed input signal, and wherein the PMOS drain/source is coupled to the first PMOS drain.

Aspect 21: The apparatus of aspect 19 or 20, wherein the pull-down circuit comprises: a first n-channel metal oxide semiconductor field effect transistor (NMOS FET) including a first NMOS source, a first NMOS gate, and a first NMOS drain, wherein the first NMOS source is coupled to the second voltage rail, and wherein the first NMOS gate is configured to receive the output signal; a second NMOS FET including a second NMOS source, a second NMOS gate, and a second NMOS drain, wherein the second NMOS source is coupled to the second voltage rail, and wherein the second NMOS gate is configured to receive the second delayed input signal; a third NMOS FET including a third NMOS source, a third NMOS gate, and a third NMOS drain, wherein the third NMOS source is coupled to the first NMOS drain, wherein the third NMOS gate is configured to receive the input signal, and wherein the third NMOS drain is coupled to the node; a fourth NMOS FET including a fourth NMOS source, a fourth NMOS gate, and a fourth NMOS drain, wherein the fourth NMOS source is coupled to the second NMOS drain, wherein the fourth NMOS gate is configured to receive the output signal, and wherein the fourth NMOS drain is coupled to the node; and a fifth NMOS FET including a NMOS drain/source, a fifth NMOS gate, and a NMOS source/drain, wherein the NMOS drain/source is coupled to the second NMOS drain, wherein the fifth NMOS gate is configured to receive the first delayed input signal, and wherein the NMOS source/drain is coupled to the first NMOS drain.

Aspect 22: The apparatus of any one of aspects 19-21, wherein the logic circuit further comprises an inverter including an input coupled to the node, and an output configured to produce the output signal.

Aspect 23: The apparatus of aspect 19, wherein the pull-up circuit comprises: a first p-channel metal oxide semiconductor field effect transistor (PMOS FET) including a first PMOS source, a first PMOS gate, and a first PMOS drain, wherein the first PMOS source is coupled to the first voltage rail, and wherein the first PMOS gate is configured to receive the input signal; a second PMOS FET including a second PMOS source, a second PMOS gate, and a second PMOS drain, wherein the second PMOS source is coupled to the first voltage rail, and wherein the second PMOS gate is configured to receive the output signal; a third PMOS FET including a third PMOS source, a third PMOS gate, and a third PMOS drain, wherein the third PMOS source is coupled to the first PMOS drain, wherein the third PMOS gate is configured to receive the first delayed input signal, and wherein the third PMOS drain is coupled to the second PMOS drain of the second PMOS FET; and a fourth PMOS FET including a fourth PMOS source, a fourth PMOS gate, and a fourth PMOS drain, wherein the fourth PMOS source is coupled to the second and third PMOS drains, wherein the fourth PMOS gate is configured to receive the second delayed input signal, and wherein the fourth PMOS drain is coupled to the node.

Aspect 24: The apparatus of aspect 19 or 23, wherein the pull-down circuit comprises: a first n-channel metal oxide semiconductor field effect transistor (NMOS FET) including a first NMOS source, a first NMOS gate, and a first NMOS drain, wherein the first NMOS source is coupled to the second voltage rail, and wherein the first NMOS gate is configured to receive the input signal; a second NMOS FET including a second NMOS source, a second NMOS gate, and a second NMOS drain, wherein the second NMOS source is coupled to the second voltage rail, and wherein the second NMOS gate is configured to receive the output signal; a third NMOS FET including a third NMOS source, a third NMOS gate, and a third NMOS drain, wherein the third NMOS source is coupled to the first NMOS drain, wherein the third NMOS gate is configured to receive the first delayed input signal, wherein the third NMOS drain is coupled to the second NMOS drain of the second NMOS FET; and a fourth NMOS FET including a fourth NMOS source, a fourth NMOS gate, and a fourth NMOS drain, wherein the fourth NMOS source is coupled to the second and third NMOS drains, wherein the fourth NMOS gate is configured to receive the second delayed input signal, and wherein the fourth NMOS drain is coupled to the node.

Aspect 25: The apparatus of aspect 24, wherein the logic circuit further comprises an inverter including an input coupled to the node, and an output configured to produce the output signal.

Aspect 26: The apparatus of aspect 18, wherein the logic circuit comprises: a first inverter including a first inverter input and a first inverter output, wherein the first inverter output is configured to produce the output signal; a second inverter including a second inverter input and a second inverter output, wherein the first inverter output is coupled to the second inverter input, wherein the second inverter output is coupled to the first inverter input, and wherein the second inverter output is configured to produce a complementary output signal; an AND gate including a set of AND inputs configured to receive the input signal, the first delayed input signal, and the second delayed input signal, respectively, and an AND output coupled to the second inverter input; and a NOR gate including a set of NOR inputs configured to receive the input signal, the first delayed input signal, and the second delayed input signal, respectively, and a NOR output coupled to the first inverter input.

Aspect 27: The apparatus of aspect 18, wherein the logic circuit comprises: a first AND gate including a first set of inputs configured to receive the input signal, the first delayed input signal, and the second delayed input signal, respectively; a second AND gate including a second set of inputs configured to receive the input signal and the output signal, respectively; a third AND gate including a third set of inputs configured to receive the first delayed input signal and the output signal, respectively; a fourth AND gate including a fourth set of inputs configured to receive the second delayed input signal and the output signal, respectively; and an OR gate including a fourth set of inputs coupled to outputs of the first, second, third, and fourth AND gates, respectively.

Aspect 28: The apparatus of aspect 27, wherein the logic circuit further comprises a buffer including an input coupled to an output of the OR gate, and an output configured to produce the output signal.

Aspect 29: An wireless communication device, comprising: at least one antenna; a transceiver coupled to at least one antenna; one or more signal processing cores coupled to the transceiver, wherein the one or more signal processing cores comprises a set of glitch absorbing buffers (GABUFs), wherein each of the GABUFs includes: a delay element configured to delay an input signal by a delay to generate a delayed input signal; and a logic circuit, responsive to the input signal, the delayed input signal, and an output signal, configured to propagate a pulse in the input signal to the output signal if a width of the pulse is greater than the delay, and suppress the propagating of the pulse to the output signal if the width of the pulse is less than the delay.

Aspect 30: An wireless communication device, comprising: at least one antenna; a transceiver coupled to at least one antenna; one or more signal processing cores coupled to the transceiver, wherein the one or more signal processing cores comprises a set of glitch absorbing buffers (GABUFs), wherein each of the GABUFs includes: a first delay element configured to delay an input signal by a first delay to generate a first delayed input signal; a second delay element configured to delay the first delayed input signal by a second delay to generate a second delayed input signal, wherein a sum of the first delay and the second delay is equal to a delay; and a logic circuit, responsive to the input signal, the first delayed input signal, the second delayed input signal, and an output signal, configured to propagate a pulse in the input signal to the output signal if a width of the pulse of a pulse burst is greater than the delay, and suppress the propagating of the pulse to the output signal if the width of the pulse of the pulse burst is less than the delay and a period of the pulse burst is greater than the width of the pulse plus the first delay. The previous description of the disclosure is provided to enable any person skilled in the

art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

1. An apparatus, comprising:
a glitch absorbing buffer (GABUF), comprising:
a delay element configured to delay an input signal by a delay to generate a delayed input signal; and
a logic circuit, responsive to the input signal, the delayed input signal, and an output signal, configured to propagate a pulse in the input signal to the output signal if a width of the pulse is greater than the delay, and suppress the propagating of the pulse to the output signal if the width of the pulse is less than the delay.

2. The apparatus of claim 1, wherein the logic circuit comprises:
a pull-up circuit configured to selectively couple a node to a first voltage rail in response to the input signal, the delayed input signal, and the output signal; and
a pull-down circuit configured to selectively couple the node to a second voltage rail in response to the input signal, the delayed input signal, and the output signal.

3. The apparatus of claim 2, wherein the pull-up circuit comprises:
a first p-channel metal oxide semiconductor field effect transistor (PMOS FET) including a first PMOS source, a first PMOS gate, and a first PMOS drain, wherein the first PMOS source is coupled to the first voltage rail, and wherein the first PMOS gate is configured to receive the input signal;
a second PMOS FET including a second PMOS source, a second PMOS gate, and a second PMOS drain, wherein the second PMOS source is coupled to the first voltage rail, and wherein the second PMOS gate is configured to receive the output signal; and
a third PMOS FET including a third PMOS source, a third PMOS gate, and a third PMOS drain, wherein the third PMOS source is coupled to the first and second PMOS drains, wherein the third PMOS gate is configured to receive the delayed input signal, and wherein the third PMOS drain is coupled to the node.

4. The apparatus of claim 3, wherein the pull-down circuit comprises:
a first n-channel metal oxide semiconductor field effect transistor (NMOS FET) including a first NMOS drain, a first NMOS gate, and a first NMOS source, wherein the first NMOS drain is coupled to the node, and wherein the first NMOS gate is configured to receive the delayed input signal;
a second NMOS FET including a second NMOS drain, a second NMOS gate, and a second NMOS source, wherein the second NMOS drain is coupled to the first NMOS source, wherein the second NMOS gate is configured to receive the input signal, and wherein the second NMOS source is coupled to the second voltage rail; and
a third NMOS FET including a third NMOS drain, a third NMOS gate, and a third NMOS source, wherein the third NMOS drain is coupled to the first NMOS source, wherein the third NMOS gate is configured to receive the output signal, and wherein the third NMOS source is coupled to the second voltage rail.

5. The apparatus of claim 2, wherein the logic circuit further comprises an inverter including an input coupled to the node, and an output configured to generate the output signal.

6. The apparatus of claim 1, wherein the delay element comprises a buffer.

7. The apparatus of claim 1, wherein the logic circuit comprises:
a first inverter including a first inverter input and a first inverter output, wherein the first inverter output is configured to produce the output signal;
a second inverter including a second inverter input and a second inverter output, wherein the first inverter output is coupled to the second inverter input, wherein the second inverter output is coupled to the first inverter input, and wherein the second inverter output is configured to produce a complementary output signal;
an AND gate including a set of AND inputs configured to receive the input signal and the delayed input signal, respectively, and an AND output coupled to the second inverter input; and
a NOR gate including a set of NOR inputs configured to receive the input signal and the delayed input signal, respectively, and a NOR output coupled to the first inverter input.

8. The apparatus of claim 7, wherein the first inverter comprises:
a first p-channel metal oxide semiconductor field effect transistor (PMOS FET) including a first PMOS source, a first PMOS gate, and a first PMOS drain, wherein the first PMOS source is coupled to a first voltage rail, wherein the first PMOS gate is coupled to the NOR output, and wherein the first PMOS drain is coupled to the AND output; and
a first n-channel metal oxide semiconductor field effect transistor (NMOS FET) including a first NMOS drain, a first NMOS gate, and a first NMOS source, wherein the first NMOS drain is coupled to the AND output, wherein the first NMOS gate is coupled to the NOR output, and wherein the first NMOS source is coupled to a second voltage rail.

9. The apparatus of claim 8, wherein the AND gate comprises a pull-down NMOS FET, wherein a first channel width to length ratio of the first PMOS FET is greater than a second channel width to length ratio of the pull-down NMOS FET.

10. The apparatus of claim 7, wherein the second inverter comprises:
a second PMOS FET including a second PMOS source, a second PMOS gate, and a second PMOS drain, wherein the second PMOS source is coupled to a first voltage rail, wherein the second PMOS gate is coupled to the AND output, and wherein the second PMOS drain is coupled to the NOR output; and
a second NMOS FET including a second NMOS drain, a second NMOS gate, and a second NMOS source, wherein the second NMOS drain is coupled to the NOR output, wherein the second NMOS gate is coupled to the AND output, and wherein the second NMOS source is coupled to a second voltage rail.

11. The apparatus of claim 10, wherein the NOR gate comprises a pull-down NMOS FET, wherein a first channel width to length ratio of the second PMOS FET is greater than a second channel width to length ratio of the pull-down NMOS FET.

12. The apparatus of claim 7, wherein the AND gate comprises:
a first memristor including a first undoped-side terminal configured to receive the input signal, and a first doped-side terminal serving as the AND output; and
a second memristor including a second undoped-side terminal configured to receive the delayed input signal, and a second doped-side terminal coupled to the first doped-side terminal of the first memristor.

13. The apparatus of claim 7, wherein the NOR gate comprises:
a first memristor including a first doped-side terminal configured to receive the input signal, and a first undoped-side terminal;
a second memristor including a second doped-side terminal configured to receive the delayed input signal, and a second undoped-side terminal coupled to the first undoped-side terminal of the first memristor; and
an inverter including an input coupled to the first and second undoped-side terminals of the first and second inverters, and an output serving as the NOR output.

14. The apparatus of claim 1, wherein the logic circuit comprises:
a first AND gate including a first set of inputs configured to receive the input signal and the delayed input signal, respectively;
a second AND gate including a second set of inputs configured to receive the delayed input signal and the output signal, respectively;
a third AND gate including a third set of inputs configured to receive the input signal and the output signal, respectively; and
an OR gate including a fourth set of inputs coupled to outputs of the first, second, and third AND gates, respectively. (Withdrawn) The apparatus of claim 14, wherein the logic circuit further comprises a buffer including an input coupled to an output of the OR gate, and an output configured to produce the output signal.

16. The apparatus of claim 14, wherein one or more of the first, second, and third AND gates, each comprises:
a first memristor including a first undoped-side terminal serving as one of the corresponding inputs, and a first doped-side terminal serving as a corresponding output; and
a second memristor including a second undoped-side terminal serving as another one of the corresponding inputs, and a second doped-side terminal coupled to the first doped-side terminal of the first memristor.

17. The apparatus of claim 14, wherein the OR gate comprises:
a first memristor including a first doped-side terminal serving as one of the fourth set of inputs coupled to an output of the first AND gate, and a first undoped- side terminal;
a second memristor including a second doped-side terminal serving as one of the fourth set of inputs coupled to an output of the second AND gate, and a second undoped-side terminal coupled to the first undoped-side terminal of the first memristor; and
a third memristor including a third doped-side terminal serving as one of the fourth set of inputs coupled to the output of the third AND gate, and a second undoped-side terminal coupled to the second undoped-side terminal of the second memristor.

18. An apparatus, comprising:
a glitch absorbing buffer (GABUF), comprising:
a first delay element configured to delay an input signal by a first delay to generate a first delayed input signal;
a second delay element configured to delay the first delayed input signal by a second delay to generate a second delayed input signal, wherein a sum of the first delay and the second delay is equal to a delay; and
a logic circuit, responsive to the input signal, the first delayed input signal, the second delayed input signal, and an output signal, configured to propagate a pulse in the input signal to the output signal if a width of the pulse of a pulse burst is greater than the delay, and suppress the propagating of the pulse to the output signal if the width of the pulse of the pulse burst is less than the delay and a period of the pulse burst is greater than the width of the pulse plus the first delay.

19. The apparatus of claim 18, wherein the logic circuit comprises:
a pull-up circuit configured to selectively couple a node to a first voltage rail in response to the input signal, the first delayed input signal, the second delayed input signal, and the output signal; and
a pull-down circuit configured to selectively couple the node to a second voltage rail in response to the input signal, the first delayed input signal, the second delayed input signal, and the output signal.

20. The apparatus of claim 19, wherein the pull-up circuit comprises:
a first p-channel metal oxide semiconductor field effect transistor (PMOS FET) including a first PMOS source, a first PMOS gate, and a first PMOS drain, wherein the first PMOS source is coupled to the first voltage rail, and wherein the first PMOS gate is configured to receive the output signal;
a second PMOS FET including a second PMOS source, a second PMOS gate, and a second PMOS drain, wherein the second PMOS source is coupled to the first voltage rail, and wherein the second PMOS gate is configured to receive the second delayed input signal;
a third PMOS FET including a third PMOS source, a third PMOS gate, and a third PMOS drain, wherein the third PMOS source is coupled to the first PMOS drain, wherein the third PMOS gate is configured to receive the input signal, and wherein the third PMOS drain is coupled to the node;
a fourth PMOS FET including a fourth PMOS source, a fourth PMOS gate, and a fourth PMOS drain, wherein the fourth PMOS source is coupled to the second PMOS drain, wherein the fourth PMOS gate is configured to receive the output signal, and wherein the fourth PMOS drain is coupled to the node; and
a fifth PMOS FET including a PMOS source/drain, a fifth PMOS gate, and a PMOS drain/source, wherein the PMOS source/drain is coupled to the second PMOS drain, wherein the fifth PMOS gate is configured to receive the first delayed input signal, and wherein the PMOS drain/source is coupled to the first PMOS drain.

21. The apparatus of claim 20, wherein the pull-down circuit comprises:
a first n-channel metal oxide semiconductor field effect transistor (NMOS FET) including a first NMOS source, a first NMOS gate, and a first NMOS drain, wherein the first NMOS source is coupled to the second voltage rail, and wherein the first NMOS gate is configured to receive the output signal;
a second NMOS FET including a second NMOS source, a second NMOS gate, and a second NMOS drain, wherein the second NMOS source is coupled to the second voltage rail, and wherein the second NMOS gate is configured to receive the second delayed input signal;
a third NMOS FET including a third NMOS source, a third NMOS gate, and a third NMOS drain, wherein the third NMOS source is coupled to the first NMOS drain, wherein the third NMOS gate is configured to receive the input signal, and wherein the third NMOS drain is coupled to the node;
a fourth NMOS FET including a fourth NMOS source, a fourth NMOS gate, and a fourth NMOS drain, wherein the fourth NMOS source is coupled to the second NMOS drain, wherein the fourth NMOS gate is configured to receive the output signal, and wherein the fourth NMOS drain is coupled to the node; and
a fifth NMOS FET including a NMOS drain/source, a fifth NMOS gate, and a NMOS source/drain, wherein the NMOS drain/source is coupled to the second NMOS drain, wherein the fifth NMOS gate is configured to receive the first delayed input signal, and wherein the NMOS source/drain is coupled to the first NMOS drain.

22. The apparatus of claim 19, wherein the logic circuit further comprises an inverter including an input coupled to the node, and an output configured to produce the output signal.

23. The apparatus of claim 19, wherein the pull-up circuit comprises:
a first p-channel metal oxide semiconductor field effect transistor (PMOS FET) including a first PMOS source, a first PMOS gate, and a first PMOS drain, wherein the first PMOS source is coupled to the first voltage rail, and wherein the first PMOS gate is configured to receive the input signal;
a second PMOS FET including a second PMOS source, a second PMOS gate, and a second PMOS drain, wherein the second PMOS source is coupled to the first voltage rail, and wherein the second PMOS gate is configured to receive the output signal;
a third PMOS FET including a third PMOS source, a third PMOS gate, and a third PMOS drain, wherein the third PMOS source is coupled to the first PMOS drain, wherein the third PMOS gate is configured to receive the first delayed input signal, and wherein the third PMOS drain is coupled to the second PMOS drain of the second PMOS FET; and
a fourth PMOS FET including a fourth PMOS source, a fourth PMOS gate, and a fourth PMOS drain, wherein the fourth PMOS source is coupled to the second and third PMOS drains, wherein the fourth PMOS gate is configured to receive the second delayed input signal, and wherein the fourth PMOS drain is coupled to the node.

24. The apparatus of claim 23, wherein the pull-down circuit comprises:
a first n-channel metal oxide semiconductor field effect transistor (NMOS FET) including a first NMOS source, a first NMOS gate, and a first NMOS drain, wherein the first NMOS source is coupled to the second voltage rail, and wherein the first NMOS gate is configured to receive the input signal;
a second NMOS FET including a second NMOS source, a second NMOS gate, and a second NMOS drain, wherein the second NMOS source is coupled to the second voltage rail, and wherein the second NMOS gate is configured to receive the output signal;
a third NMOS FET including a third NMOS source, a third NMOS gate, and a third NMOS drain, wherein the third NMOS source is coupled to the first NMOS drain, wherein the third NMOS gate is configured to receive the first delayed input signal, and wherein the third NMOS drain is coupled to the second NMOS drain of the second NMOS FET; and
a fourth NMOS FET including a fourth NMOS source, a fourth NMOS gate, and a fourth NMOS drain, wherein the fourth NMOS source is coupled to the second and third NMOS drains, wherein the fourth NMOS gate is configured to receive the second delayed input signal, and wherein the fourth NMOS drain is coupled to the node.

25. The apparatus of claim 24, wherein the logic circuit further comprises an inverter including an input coupled to the node, and an output configured to produce the output signal.

26. The apparatus of claim 18, wherein the logic circuit comprises:
a first inverter including a first inverter input and a first inverter output, wherein the first inverter output is configured to produce the output signal;
a second inverter including a second inverter input and a second inverter output, wherein the first inverter output is coupled to the second inverter input, wherein the second inverter output is coupled to the first inverter input, and wherein the second inverter output is configured to produce a complementary output signal;
an AND gate including a set of AND inputs configured to receive the input signal, the first delayed input signal, and the second delayed input signal, respectively, and an AND output coupled to the second inverter input; and
a NOR gate including a set of NOR inputs configured to receive the input signal, the first delayed input signal, and the second delayed input signal, respectively, and a NOR output coupled to the first inverter input.

27. The apparatus of claim 18, wherein the logic circuit comprises:
a first AND gate including a first set of inputs configured to receive the input signal, the first delayed input signal, and the second delayed input signal, respectively;
a second AND gate including a second set of inputs configured to receive the input signal and the output signal, respectively;
a third AND gate including a third set of inputs configured to receive the first delayed input signal and the output signal, respectively;
a fourth AND gate including a fourth set of inputs configured to receive the second delayed input signal and the output signal, respectively; and
an OR gate including a fourth set of inputs coupled to outputs of the first, second, third, and fourth AND gates, respectively.

28. The apparatus of claim 27, wherein the logic circuit further comprises a buffer including an input coupled to an output of the OR gate, and an output configured to produce the output signal.

29. A wireless communication device, comprising:
at least one antenna;
a transceiver coupled to at least one antenna;
one or more signal processing cores coupled to the transceiver, wherein the one or more signal processing cores comprises a set of glitch absorbing buffers (GABUFs), wherein each of the GABUFs comprises:
a delay element configured to delay an input signal by a delay to generate a delayed input signal; and
a logic circuit, responsive to the input signal, the delayed input signal, and an output signal, configured to propagate a pulse in the input signal to the output signal if a width of the pulse is greater than the delay, and suppress the propagating of the pulse to the output signal if the width of the pulse is less than the delay.

30. A wireless communication device, comprising:
at least one antenna;
a transceiver coupled to at least one antenna;
one or more signal processing cores coupled to the transceiver, wherein the one or more signal processing cores comprises a set of glitch absorbing buffers (GABUFs), wherein each of the GABUFs comprises:
a first delay element configured to delay an input signal by a first delay to generate a first delayed input signal;
a second delay element configured to delay the first delayed input signal by a second delay to generate a second delayed input signal, wherein a sum of the first delay and the second delay is equal to a delay; and
a logic circuit, responsive to the input signal, the first delayed input signal, the second delayed input signal, and an output signal, configured to propagate a pulse in the input signal to the output signal if a width of the pulse of a pulse burst is greater than the delay, and suppress the propagating of the pulse to the output signal if the width of the pulse of the pulse burst is less than the delay and a period of the pulse burst is greater than the width of the pulse plus the first delay.
